(19) United States
(12) Patent Application Publication
(10) Pub. No.: US 2009/0060093 A1
(43) Pub. Date: Mar. 5, 2009

(54) MULTI-FUNCTION DECODER ENGINE IN WIRELESS RECEIVER

(75) Inventors: Sharath Narahari, Pleasanton, CA (US); Ramesh Duvvuru, San Jose, CA (US); Yu-Wen (Evan) Chang, Fremont, CA (US); Mohammad R. Moradi, Sunnyvale, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: MediaPhy Corporation, San Jose, CA (US)

(21) Appl. No.: 12/186,092

(22) Filed: Aug. 5, 2008

Related U.S. Application Data
(60) Provisional application No. 60/954,236, filed on Aug. 6, 2007.

(51) Int. Cl. H04L 27/06; H03M 13/00; G06F 11/00

(52) U.S. Cl. 375/340; 714/776; 714/E11.001

(57) ABSTRACT

Systems, methods, devices, and processors are described for a wireless receiver. The receiver may be configured to receive signals transmitted according to various mobile digital television standards. The receiver may include a number of hardware engines. The hardware engines may be individually controlled in a number of aspects. Power to particular hardware engines may be controlled, and the speed of the different hardware engines may vary. The receiver may include a novel multi-function decoder engine. The receiver may be configured to dynamically avoid problems related to harmonics, and may include a novel tap configuration with taps at different locations in the data flow.

### CROSS REFERENCES

This application claims priority from co-pending U.S. Provisional Patent Application No. 60/954,236, filed Aug. 6, 2007, entitled “MULTI-FUNCTION DECODER ENGINE IN WIRELESS RECEIVER” (Attorney Docket No. 025950-001200US). This application is related to the following U.S. patent applications: U.S. patent application Ser. No. ______, Attorney Docket No. 025950-0010US, filed concurrently herewith, entitled “POWER CONTROL FOR RESPECTIVE HARDWARE ENGINES IN WIRELESS RECEIVER”, U.S. patent application Ser. No. ______, Attorney Docket No. 025950-001110US, filed concurrently herewith, entitled “ACCELERATED PROCESSING IN SUBSET OF HARDWARE ENGINES IN WIRELESS RECEIVER”, U.S. patent application Ser. No. ______, Attorney Docket No. 025950-001310US, filed concurrently herewith, entitled “MULTI-MODE ARCHITECTURE IN WIRELESS RECEIVER”; U.S. patent application Ser. No. ______, Attorney Docket No. 025950-001410US, filed concurrently herewith, entitled “HARMONICS AVOIDANCE”, and U.S. patent application Ser. No. ______, Attorney Docket No. 025950-001510US, filed concurrently herewith, entitled “TAPS FOR DATA FROM HARDWARE ENGINES IN A RECEIVER”. This application hereby incorporates by reference herein the content of the aforementioned applications in their entirety and for all purposes.

### BACKGROUND

The present invention generally relates to wireless communications and mobile digital TV (MDTV) technology. Different standards have been developed for digital TV reception on battery-based mobile devices. In such devices, power consumption is often a concern. Reading, writing, and storing data in memory consumes power. It may be desirable to introduce novel architectures and methods which process multiple standards on a device, allow for the reduction of processing operations, and/or have lessened requirements for memory.

### SUMMARY

Systems, methods, devices, and processors are described for a wireless receiver. The receiver may be configured to receive signals transmitted according to various mobile digital television standards. The receiver may include a number of hardware engines. The hardware engines may be individually controlled in a number of aspects. Power to particular hardware engines may be controlled, and the speed of the different hardware engines may vary. The receiver may include a novel multi-function decoder engine. The receiver may be configured to dynamically avoid problems related to harmonics, and may include a novel tap configuration with taps at different locations in the data flow.

In one set of embodiments, methods, devices, and processors are described for controlling a decoder unit in a wireless receiver. In one set of embodiments, a processor includes a number of hardware engines, one of which is a decoder unit. The decoder unit processes both physical layer packets and link layer frames. A stream of data made up of a series of physical layer packets is generated from the digitized wireless communication signal. Using a particular set of hardware resources of the decoder unit, the series of physical layer packets is decoded to generate decoded physical layer packet data to fill a frame. A selected row of the frame is also decoded using the particular set of hardware resources. The decoder unit may be configured to serially process and decode packets and rows, using arbitration algorithms to decide whether to queue a packet or row.

In another set of embodiments, a decoding process for a frame is initiated in which the first link layer frame is decoded row by row. Data is received indicating that one or more stored physical layer packets are ready to be decoded. The decoding process of the frame is interrupted to decode the one or more stored physical layer packets. Once the processing of the stored physical layer packets is completed, the processing of the interrupted link layer frame may be resumed. In another embodiment, interrupting the processing of a link layer frame to process stored physical layer packets occurs only when the number of stored physical layer packets exceeds a threshold.

### BRIEF DESCRIPTION OF THE DRAWINGS

A further understanding of the nature and advantages of the present invention may be realized by reference to the following drawings. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 is a block diagram of a wireless system configured according to various embodiments of the invention.

FIG. 2 is a block diagram of a device configured according to various embodiments of the invention.

FIG. 11 is a block diagram of a processor with a resource sharing architecture configured according to various embodiments of the invention.

FIG. 12 is a block diagram of a component configuration illustrating resource sharing according to various embodiments of the invention.

FIGS. 13A and 13B are block diagrams of component configurations illustrating memory sharing according to various embodiments of the invention.

FIG. 14 is a block diagram of a de-interleaver unit architecture illustrating resource sharing according to various embodiments of the invention.

FIG. 15 is a flowchart illustrating a method of processing mobile digital broadcast video signals according to various embodiments of the invention.

FIG. 16 is a flowchart illustrating an alternative method of processing mobile digital broadcast video signals according to various embodiments of the invention.

FIG. 21 is a block diagram of a device including hardware engines and power control functionality according to various embodiments of the invention.

FIG. 22A is a block diagram of a device including control functionality for powering off selected hardware engines according to various embodiments of the invention.

FIG. 22B is a block diagram of a device including control functionality for withholding clock signals from selected hardware engines according to various embodiments of the invention.

FIG. 23 is a block diagram of a device including control functionality for powering off or withholding clock signals from selected hardware engines according to various embodiments of the invention.

FIG. 24 is a timing diagram related to reception of bursts of data according to various embodiments of the invention.

FIGS. 25A-25E are block diagrams of a device configured to selectively power components according to various embodiments of the invention.

FIG. 26 is a block diagram of a device including an integer carrier frequency offset unit configured according to various embodiments of the invention.

FIG. 27 is a flowchart illustrating a method of controlling power to hardware engines according to various embodiments of the invention.

FIG. 28 is a flowchart illustrating a method of successively applying power to hardware engines according to various embodiments of the invention.

FIG. 29 is a flowchart illustrating a method of controlling the application and withdrawal of power to hardware engines according to various embodiments of the invention.

FIG. 30 is a flowchart illustrating a method for monitoring and controlling particular resources of a hardware engine according to various embodiments of the invention.

FIG. 31 is a diagram of a device including components configured according to various embodiments of the invention.

FIG. 32 is a diagram of a device including components configured according to various embodiments of the invention.

FIG. 33 is a diagram of a device including components configured according to various embodiments of the invention.

FIG. 34 is a block diagram of a device including a decoder unit configured according to various embodiments of the invention.

FIG. 35 is block diagram illustrating an alternative configuration of a device including a decoder unit configured according to various embodiments of the invention.

FIG. 36 is a flowchart illustrating a method for decoding according to various embodiments of the invention.

FIG. 37 is a flowchart illustrating a method for decoding physical layer packets and rows of a link layer frame according to various embodiments of the invention.

FIG. 38 is a flowchart illustrating an alternative method for decoding packets and rows according to various embodiments of the invention.

FIG. 41 is a block diagram of a device including a hardware engine configuration according to various embodiments of the invention.

FIG. 42 is a block diagram of a component configuration for a device according to various embodiments of the invention.

FIG. 43 is a block diagram of a device including hardware engines configured to run at the same or different speeds according to various embodiments of the invention.

FIGS. 44A and 44B are block diagrams of component configurations to implement differential clock outputs according to various embodiments of the invention.

FIG. 45 is a flowchart illustrating a method for operating clock domains on a processor at different speeds according to various embodiments of the invention.

FIG. 46 is a flowchart illustrating a method for dynamically modifying the operating frequency in a subset of hardware engines for a processor according to various embodiments of the invention.

FIG. 47 is a flowchart illustrating a method for responsively modifying the operating frequency in a subset of hardware engines for a processor according to various embodiments of the invention.

FIG. 51A is a block diagram of a device including components for avoiding harmonics according to various embodiments of the invention.

FIG. 51B is a block diagram of a mobile communications device including components for avoiding harmonics according to various embodiments of the invention.

FIG. 52 is a block diagram of a clock configuration according to various embodiments of the invention.

FIG. 53 is a diagram of a look-up table for looking up clock frequencies to be transitioned to according to various embodiments of the invention.

FIGS. 54A and 54B are block diagrams of alternative clock configurations according to various embodiments of the invention.

FIG. 55 is a flowchart illustrating a method for avoiding harmonics in a wireless receiver according to various embodiments of the invention.

FIG. 56 is a flowchart illustrating a method for avoiding harmonics when receiving a wireless digital video signal according to various embodiments of the invention.

FIG. 57 is a flowchart illustrating a method for transitioning clock frequencies to avoid harmonics from the reception of a wireless digital video signal according to various embodiments of the invention.

FIG. 61 is a block diagram of a device utilizing taps to collect input data to and output data from hardware engines according to various embodiments of the invention.

FIG. 62 is a block diagram of a mobile communications device utilizing taps to collect input data to and output data from hardware engines according to various embodiments of the invention.

FIG. 63 is a block diagram of an alternative configuration of a mobile communications device utilizing taps to collect input data to and output data from hardware engines according to various embodiments of the invention.

FIG. 64 is a block diagram of a configuration utilizing taps to collect data according to various embodiments of the invention.

FIG. 65 is a flowchart illustrating a method for utilizing taps to collect data according to various embodiments of the invention.

FIG. 66 is a flowchart illustrating a method for utilizing taps to collect data when receiving a digital video broadcast signal according to various embodiments of the invention.

FIG. 67 is a flowchart illustrating a method for utilizing taps to collect and transfer data when receiving a wireless digital video broadcast signal according to various embodiments of the invention.

### DETAILED DESCRIPTION

Systems, devices, processors, methods, and software are described for the reception of wireless signals at a receiver. The receiver may be configured to receive and process signals transmitted according to various mobile digital television standards. The receiver may include a number of hardware engines, and certain resources in the engines may be used for a variety of the different standards. The hardware engines may be individually controlled in a number of aspects. For example, power to and the clock speed of particular hardware engines may be controlled. The receiver may include a novel multi-function decoder engine. The receiver may be configured to dynamically avoid problems related to harmonics, and may include a novel tap configuration with taps at different locations in the data flow.

The following description provides examples only, and is not intended to limit the scope, applicability, or configuration of the invention. Rather, the ensuing description of the embodiments will provide those skilled in the art with an enabling description for implementing embodiments of the invention. Various changes may be made in the function and arrangement of elements without departing from the spirit and scope of the invention.

Thus, various embodiments may omit, substitute, or add various procedures or components as appropriate. For instance, it should be appreciated that in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner.

It should also be appreciated that the following systems, methods, and software may individually or collectively be components of a larger system, wherein other procedures may take precedence over or otherwise modify their application. Also, a number of steps may be required before, after, or concurrently with the following embodiments.

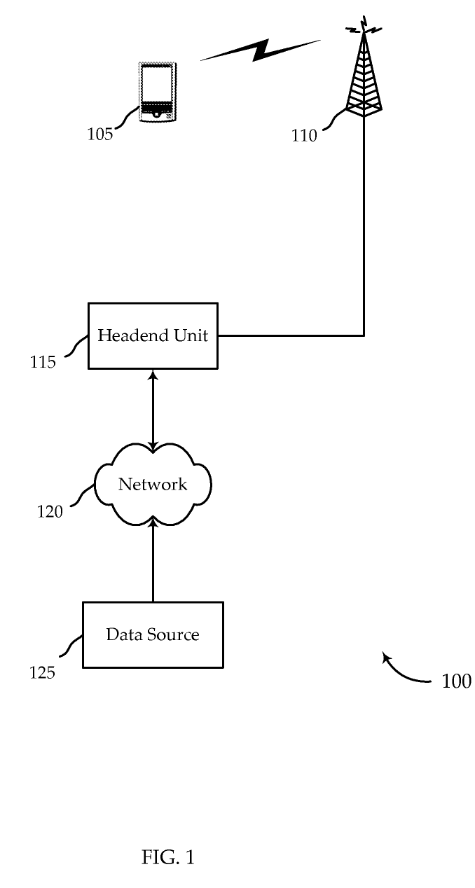

Novel receiver functionality is described for the reception of and processing of signals transmitted according to various mobile digital television standards. Turning to FIG. 1, an example communications system 100 for implementing embodiments of the invention is illustrated. The system includes a mobile communications device 105. The mobile communications device 105 may be a cellular telephone, other mobile phone, personal digital assistant (PDA), portable video player, portable multimedia player, portable DVD player, laptop personal computer, a television in transportation means (including cars, buses, and trains), portable game console, digital still camera or video camcorder, or other device configured to receive wireless communications signals.

In the illustrated embodiment, the device 105 communicates with one or more base stations 110. A base station 110 may be one of a collection of base stations utilized as part of a system 100 that communicates with the device 105 using wireless signals. The device 105 may receive a wireless signal including a number of time-multiplexed bursts of data (e.g., a video broadcast signal) from the base station 110. Components of the device may be used to process a number of different standards, and be powered on or off (or otherwise suspended and reactivated) in series between bursts. The device 105 may include a processor with a number of hardware engines. The hardware engines may be individually controlled in a number of aspects. For example, power to particular hardware engines may be switched on and off as a burst is processed through the hardware engines, and the speed of the different hardware engines may be varied. The device 105 may include a novel, multi-function decoder. The receiver may be configured to dynamically avoid problems related to harmonics, and may include a novel tap configuration with taps at different locations in the data flow. These novel techniques will be described in detail below.

The base station 110 is in communication with a headend unit 115 that routes the communication signals between the network 120 and the base station 110. In other embodiments, other types of infrastructure network devices or sets of devices (e.g., servers or other computers) may also serve as an interface between a network 120 and the base station 110. For example, a headend unit 115 may communicate with a Mobile Switching Center (MSC) that can be configured to operate as an interface between the device 105 and a Public Switched Telephone Network (PSTN).

The network 120 of the illustrated embodiment may be any type of network, and may include, for example, the Internet, an IP network, an intranet, a wide-area network (WAN), a local-area network (LAN), a virtual private network (VPN), the Public Switched Telephone Network (PSTN), or any other type of network supporting data communication between any devices described herein. A network 120 may include both wired and wireless connections, including optical links. The system 100 also includes a data source 125, which may be a server or other computer configured to transmit data (video, audio, or other data) to the communications device 105 via the network 120.

It is worth noting that aspects of the present invention may be applied to a variety of devices (such as communications device 105) generally and, more specifically, may be applied to mobile digital television (MDTV) devices. Aspects of the present invention may be applied to digital video broadcast standards that are either in effect or are at various stages of development. These may include the European standard DVB-H, the Japanese standard ISDB-T, the Korean standards digital audio broadcasting (DAB)-based Terrestrial-DMB and Satellite-DMB, the Chinese standards DTV-M, Terrestrial-Mobile Multimedia Broadcasting (T-MMB), Satellite and terrestrial interaction multimedia (STiMi), and the MediaFLO format proposed by Qualcomm Inc. While certain embodiments of the present invention are described in the context of the DVB-H standard, it may also be implemented in any of the above or future standards, and as such is not limited to any one particular standard.

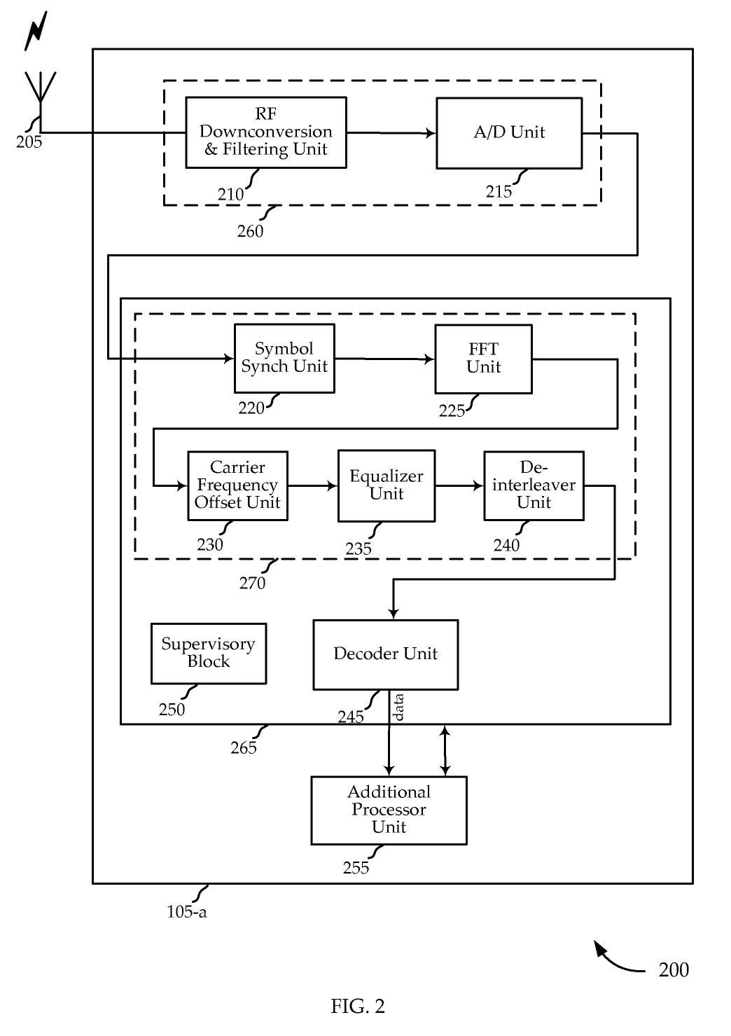

Referring to FIG. 2, a block diagram 200 of an example device 105-a is shown which illustrates various embodiments of the invention. The device 105-a may be the mobile communications device 105 of FIG. 1, or a processor, set of processors, or other combination of components integrated therein. In the embodiments described herein, assume an orthogonal frequency division multiplexing (OFDM) system is implemented, while realizing that the principles described are applicable to a multicarrier signal in a range of both wireless and wireline systems.

The device 105-a may be configured to receive a radio frequency (RF) signal via an antenna 205. The device 105 may be a mobile phone, PDA, iPAC, portable video player, portable multimedia player, portable DVD player, laptop PC, TV in transportation means (including cars, buses, and trains), portable game console, digital still camera or video camcorder, or any other mobile device. Also, while an assumption will be made that the system in certain embodiments implements DVB-H, DMB, and ISDB-T, other embodiments of the invention may be implemented in a broader, narrower, or otherwise different range of standards.

The device 105-a includes a number of receiver components, which may include: an RF down-conversion and filtering unit 210, A/D unit 215, symbol synchronization unit 220, FFT unit 225, carrier frequency offset unit 230, equalizer unit 235, de-interleaver unit 240, and decoder unit 245. The device 105-a includes one or more memory units (not explicitly shown in this embodiment, but illustrated elsewhere) used for a variety of purposes. In one embodiment, the radio frequency signal is received via an antenna 205. The desired signal is selected, down-converted, and filtered through the RF down-conversion and filtering unit 210. The output is converted into a digital signal by the A/D unit 215. The RF down-conversion and filtering unit 210 and the A/D unit 215 may hereinafter be referred to collectively as the analog processing units 260 (and may be controlled collectively or individually). It is worth noting that the RF down-conversion and filtering unit 210 or the A/D unit 215 may be external components, or may be integrated to varying degrees on a single chip with the hardware block 265 discussed in greater detail below. Those skilled in the art recognize the various options.

In one embodiment, this digitized signal is forwarded to and through a series of hardware engines, namely the symbol synchronization unit 220, FFT unit 225, carrier frequency offset unit 230, equalizer unit 235, de-interleaver unit 240, and decoder unit 245. The symbol synchronization unit 220, FFT unit 225, carrier frequency offset unit 230, equalizer unit 235, and de-interleaver unit 240 may be together referred to as the demodulator 270, performing the bulk of the PHY layer processing. The decoder unit 245 may perform both PHY and link layer processing. Various functions of the hardware engines may be set up and controlled by a supervisory block 250, also implemented in hardware.

In one embodiment, a hardware block 265 includes a symbol synchronization unit 220, FFT unit 225, carrier frequency offset unit 230, equalizer unit 235, de-interleaver unit 240, decoder unit 245, and supervisory block 250. Certain set-up, control, and other functions described herein may be also be performed by an on or off chip central processing unit (CPU), or a host processor, which may be described as the additional processor unit 255. The additional processor unit 255 may, thus, control certain aspects of the hardware block 265 functionality. Throughout this Detailed Description, various functionality is described as capable of being performed by the supervisory block 250 or the additional processor unit 255. It is worth noting that, in various embodiments, any such functionality may be performed by the supervisory block 250, the additional processor unit 255, or any combination thereof.

Each respective hardware engine may be a distinct set of multipliers, adders, rounders, and memory configured to perform particular, designated tasks (e.g., symbol synchronization for the symbol synchronization unit 220, fast fourier transform processing for the FFT unit 225, and so on). The distinct set of multipliers, adders, rounders, and memory making up the symbol synchronization unit 220 may, therefore, be separate from (while being in communication with) the distinct set of multipliers, adders, rounders, and memory making up the FFT unit 225, carrier frequency offset unit 230, or equalizer unit 235, for example. Thus, the multipliers, adders, rounders, and memory making up each respective hardware engine may be allocated to performing the functions of the applicable unit, and not to functions of the other units.

In certain embodiments, resources (e.g., multipliers, adders, rounders, and/or memory) of a particular hardware engine (e.g, the FFT unit 225) may be shared for multiple standards (e.g., DVB-H, DMB, and ISDB-T). Resources (e.g., multipliers, adders, rounders, and/or memory) of a particular hardware engine (e.g, the carrier frequency offset unit 230) may also be different for each standard. For a particular device, some resources may be shared among different standards, while other resources are allocated to particular standards. Although certain units (e.g., symbol synchronization unit 220, equalizer unit 235) may be described broadly as a “hardware engine,” the components that make up the unit may be referred to hardware engines, as well. For example, a time-domain interpolation unit and frequency-domain interpolation unit in the equalizer unit 235 could each be referred to individually as a hardware engine.

Returning to the description of the data path, the digitized signal from the A/D unit 215 is received by the symbol synchronization unit 220, where the signal is grouped into symbols with a symbol boundary properly identified, and the guard periods (typically cyclic prefix) removed. The signal is provided to FFT unit 225, where it is transformed to the frequency domain. The signal is then forwarded to the carrier frequency offset unit 230, where the frequency offset of the signal is corrected (e.g., integer and fractional). The functions of carrier frequency offset unit 230 and symbol synchronization unit 220 may be performed before and/or after the FFT is performed in other embodiments.

The signal is then processed by the equalizer unit 235. In one embodiment, the equalizer unit 235 processes the signal in the frequency domain. With orthogonality, a frequency-domain equalizer can be implemented separately for each sub-carrier. Since the symbols are separated by some guard time period, the inter-symbol-interference (ISI) may be avoided. Hence, such an equalization simply becomes a one-tap complex scaling. This complex tap coefficient can be determined adaptively through training, and may be updated during data transmission. In other embodiments, other equalizer functions and steps may be performed, for a range of standards. Engines of the equalizer unit 235 may be configured to share some resources among multiple standards, while for other functions certain engines only process a single standard or subset of standards.

The equalized data is de-interleaved at the de-interleaver unit 240, and in some embodiments some additional processing is performed (e.g., Viterbi, de-puncturing). The decoder unit 245 performs error detection and correction to produce a stream of data. The data from the decoder unit 245 is forwarded to an additional processor unit 255 (e.g., an on chip CPU or a host processor) for further processing.

1. Multi-Mode Architecture: As noted above, in certain embodiments, resources (e.g., multipliers, adders, rounders, and/or memory) of a particular hardware engine may be shared for multiple standards (e.g., DVB-H, DMB, ISDB-T, MediaFLO, etc). The resources of a particular hardware engine used for each standard may also be different (e.g., each standard may have a different set of resources allocated). For a particular device, therefore, certain resources may be shared among different standards, while other resources are allocated to particular standards or subsets of standards. The following descriptions are illustrative of these concepts, but are for purposes of example only.

These resource sharing techniques may be used, for example, for the device 105 described with reference to FIG. 1 or 2, or in a range of other MDTV devices. A stream of data representative of a digitized version of a wireless communication signal may be received at a device 105. A first set of hardware engines processing the stream may be configured to use the same set of hardware resources to process a received data signal transmitted according to each of a number of different standards. A second set of hardware engines may be configured to receive this data and use different subsets of hardware resources to receive and process the streams of data generated from the first set of hardware engines, depending on the applicable standard. In addition, particular regions of memory may be shared by different hardware engines or resources therein, leveraging a design wherein aspects of processing occurring at certain engines will not overlap in time.

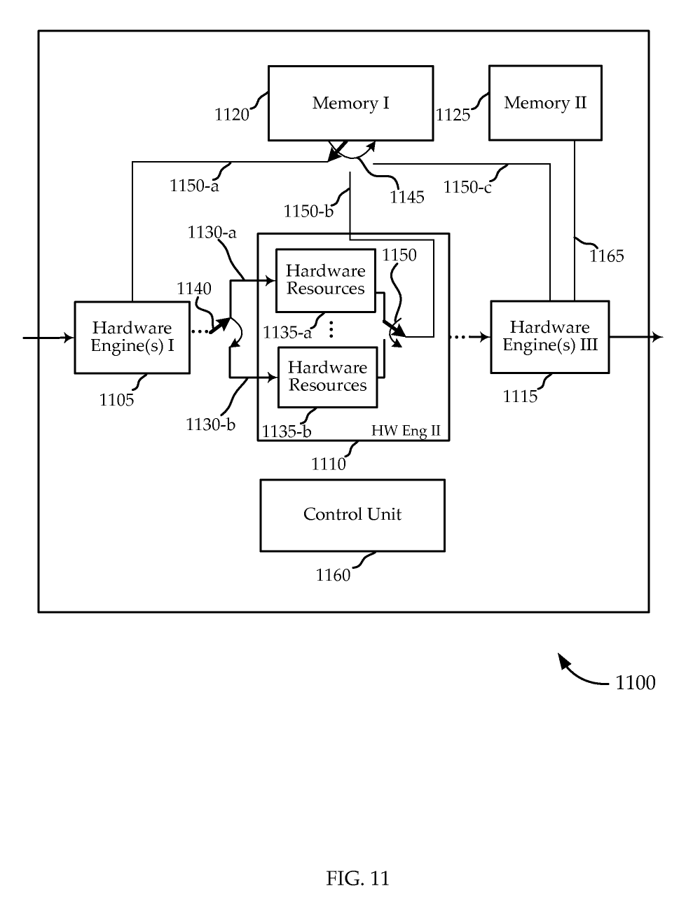

Referring first to FIG. 11, a block diagram is shown illustrating a processor 1100 including an example architecture for resource sharing for of hardware engines 1105, 1110, 1115 configured to process a signal transmitted according to a number of different mobile digital video standards. The processor 1110 may be the hardware block 265 of FIG. 2, and thus the hardware engines 1105, 1110, 1115 may each be a hardware engine of FIG. 2, such as a symbol synchronization unit 220, FFT unit 225, carrier frequency offset unit 230, equalizer unit 235, de-interleaver unit 240 or decoder unit 245, or may be any combination or subset thereof. This processor 1100 also includes two distinct memory regions 1120, 1125, along with other memory (not shown). This processor 1100 may be used to perform the functionality of the device 105 of FIG. 1 or 2, although the illustrated configuration may be also utilized in a number of different processors or devices.

For purposes of explanation, first assume the hardware engines are each operating to process a stream of data representative of the wireless communication signal. The digitized version of a wireless communication signal is received at the first set of hardware engine(s) 1105 (perhaps after being received and digitized by analog processing units (not shown)). This first set of engines 1105, in some embodiments, are configured to use the same set of hardware resources to process transmissions from each of a number of different standards (e.g., ISDB-T, DMB, or DVB-H). In one embodiment, the first set of hardware engine(s) 1105 includes the initial sync functions of the symbol synchronization unit 220 of FIG. 2. The first set of hardware engine(s) 1105 may be allocated exclusive use of a region of memory 1120.

The device also includes a control unit 1160, which may be the supervisory block 250 of FIG. 2. Some of the functionality described for the control unit 1160 may also be performed by an on or off chip processor, such as the additional processing unit 255 of FIG. 2. The control unit 1160 may be configured to selectively control the data flow between hardware engines 1105, 1110, and 1115. The control unit 1160 may also be configured to selectively control the data flow between hardware engines 1105, 1110, and 1115 and memory 1120, 1125. Although the example processor shows three sets of hardware engines and two distinct memory regions, in other embodiments, there may be any number of hardware engines and other components (e.g., other memory, analog processing units, etc.) individually or collectively controlled by control unit 1160. The control unit 1160 may be configured to dynamically switch power to each set of engines or each memory on or off in response to monitored flow of the stream of data through the processor, functionality that will be described in more detail below.

A second set of one or more hardware engine(s) 1110, in some embodiments, are configured to use different subsets of hardware resources to process different standards (e.g., one distinct subset for ISDB-T, one distinct subset for DMB, and one distinct subset DVB-H). In the second set of engines 1110 of the illustrated embodiment, a first subset of hardware resources 1135-a is allocated to process a first standard, while a second, physically distinct subset of hardware resources 1135-b is allocated to process a second standard. Other processors may include more distinct subsets of hardware resources to process other standards.

The control unit 1160 may identify, or receive an identification of, the particular standard (e.g., ISDB-T, DMB, or DVB-H) that was used to transmit the received signals. The control unit 1160 may, then, control a switch 1140 to direct the stream of data from the first set of hardware engine(s) 1105 to a data path 1130-a or 1130-b directed at the applicable hardware resources 1135-a or 1135-b of the second set of hardware engine(s) 1110 configured to process the identified standard. The stream of data may, but need not, be processed further by other engines or components between the first set of hardware engine(s) 1105 and the second set of hardware engine(s) 1110.

The control unit 1160 may also monitor the data flow, and receive or generate a signal indicating that processing for mobile digital broadcast video signals is complete (perhaps only temporarily) at the first set of hardware engine(s) 1105. For example, the control unit 1160 may receive data (e.g., from a downstream engine) indicating that data stored in memory 1120 for the first set of hardware engine(s) 1105 has been retrieved or released from the memory 1120. The control unit 1160 may, then, control a switch 1145 to change the active data path 1150-a from between the first set of hardware engine(s) 1105 and memory 1120 to a data path 1150-b between the second set of hardware engine(s) 1110 and memory 1120. Thus, in one embodiment, the memory may be allocated for use to the first set of hardware engine(s) 1105 during a first portion of a period of time and then re-allocated to the second set of hardware engine(s) 1110 for a next portion of a period of time, but both would not be allowed to use the memory at the same time (e.g., the allocation may be for periods of exclusive use).

In addition, control unit 1160 may control a switch 1150 dictating the proper source data flow from the second set of hardware engine(s) 1110 to memory 1120 (e.g., switching the data path to the output for the distinct hardware resources applicable to the identified standard). Thus, memory 1120 may be shared by distinct sets of hardware resources performing the same or similar function according to different standards (e.g., resources of the carrier frequency offset unit 230 or the equalizer unit 235 applicable to each standard). Said differently, the control unit 1160 may be configured to communicatively couple the first subset of hardware resources 1135-a with the memory 1120 when the first standard is being processed, and communicatively couple the second subset of hardware resources 1135-b with the memory 1125 when the second standard is being processed. In various embodiments, therefore, a memory architecture is designed for hardware engines to share memory 1120 based, at least in part, on the conclusion that certain resources will not need a particular memory at overlapping times.

A third set of one or more hardware engine(s) 1115 are, in some embodiments, again configured to use a common set of hardware resources to process each different standard (e.g., ISDB-T, DMB, or DVB-H). The first and second subsets of hardware resources 1135-a, 1135-b of the second set of one or more engine(s) 1110 are each configured to generate a processed stream of data to be forwarded to the same set of hardware resources at the third set of engine(s) 1115. The stream of data may, but need not, be processed further by other engines or components between the second set of hardware engine(s) 1110 and the third set of hardware engine(s) 1115. This shared set of hardware resources in the third set of engine(s) 1115 may be a decoder configured to perform RS decoding on physical layer packets for each particular standard (e.g., ISDB-T, DMB, or DVB-H).

The control unit 1160 may also monitor the data flow, or otherwise receive data (e.g., from a downstream engine) indicating that certain memory 1120 allocated for the second set of hardware engine(s) 1105 is not being used because the memory is allocated for a standard other than the one being processed (or that data in memory 1120 has been retrieved or otherwise released). The control unit 1160 may control a switch 1145 to change the active data path 1150-b from between the second set of hardware engine(s) 1110 and memory 1120 to a data path 1150-c between the third set of hardware engine(s) 1115 and memory 1120.

In one embodiment, the memory 1120 is allocated for use by the third set of hardware engine(s) 1115 for storage of a processed mobile digital broadcast video signal according to a particular standard, and not other standards. A second region of memory 1125 is allocated for use by the third set of one or more hardware engine(s) 1115 for storage of a processed mobile digital broadcast video signal according to a number of standards. Consider, for example, an embodiment where we assume that the third set of engine(s) 1115 is functioning as decoder unit 245 using the shared set of resources for decoding functionality (e.g., performing physical layer packet decoding and DVB-H link layer decoding). The third set of engine(s) 1115 may use memory 1120 for DVB-H link layer frame buffering. Thus, this memory 1120 may still be used for storage for other standards (e.g., being used by the de-interleaver for storage of ISDB signals). When the control unit 1160 has identified the stream as a DVB-H stream, the control unit 1160 may control a switch 1145 to change the active data path to data path 1150-c between the third set of hardware engine(s) 1115 and memory 1120. A different memory 1125 region may be allocated for buffering of physical layer packets for each of the standards for the third set of hardware engine(s) 1115 across data path 1165. The control unit 1160 may arbitrate access to each memory 1120, 1125 by the third set of hardware engine(s) 1115.

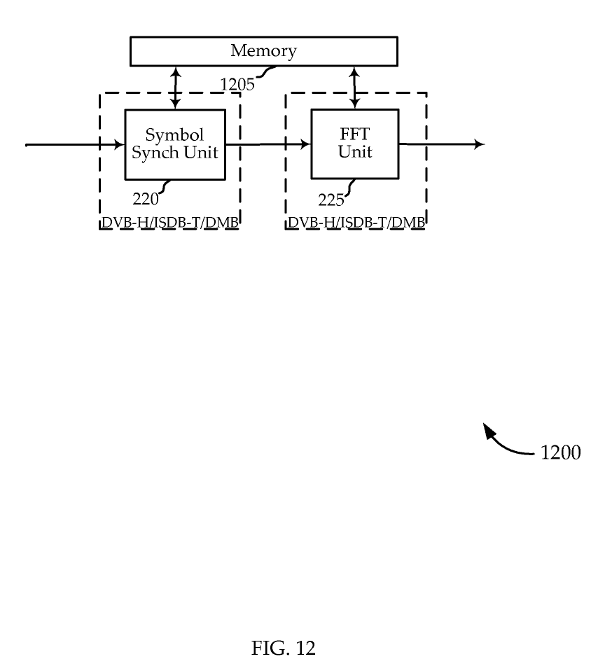

Referring to FIG. 12, a block diagram illustrates a resource-sharing configuration 1200 according to an embodiment of the invention. This configuration 1200 includes a symbol synchronization unit 220 and an FFT unit 225, which may be implemented in the device 105 of FIG. 1 or 2, the processor 1100 of FIG. 11, or in other devices or processors. The symbol synchronization unit 220 and FFT unit 225 may have the same functionality as described with reference to FIG. 2. The symbol synchronization unit 220 and FFT unit 225 may, individually or in combination, represent one of the sets of hardware engines 1105, 1110, 1115 of FIG. 11. In one embodiment, certain resources (e.g., multipliers, adders, and rounders) making up the symbol synchronization unit 220 are allocated to performing symbol synchronization, and do not perform FFT processing. These resources may together process signals received via DVB-H, ISDB-T, or DMB, and are thus shared by the different standards.

Similarly, certain resources (e.g., multipliers, adders, and rounders) making up the FFT unit 225 are allocated to performing fast fourier transform operations, and do not perform symbol synchronization processing. These resources may together process signals received via DVB-H, ISDB-T, or DMB, and are thus shared by the different standards. This configuration 1200 also includes memory 1205. This memory 1205 may be memory shared by both the symbol synchronization unit 220 and FFT unit 225. Thus, in some embodiments data stored in a given physical location in memory may be processed by both the symbol synchronization unit 220 and FFT unit 225. In one embodiment, the memory 1205 is not shared with the other units (e.g., carrier frequency offset unit 230, equalizer unit 235, de-interleaver unit 240, decoder unit 245) of the device 105. In another embodiment, data in a given physical location in memory may be allocated to buffering for certain tasks of either the symbol synchronization unit 220 or the FFT unit 225, but not both at the same time. This sharing of resources may be applied to other hardware engines, as well.

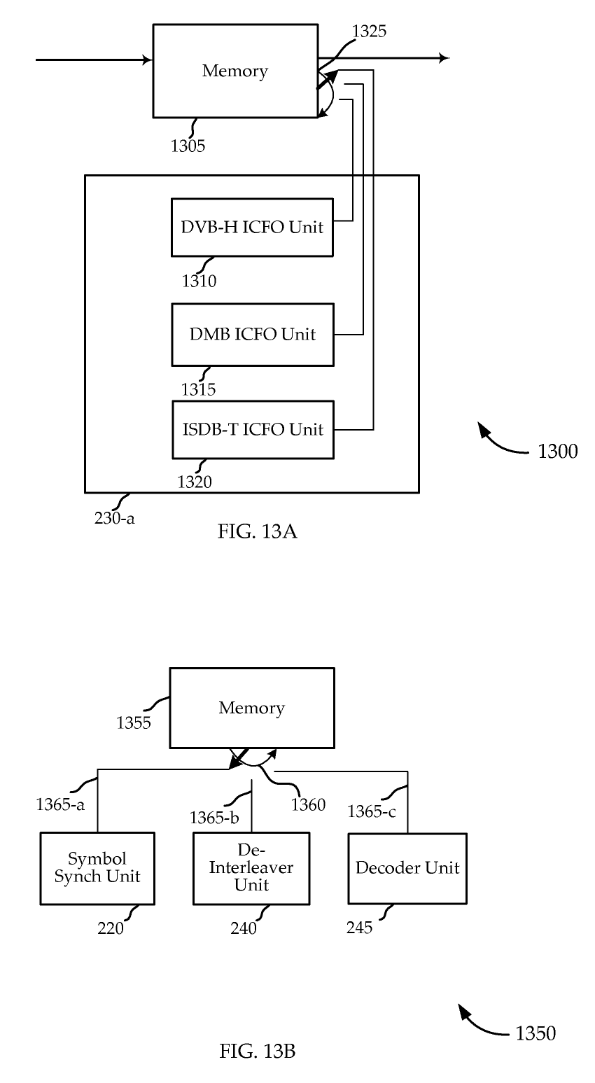

Referring next to FIG. 13A, a block diagram illustrates an example resource-sharing configuration 1300 according to an embodiment of the invention. This configuration illustrates a carrier frequency offset unit 230-a, which may be implemented in the device 105 of FIG. 1 or 2, the processor 1100 of FIG. 11, or in other devices or processors. The carrier frequency offset unit 230-a may have the same functionality as described with reference to carrier frequency offset unit 230 of FIG. 2. The carrier frequency offset unit 230-a may represent one of the sets of hardware engines 1105, 1110, 1115 of FIG. 11.

The carrier frequency offset unit 230-a of FIG. 13A includes a DVB-H integer carrier frequency offset (ICFO) unit 1310, a DMB integer carrier frequency offset (ICFO) unit 1315, and an ISDB-T integer carrier frequency offset (ICFO) unit 1320. In one embodiment, each of these units is a distinct hardware engine (a distinct region of hardware resources), configured to perform the integer carrier frequency offset processing for the relevant standard (but not the other standards). A control unit (not shown) may identify the standard to be used for data to be processed, activate the data path to the particular resources, and control the applicable unit (e.g., the DVB-H ICFO unit 1310, DMB ICFO unit 1315, or ISDB-T ICFO unit 1320) to perform the requisite processing.

Thus, the hardware resources (e.g., multipliers, adders, and rounders) making up the DVB-H ICFO unit 1310 are allocated for performing DVB-H ICFO processing, and are not shared with other functions or other standards. The hardware resources (e.g., multipliers, adders, and rounders) making up the DMB ICFO unit 1315 are allocated for performing DMB ICFO processing, and are not shared with other functions or other standards. The hardware resources (e.g., multipliers, adders, and rounders) making up the ISDB-T ICFO unit 1320 are allocated for performing ISDB-T ICFO processing, and are not shared with other functions or other standards. In other embodiments, some of these different standards and functions could be performed by shared resources.

Each of the units 1310, 1315, 1320 may share a common memory 1305. In one embodiment, the memory 1305 may be shared by only the DVB-H ICFO unit 1310, DMB ICFO unit 1315, and ISDB-T ICFO unit 1320; alternatively, a portion the memory 1305 may be shared with other components of the carrier frequency offset unit 230-a, or perhaps with an equalizer unit 235, as well. In one embodiment, a switch 1325 activates a data path between the memory 1305 and the applicable unit 1310, 1315, 1320, while deactivating the data path to the other units.

Referring next to FIG. 13B, a block diagram illustrates an example resource-sharing configuration 1350 according to another embodiment of the invention. This configuration illustrates how a symbol synchronization unit 220, de-interleaver unit 240, and decoder unit 245 may be allocated exclusive use of a particular memory 1355 region. This configuration 1350 may be implemented in the device 105 of FIG. 1 or 2, the processor 1100 of FIG. 11, or in other devices or processors. The symbol synchronization unit 220, de-interleaver unit 240, and decoder unit 245 may have the same functionality as described with reference to FIG. 2. The symbol synchronization unit 220, de-interleaver unit 240, and decoder unit 245 of FIG. 13B may, individually or in combination, represent one of the sets of hardware engines 1105, 1110, 1115 of FIG. 11.

In the illustrated embodiment, a particular region of memory 1355 may be allocated for certain specific storage functionality. Each processing unit 220, 240, 245 may be allocated exclusive use of the memory region for certain time periods. The memory may be allocated to the symbol synchronization unit 220 for the initial synchronization operations to acquire the signal. A notification may then be received or generated indicating that processing for mobile digital broadcast video signals is complete for the initial synchronization phase (e.g., indicated by a signal generated by the control unit 1160 of FIG. 11 monitoring data flow or by a downstream engine).

The signal may be identified as an ISDB signal. The switch 1360 may change the data path 1365-a from between the symbol synchronization unit 220 and memory 1355 to a data path 1365-b between the de-interleaver unit 240 and memory 1355. The memory may be allocated to the de-interleaver unit 240 for certain ISDB de-interleaver operations related to segmentation. Alternatively, the signal may be identified as a DVB-H signal. The switch 1360 may change the data path 1365-a from between the symbol synchronization unit 220 and memory 1355 to a data path 1365-c between the decoder unit 245 and memory 1355. FIGS. 13A and 13B illustrate different embodiments wherein exclusive memory use can be shared across modes, and across time.

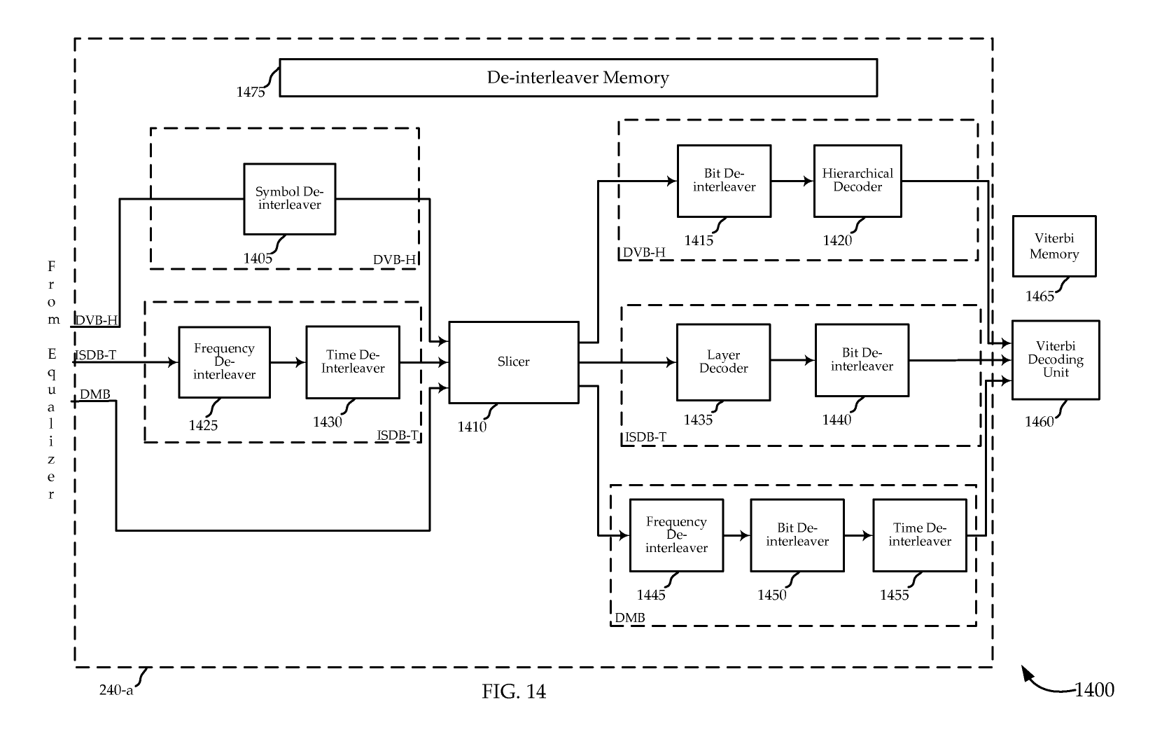

Referring next to FIG. 14, a block diagram illustrates a resource-sharing configuration 1400 according to an embodiment of the invention. This configuration illustrates de-interleaver unit 240-a, which may be implemented in the device 105 of FIG. 1 or 2, or in other devices. The de-interleaver unit 240-a may have the same functionality as described with reference to de-interleaver unit 240 of FIG. 2. The de-interleaver unit 240-a may represent one of the sets of hardware engines 1105, 1110, 1115 of FIG. 11.

De-interleaver unit 240-a is configured to process wireless signals transmitted according to the DVB-H, ISDB-T, or DMB standards. In other embodiments, configurations may process a signal from more, fewer, or different standards. In the illustrated embodiment, signals are received from an equalizer, and the applicable standard is identified (e.g., by the supervisory block 250, an on chip CPU, a host processor, or other controller).

For the DVB-H standard, the data is first passed through a symbol de-interleaver 1405. The resources (e.g., multipliers, adders, and rounders) making up the symbol de-interleaver 1405 are allocated for performing DVB-H symbol de-interleaving, and are not shared with other functions or other standards. The DVB-H data is then passed through a slicer 1410. Resources (e.g., multipliers, adders, and rounders) making up the slicer 1410 are allocated to performing slicer functions, and do not perform other processing functions. These resources may, however, process data received via DVB-H, ISDB-T, or DMB standards, and the slicer 1410 is therefore shared by the different standards.

The DVB-H data is then passed through a bit de-interleaver 1415 and a hierarchical decoder 1420. The resources (e.g., multipliers, adders, and rounders) making up the bit de-interleaver 1415 and hierarchical decoder 1420 are respectively allocated for performing bit de-interleaving and hierarchical decoding for DVB-H, and are not shared with other functions or other standards. The DVB-H data is then passed through a Viterbi decoding unit 1460. Resources (e.g., multipliers, adders, and rounders) making up the Viterbi decoding unit 1460 are allocated to performing Viterbi functions, and do not perform other processing functions. These resources may process data received via DVB-H, ISDB-T, or DMB standards, and the Viterbi decoding unit 1460 is, therefore, shared by the different standards.

Turning to the ISDB-T data, the data from the equalizer is first passed through a frequency de-interleaver 1425 and time de-interleaver 1430. The resources making up the frequency de-interleaver 1425 and time de-interleaver 1430 are respectively allocated for performing ISDB-T frequency and time de-interleaving, and are not shared with other functions or other standards. The ISDB-T data is then passed through the slicer 1410 (shared among standards).

The ISDB-T data is then passed through a layer decoder 1435 and bit de-interleaver 1440. The resources making up the layer decoder 1435 and resources making up the bit de-interleaver 1440 are respectively allocated for performing layer decoding and bit de-interleaving for ISDB-T, and are not shared with other functions or other standards. The ISDB-T data is then passed through a Viterbi decoding unit 1460 (shared among standards).

Turning to the DMB signals, the DMB data from the equalizer is first passed through the slicer 1410 (shared among standards). The DMB data is then passed through a frequency de-interleaver 1445, a bit de-interleaver 1450, and a time de-interleaver 1455. The resources making up the frequency de-interleaver 1445 are allocated for performing DMB frequency de-interleaving, and are not shared with other functions or other standards. Similar allocations of resources are made for the DMB bit de-interleaver 1450 and time de-interleaver 1455. The DMB data is then passed through a Viterbi decoding unit 1460 (shared among standards).

Thus, the de-interleaver 240-a illustrates that hardware engines may use different subsets of hardware resources to process signals transmitted according to different standards at a first stage, and then use a common set of hardware resources (e.g., the slicer 1410) to process data generated from different subsets of hardware resources during a second stage, then again use different subsets of hardware resources to process a signal transmitted according to different standards in a third stage. The processing units (1405-1455) making up the de-interleaver may share a common de-interleaver memory 1475. Thus, data stored in a given physical location in memory may be processed by each of these components, but not other components not part of the de-interleaver 240-a. Thus, the de-interleaver memory 1475 may be physically distinct from the Viterbi memory 1465 allocated to the Viterbi decoding unit 1460. In other embodiments, memory for certain processing units (1405-1455) may be separated.

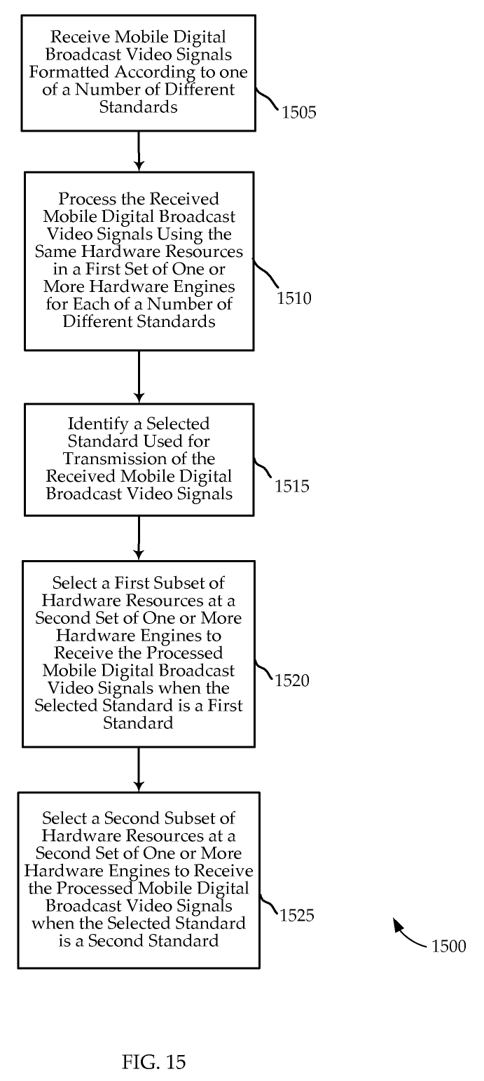

FIG. 15 is a flowchart illustrating a method 1500 of processing mobile digital broadcast video signals according to various embodiments of the invention. The method 1500 may, for example, be performed in whole or in part with the device 105 of FIG. 1 or 2, or the processor 1100 of FIG. 11.

At block 1505, mobile digital broadcast video signals, formatted according to one of a number of different standards, are received. At block 1510, the received mobile digital broadcast video signals are processed, wherein the same hardware resources in a first set of one or more hardware engines are used for each of a number of different standards. At block 1515, a selected standard (e.g., DVB-H, DMB, ISDB-T) used for transmission of the received mobile digital broadcast video signals is identified. At block 1520, a first subset of hardware resources at a second set of one or more hardware engines is selected to receive the processed mobile digital broadcast video signals if the selected standard is a first standard. At block 1525, a second subset of hardware resources at a second set of one or more hardware engines is selected to receive the processed mobile digital broadcast video signals if the selected standard is a second standard.

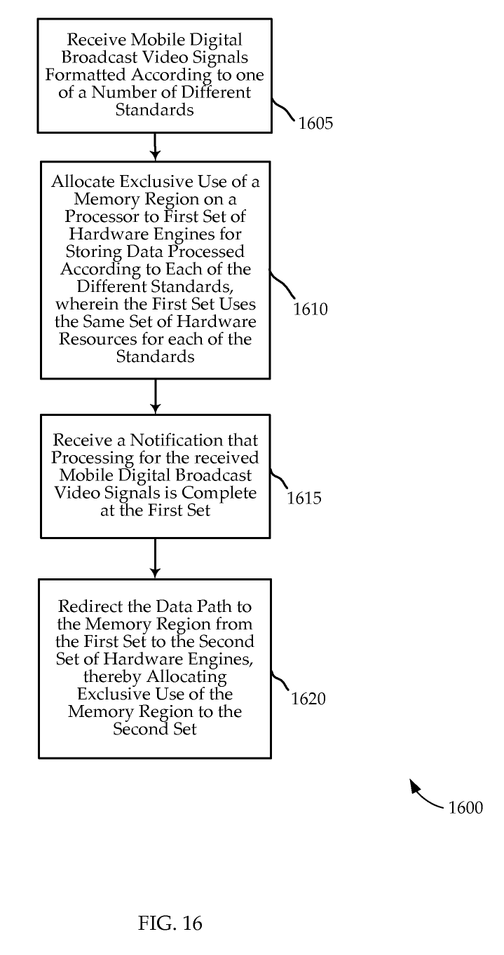

FIG. 16 is a flowchart illustrating an alternative method 1600 of processing mobile digital broadcast video signals according to various embodiments of the invention. The method 1600 may, for example, be performed in whole or in part with the device 105 of FIG. 1 or 2, or the processor 1100 of FIG. 11.

At block 1605, mobile digital broadcast video signals formatted according to one of a number of different standards are received. At block 1610, exclusive use of a memory region on a processor is allocated to a first set of hardware engines for storing data processed according to each of the different standards, wherein the first set of engines uses the same set of hardware resources for each of the standards. At block 1615, a notification is received that processing for the received mobile digital broadcast video signals is complete at the first set. At block 1620, the data path to the memory region is redirected from the first set to the second set of hardware engines, thereby allocating exclusive use of the memory region to the second set. In one embodiment, a first subset of hardware resources of the second set is configured to receive and process data according to a first standard and a second subset of hardware resources, distinct from the first subset, is configured to receive and process the data according to a second standard. Each distinct subset will, in one embodiment, use the allocated memory region when that standard is being processed.

The preceding description is for purposes of example. They illustrate how resources (e.g., multipliers, adders, rounders, and/or memory) of a particular hardware engine or component thereof may be shared for multiple standards (e.g., DVB-H, DMB, and ISDB-T). Also, resources (e.g., multipliers, adders, rounders, and/or memory) of a particular hardware engine may be different for certain standards in certain embodiments. For a particular device, some resources may be shared among different standards, while other resources are allocated to particular standards. Also, for a given device, processing units may be hardware engines allocated to performing a certain function or functions. Nonetheless, certain resources (e.g., memory) may be shared among different hardware engines on the device.

2. Power Management: In a number of embodiments, time slicing and similar time-multiplexing techniques are used. Selected hardware engines, or components thereof, may be configured to perform limited operations between bursts. Specifically, the clock signals or power may be applied for only limited periods of time (e.g., when processing a burst or time slice and during any prewake (warm-up) period).

These power management techniques may be used, for example, for the device 105 described with reference to FIG. 1 or 2, or in a range of other MDTV devices. A stream of data representative of a digitized version of a wireless communication signal may be received at a device. The hardware engines processing the stream of data may be monitored. There may be an identification (e.g., a generated signal) when a burst of data within the stream is complete at certain monitored hardware engines, while the processing for the burst continues at other engines. Power may be withheld to the identified engines (e.g., by not applying clock signals or by powering off such engines) in response to the identification, while power continues to be provided to the continued processing of the burst.

In another embodiment, consider an example when power is withheld to each of a number of hardware engines. The stream of data may be monitored to determine when a next burst will be available for processing at each of the hardware engines. A start-up time for each engine may be identified based on the determination as to when the next burst will be available for processing at each respective engine. Power may then be applied to selected hardware engines according to the identified start-up time, while power remains withheld to others with a later start-up time.

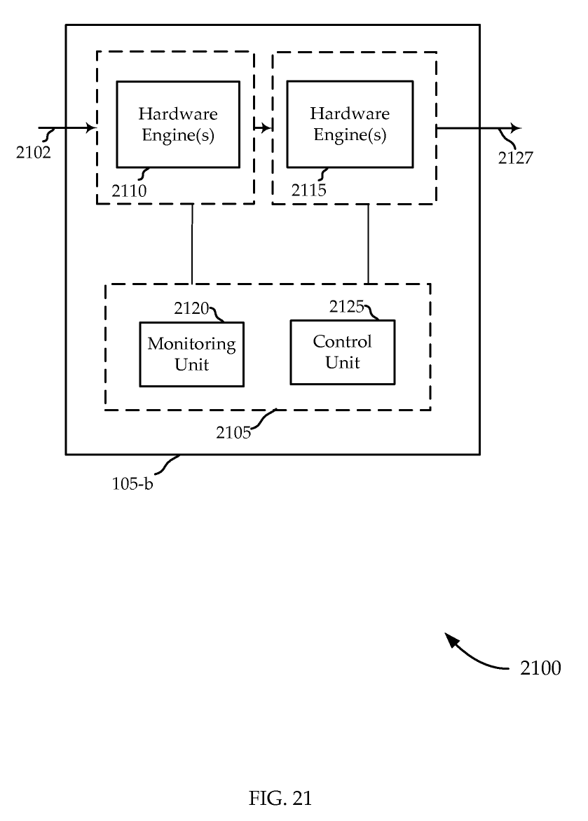

Referring first to FIG. 21, a block diagram 2100 is shown illustrating a device 105-b including an example configuration for selectively controlling power to sets of one or more hardware engines 2110, 2115. This device 105-b may represent the device 105 of FIG. 1 or 2, although the illustrated configuration may be utilized in a number of different processors or devices. A digitized version of a wireless communication signal 2102 is received at the first set of hardware engine(s) 2110 (perhaps after being received and digitized by analog processing units (not shown).

For purposes of explanation, first assume the hardware engines are each operating to process a stream of data representative of the wireless communication signal transmitted according to the DVB-H standard (while noting that the principles herein may be applied to standards with a more constant/less bursty transmission by buffering and accumulating data at some point before or within the series of hardware engines, creating a delayed burst). The hardware engines may each be a hardware engine of FIG. 2, such as symbol synchronization unit 220, FFT unit 225, carrier frequency offset unit 230, equalizer unit 235, de-interleaver unit 240 or decoder unit 245, or may be any combination or subset thereof.

The device also includes a controller 2105, which may be the supervisory block 250 of FIG. 2, the additional processing unit 255 of FIG. 2, a combination thereof, or another processor. The controller 2105, or particular components thereof, may be configured to selectively control power to each set of hardware engines 2110, 2115. Although the example device 105-b shows two sets of hardware engines, in other embodiments, there may be any number of hardware engines and other components (e.g., other memory, analog processing units, etc.) individually or collectively controlled by controller 2105. The controller 2105 may include a monitoring unit 2120 and a control unit 2125. The controller 2105 may be configured to dynamically switch power to each engine or set of engines on or off in response to monitored flow of the stream of data through the device 105-b.

The monitoring unit 2120 may, therefore, be configured to monitor processing of the stream of data through the hardware engines. The monitoring unit 2120 may also identify when processing for a burst of data (in this example, a time sliced burst of a received DVB-H transmission) within the stream of data is complete at the first set of hardware engine(s) 2110. This identification may be made up of the receipt or generation of an interrupt signal identifying completion of the burst processing. The control unit 2125 may withhold power to the first set of hardware engine(s) 2110 in response to the identification, while allowing power to the second set to continue processing of the second set of hardware engines 2115. The control unit 2125 may be configured to withhold power by withholding a clock signal or by powering off a selected one of the hardware engines 2110, 2115.

The control unit 2125 may determine whether there is sufficient time to withhold power and restart the first set of hardware engine(s) 2110 before the next burst is available for processing at the first set 2110, and base the power control decisions on this determination. The control unit 2125 may estimate a first warm-up period for the first set of hardware engine(s) 2110 applicable to reapplying a clock signal, and estimate a second warm-up period for these hardware engines 2110 applicable to powering on from a powered off state. The control unit 2125 may then determine whether to withhold a clock signal or power off the first set of hardware engines based on warm-up period estimates. It is worth noting that different hardware engines may also have different warm-up periods, and thus this analysis and the associated start-up time decisions may need to be made on a per engine basis.

In some instances, power may be withheld from both sets of hardware engines 2110, 2115. The control unit 2125 may monitor the stream of data to determine when a next burst will be available for processing at each set of hardware engines 2110, 2115. The control unit 2125 may identify a start-up time for each set of hardware engines 2110, 2115 based on the determination as to when the next burst will be available for processing at each set (and, perhaps based on the applicable warm-up period as well). The control unit 2125 may apply power (re-applying clock or powering on) to the first set of hardware engine(s) 2110 according to the identified start-up time, while withholding power to the second set 2115 associated with a later start-up time.

After processing by the second set of hardware engine(s) 2115, the data may be forwarded 2127 to another component or off of the device. In other embodiments, the functionality set forth for the monitoring unit 2120 may be integrated into other components, such as the control unit 2125 or other aspects of the controller 2105. The functions of the controller 2105 may, individually or collectively, be implemented with one or more Application Specific Integrated Circuits (ASICs) adapted to perform some or all of the applicable functions in hardware. Alternatively, the functions may be performed by one or more other processing units (or cores), on one or more integrated circuits. In other embodiments, other types of integrated circuits may be used (e.g., Structured/Platform ASICs, Field Programmable Gate Arrays (FPGAs), and other Semi-Custom ICs), which may be programmed in any manner known in the art. The functions may also be implemented, in whole or in part, with instructions embodied in a memory, formatted to be executed by one or more general or application-specific processors.

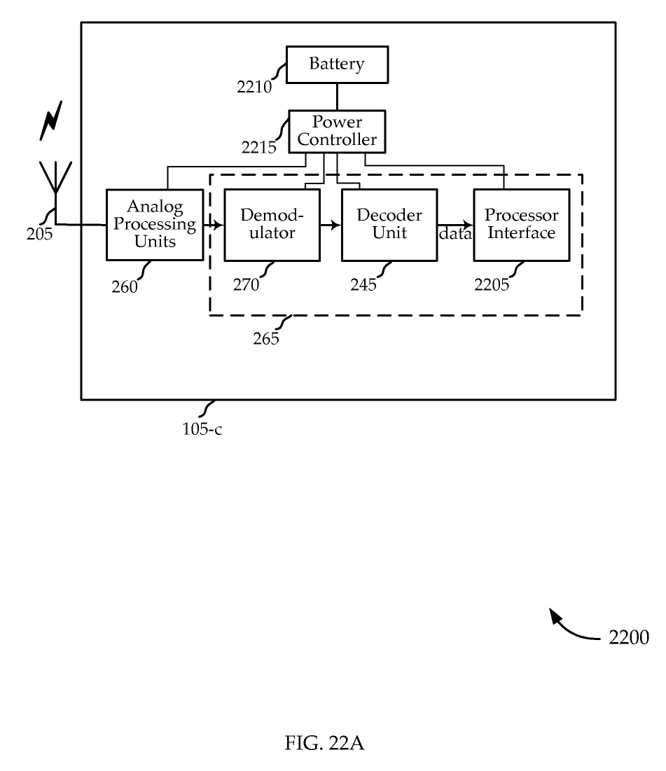

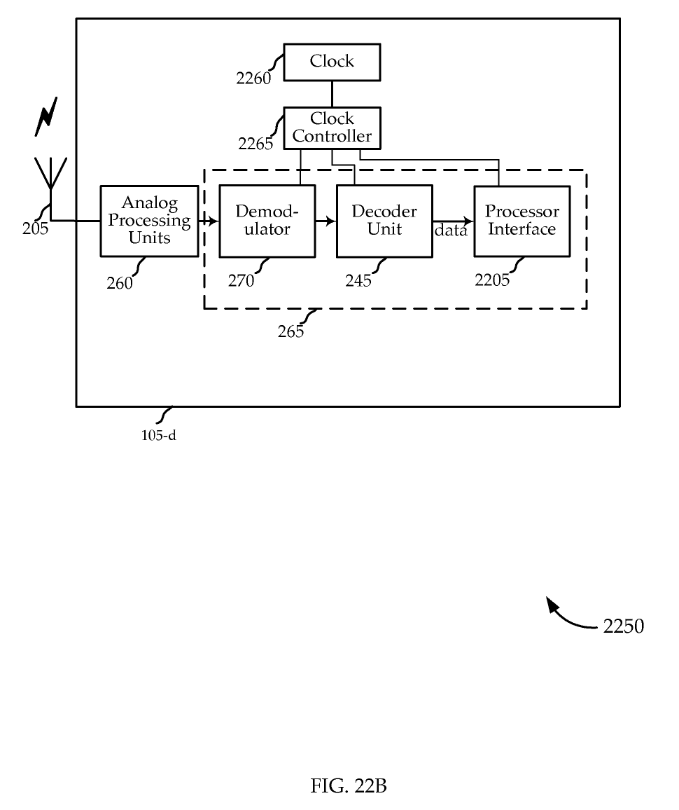

Therefore, as illustrated above, a device (for example, a mobile communications device or one or more processors therein) may be configured to selectively apply clocks and/or power to particular hardware engines. Referring next to FIG. 22A, a block diagram 2200 illustrates an example device 105-c which may be configured to provide power selectively to particular digital logic and interfaces. This illustrated device 105-c may be the device 105 of FIG. 1, 2, or 21.

The simplified block diagram shows a device 105-c including an antenna 205, analog processing units 260, demodulator 270, decoder unit 245, and processor interface 2205. The processor interface may be an interface between certain digital logic 265 and an additional processor (e.g., an on or off chip CPU or host processor, not shown). The demodulator 270 may be implemented with the hardware engines described with reference to FIG. 2, or other configurations may be used. In one embodiment, an RF signal is received via an antenna 205, and down-converted and digitized by the analog processing units 260. The digitized signals are processed by the demodulator 270, decoded by the decoder unit 245, and the decoded data is passed through the processor interface 2205 to an additional processor unit.

The device 105-c also includes a battery 2210 (or, perhaps, other power source) and a power controller 2215 configured to selectively power the analog processing units 260, demodulator 270, decoder unit 245, and processor interface 2205. The power controller 2215 may, for example, be the supervisory block 250 of FIG. 2, an on or off chip CPU, a host processor, the controller 2105 of FIG. 21, or any combination thereof. In one embodiment, assume that the analog processing units 260, demodulator 270, decoder unit 245, and processor interface 2205 are each being powered and processing data.

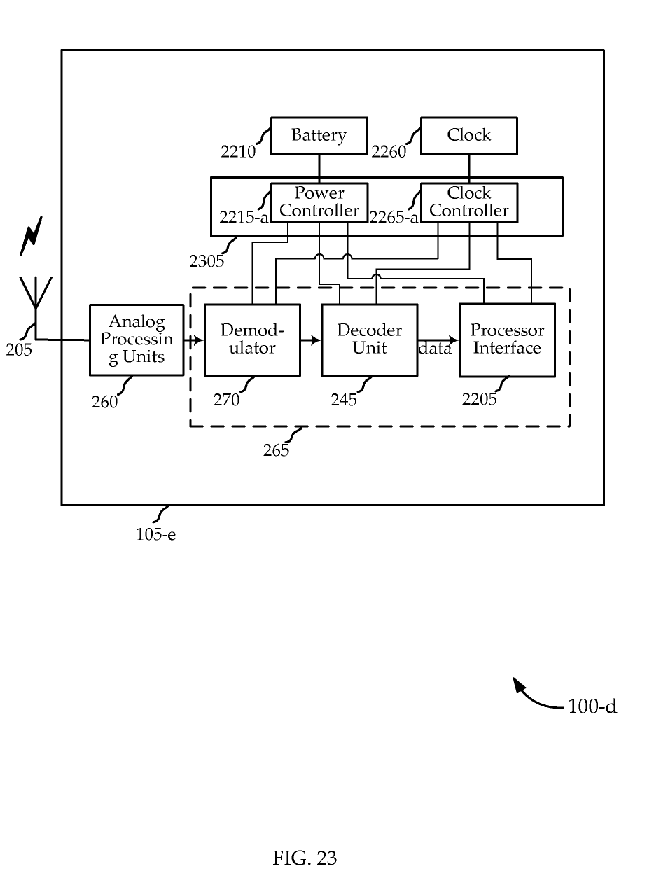

The demodulator 270, power controller 2215, or other monitoring device (not shown), may monitor the PHY layer processing within the demodulator 270 or other components, and generate an interrupt or other signal when the demodulator 270 has received all the data that is needed for a particular time slice or burst. The power controller 2215 determines if it can power down one or more components of the analog processing units 260. This may, for example, be done by assessing the time until the next burst. The power controller 2215 may be configured to power-off only if the power-off interrupt and the next burst start are separated, for example, by a certain minimum period of time. The power controller 2215 may be configured to power-off some or all of the analog processing units 260 when powering down. Note that this control over the analog processing units 260 may be applied to the device 105 of FIG. 22A or 23, although it is not specifically shown in those drawings.

The decoder unit 245, power controller 2215, or other monitoring device (not shown), may monitor the PHY and link layer processing at the decoder unit 245 or other components, and generate an interrupt or other signal when the decoder unit 245 has received all the data that is needed for a particular time slice or burst. The power controller 2215 determines if it can power down the demodulator 270 logic. This may, for example, be done by assessing the time until the next burst. The power controller 2215 may be configured to power-off only if the power-off interrupt and the next burst start are separated by a distance greater than a programmable threshold or an otherwise determined minimum period of time. The power controller 2215 may be configured to power-off some or all of the demodulator 270 logic when powering down.

The decoder unit 245, power controller 2215, or other monitoring device (not shown) may monitor the link layer processing at the decoder unit 245 or other components, and generate an interrupt or other signal when the decoder unit 245 has completed processing all the data that is needed for a time slice or burst. The power controller 2215 determines whether it should power down the decoder unit 245 logic. The power controller 2215 may be configured to power-off the decoder unit 245 only if the time of the next burst start is greater than a programmable threshold or an otherwise determined minimum time. The power controller 2215 may be configured to power-off some or all of the decoder unit 245 logic in appropriate circumstances.

When the data transfer to the additional processor is complete for a given burst or slice, the power controller 2215 determines if it can power down the processor interface 2205 by, for example, assessing the time until the next burst. When the demodulator 270, decoder unit 245, or processor interface 2205 is powered down, the power controller 2215 may be configured to save the current state in memory (not shown). The foregoing description provides an example of one power-down implementation only, and there are many alternative implementation options. For example, the power controller 2215 or other power management controller discussed herein may be configured to selectively apply power to only a subset of the engines of the demodulator 270, or only to a subset of the components of a particular engine.

Regarding power-up, a single counter or multiple counters may be used. In one single counter implementation, a single counter is loaded with a wakeup value at the end of a burst, as the intervals between bursts can vary. This counter decrements when it is non-zero, and saturates at zero. A prewake (warm-up) period is programmable to adjust the wakeup resolution. Thus, the counter may be set to go off at the beginning of a next burst, less a programmable warm-up period. When the counter reaches zero, the power controller reapplies power to the demodulator 270, decoder unit 245, and processor interface 2205

In another embodiment, a different counter could be used for each of the demodulator 270, decoder unit 245, and processor interface 2205. Each counter may be loaded with a wakeup value after the previous burst, directed to a wakeup for the particular component. The prewake (warm-up) period may be fixed or may be programmable to adjust the wakeup resolution. The wakeup resolution may be modified for each particular component. Thus, the counter may again be set to go off at the beginning of a next burst, less the warm-up period. There may be an additional delay added for the downstream components to account for processing time at the upstream components (e.g., the decoder unit 245 may be ready later than the demodulator 270 because it receives processed data from the demodulator 270). While counters are described in this embodiment, it is worth noting that other timer mechanisms may be used, as well.

Referring next to FIG. 22B, a block diagram 2250 illustrates an example device 105-d which may be configured to apply clocks selectively to particular digital logic and interfaces. This illustrated device 105-d may be the device 105 of FIG. 1, 2, 21, or 22A.

The simplified block diagram again shows a device 105-d including an antenna 205, analog processing units 260, demodulator 270, decoder unit 245, and processor interface 2205. These components may be configured largely in the same manner, and to perform the same functions, as described with reference to FIG. 22A. As above, an RF signal is received via an antenna 205, and down-converted and digitized by the analog processing units 260. The digitized signals are processed by the demodulator 270 and decoded by the decoder unit 245, and the decoded data is then passed through the processor interface 2205 to an additional processor unit (not shown).

The device 105-d also includes a clock unit 2260 (or, perhaps, other clock generation unit), and a clock controller 2265 configured to selectively apply clock signals to the demodulator 270, decoder unit 245, and processor interface 2205. The clock controller 2265 may, for example, be the supervisory block 250 of FIG. 2, an on or off chip CPU, a host processor, the controller 2105 of FIG. 21, or any combination thereof.

In one embodiment, assume that clock unit 2260 is being applied to each of the demodulator 270, decoder unit 245, and processor interface 2205. As discussed with reference to FIG. 22A, the PHY and link layer processing at the decoder unit 245 may be monitored and an interrupt or other signal generated when the decoder unit 245 has received all the data that is needed for a particular time slice or burst. The clock controller 2265 may determine if it should withhold application of the clock signal to the demodulator 270 logic by, for example, assessing the time until the next burst while factoring in a warm-up period. A similar monitoring and clock controller 2265 determination may be made when the decoder unit 245 has completed processing the data that is needed for a time slice or burst, and when data transfer to the additional processor is complete.

In some embodiments, the state of the demodulator 270, decoder unit 245, or processor interface 2205 is remembered once the clock controller 2265 withholds the application of their clock signals, without storage in memory. Regarding the reapplication of the clocks, the single counter or multiple counter configurations described with reference to FIG. 22A may be used, as may other timers. The factors to be used in determining whether and when the clock unit 2260 will be applied may be the same as those described for the device 105 of FIG. 21 or 22.

Referring next to FIG. 23, a block diagram illustrates an example device 105-e which may be configured to apply clocks and power selectively to particular digital logic and interfaces. This illustrated device 105-e may be the device 105 of FIG. 1, 2, 21, 22A, or 22B.

The simplified block diagram yet again shows a device 105-e including an antenna 205, analog processing units 260, demodulator 270, decoder unit 245, and processor interface 2205. These components may be configured largely in the same manner, and to perform the same functions as described with reference to FIG. 22A or 22B. As above, an RF signal is received via an antenna 205, and down-converted and digitized by the analog processing units 260. The digitized signals are processed by the demodulator 270, decoded by the decoder unit 245, the decoded data passed through the processor interface 2205 to an additional processor unit.

The device 105-e includes a battery 2210 (or, perhaps, other power source) and a power controller 2215-a configured to selectively power the demodulator 270, decoder unit 245, and processor interface 2205. The power controller 2215-a may, for example, be the supervisory block 150 of FIG. 1, an on or off chip CPU, a host processor, the controller 2105 of FIG. 21, the power controller 2215 of FIG. 22A, or any combination thereof. The device 105-e may also include a clock unit 2260 (or, perhaps, other clock generation unit), and a clock controller 2265-a configured to selectively apply clocks to the demodulator 270, decoder unit 245, and processor interface 2205. The clock controller 2265-a may, for example, be the supervisory block 150 of FIG. 1, an on or off chip CPU, a host processor, the controller 2105 of FIG. 21, the clock controller 2265 of FIG. 22B, or any combination thereof. The power controller 2215-a and the clock controller 2265-a may each have the power management functionality as described with reference to FIGS. 22A and 22B.

In one embodiment, the device 105-e includes a power management controller 2305, which encompasses both the power controller 2215-a and the clock controller 2265-a. Additionally, the power management controller 2305 may include additional functionality. For example, the power management controller 2305 may oversee the power controller 2215-a and the clock controller 2265-a to determine which controller will be applied. To do so, power management controller 2305 may assess the time between bursts and the warm-up period for one or more components, and allocate control of a component according to the assessment. For example, if a timing threshold or power savings is not sufficient to power off and on a component, there may still be sufficient time or savings to withhold clock application (as the withholding and application of the clock may take less time and have lower memory or power requirements). However, in instances where there may be more time available between bursts, the power controller 2215-a may be a better choice because of its ability to prevent leakage current.

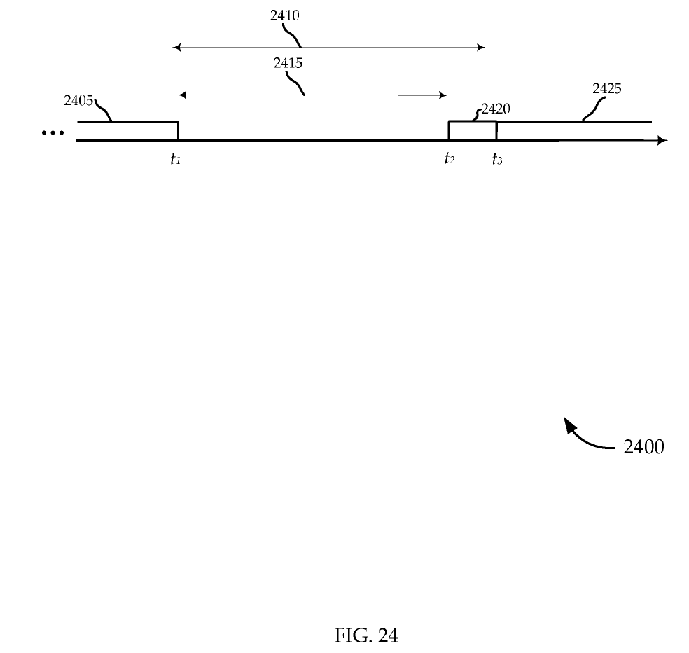

Referring next to FIG. 24, a diagram 2400 illustrates power management techniques to be applied to one or more hardware engines, or particular components thereof, in different embodiments. These may be the engines and components of the device 105 described with reference to FIG. 1, 2, 21, 22A, 22B, or 23, for example. Going from left to right in the diagram 2400 with regard to time, the diagram 2400 illustrates a first received burst 2405. The processing of the burst by the applicable engine or component ends at or about time t₁. At about time t₁, the selected hardware engine, or particular component thereof, is switched to a power saving mode (e.g., by powering down or withholding application of the clock as described above).

In one embodiment, the time between bursts 2410 is known. The power saving period 2415 (e.g., the time in which the engine(s) or component(s) are turned off or in which clocks are not applied) is determined. This may be based on the time interval between bursts, less a prewake (warm-up) period 2420. Because different engine(s) or component(s) may need different amounts of time to awake and resync, the prewake (warm-up) period 2420 may vary depending on the applicable engine(s) or component(s). Thus, a wakeup resolution may be modified for each particular engine(s) or component(s) for which individual power management techniques are being applied. After the power saving time 2415 has elapsed at or about time t₂, the power and then clock may be reapplied. After the prewake period 2420, the data 2425 is then processed beginning at or about time t₃.

It is worth noting that an estimate may be made or received as to a warm-up period for a particular hardware engine, the warm-up period applicable to reapplying a clock signal. An estimate may also be made as to a warm-up period applicable to powering on the particular hardware engine from a powered off state. The time of arrival of the next burst at the particular hardware engine is also received, estimated, or otherwise calculated. Using the warm-up period estimates and the estimated time of availability of the next burst, a determination may be made as to whether to: 1) withhold a clock signal from the particular hardware engine, 2) power off the particular hardware engine, or 3) not power down the particular hardware engine because there is not sufficient time between bursts or because the powering off would not result in sufficient (or perhaps any) power savings

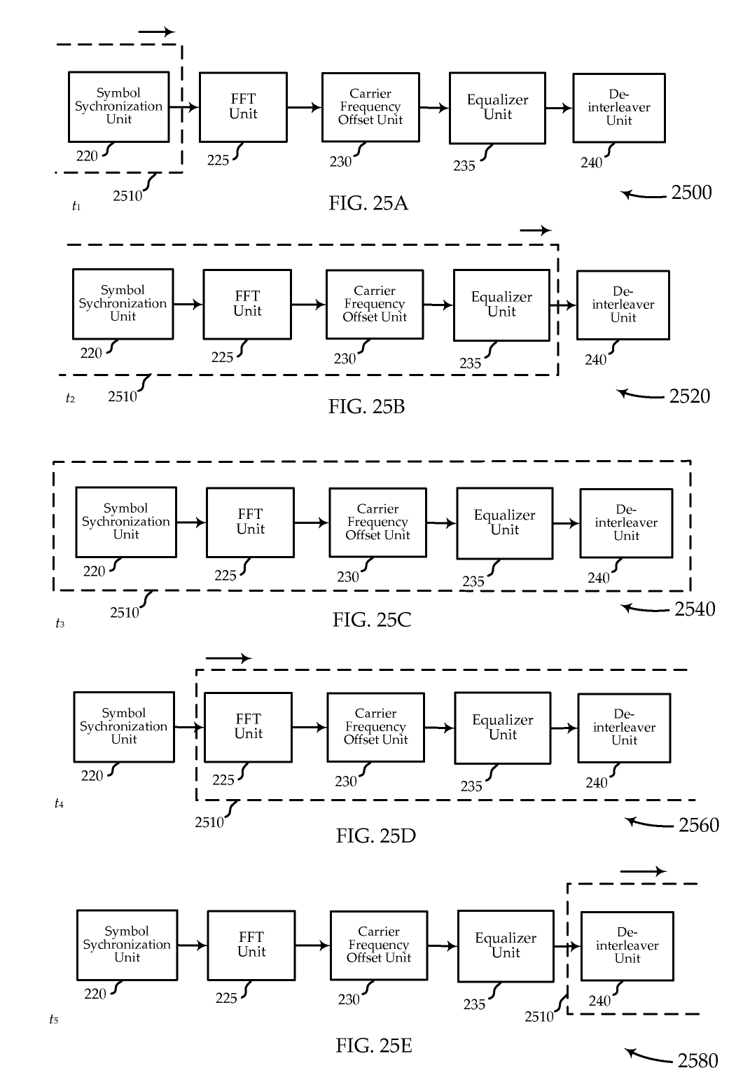

Referring next to FIGS. 25A-25E, an embodiment of the power management techniques set forth above is described. FIGS. 25A through 25E each include symbol synchronization unit 220, FFT unit 225, carrier frequency offset unit 230, equalizer unit 235, and de-interleaver unit 240 (e.g., from the device 105-a of FIG. 2). A controller (e.g., the controller 2105 of FIG. 21, power controller 2215 of FIG. 22A, clock controller 2265 of FIG. 22B, or controller 2305 of FIG. 23) may be configured to selectively control the application of power or clock signals to each of the symbol synchronization unit 220, FFT unit 225, carrier frequency offset unit 230, equalizer unit 235, and de-interleaver unit 240. As illustrated, this may allow for only selected engines to operate while data is processed (and during the warm-up attributed to each engine), and then return to power saving mode once processing for a burst or slice is completed.

Referring first to FIG. 25A, a dashed line 2510 in block diagram 2500 illustrates that, at time t₁, only the symbol synchronization unit 220 is receiving power and a clock signal. The remainder of the engines remain in power saving mode. As the processing progresses, the previously withheld power or clock signal will be applied to the FFT unit 225, carrier frequency offset unit 230, and equalizer unit 235, respectively. Referring to FIG. 25B, a dashed line 2510 in block diagram 2520 illustrates that, at time t₂, the clock signal or power is being withheld from only the de-interleaver unit 240. The processing progresses, and the power or clock signal is then applied to de-interleaver unit 240. Referring to FIG. 25C, a dashed line 2510 in block diagram 2540 illustrates that, at time t₃, the clock signal and power are being applied to each of the illustrated engines.

As the processing of the burst in this embodiment moves toward completion, an interrupt or other signal is generated when symbol synchronization unit 220 completes processing the burst. The power or clock signal, as applicable, is then withheld from the symbol synchronization unit 220. Referring to FIG. 25D, a dashed line 2510 in block diagram 2560 illustrates that, at time t₄, the clock signal or power is being withheld from only the symbol synchronization unit 220. The processing continues, and an interrupt or other signal is generated when the FFT unit 225, carrier frequency offset unit 230, equalizer unit 235, respectively, complete their processing of the burst. The power or clock signal, as applicable, is then withheld accordingly. Referring to FIG. 25E, a dashed line 2510 in block diagram 2580 illustrates that, at time t₅, the clock signal and power are being applied to only the de-interleaver unit 240. Once the de-interleaver unit 240 completes its processing for the burst, power or the clock signal may be withheld. It is worth noting that the foregoing example is for purposes of illustration, and the described power management techniques may be applied to a broader or narrower range of components.

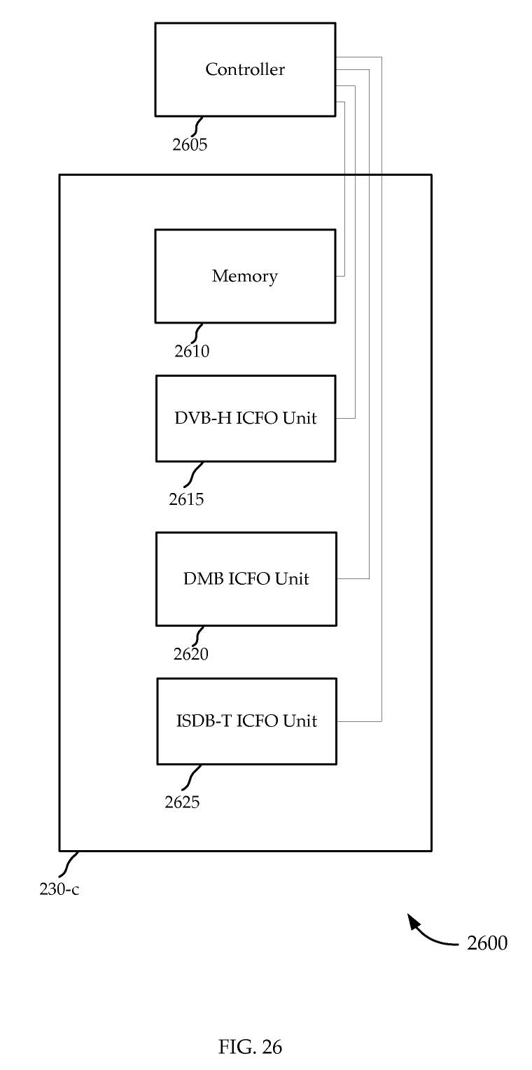

For example, referring next to FIG. 26, a block diagram shows an example power management configuration 2600 for a carrier frequency offset unit 230-c. This configuration 2600 may be implemented for the carrier frequency offset unit 130 from the device 105 of FIG. 1 or 2.

The carrier frequency offset unit 230-c of FIG. 26 includes a DVB-H integer carrier frequency offset (ICFO) unit 2615, a DMB integer carrier frequency offset (ICFO) unit 2620, and an ISDB-T integer carrier frequency offset (ICFO) unit 2625. In one embodiment, each of these units is a distinct hardware engine, configured to perform the integer carrier frequency offset processing for the relevant standard (but not the other standards). Each of units 2615, 2620, 2625 may share memory 2610. The memory 2610 may, in one embodiment, be shared by only the DVB-H ICFO unit 2615, DMB ICFO unit 2620, and ISDB-T ICFO unit 2625; alternatively, a portion the memory 2610 may be shared with other components of the carrier frequency offset unit 230-c, or perhaps only the FFT unit 225 and decoder unit 245 of FIG. 2, although a variety of configurations are possible.

The power management configuration 2600 also includes a controller 2605. The controller may, for example, be the controller 2105 of FIG. 21, power controller 2215 of FIG. 22A, the clock controller 2265 of FIG. 22B, or the controller 2305 of FIG. 23. Other controller configurations are possible (e.g., using supervisory block 250 or the additional processor 255 of FIG. 2), wherein power or clock signals may be applied selectively to the memory. In one embodiment, the controller 2605 may control the memory 2610, DVB-H ICFO unit 2615, DMB ICFO unit 2620, and ISDB-T ICFO unit 2625 independently. Therefore, the controller 2605 may determine or receive a determination that the device 100 is operating according to a particular standard (e.g., DVB-H). Upon making this determination, controller 2605 may power down or withhold clocks from the DMB ICFO unit 2620 and ISDB-T ICFO unit 2625.

Additionally, it is worth noting that the memory 2610 and each unit may have different prewake (warm-up) periods. Also, because the units may operate independently, the memory 2610 may continue to operate with power and clocks applied to store a DVB-H burst, while clocks or power are withheld from the DVB-H ICFO unit 2615. Although the foregoing examples relate to a carrier frequency offset unit 230-c, the controller 2605 may be configured to selectively control other components of a particular hardware engine (e.g., controlling memory or other selected engine components).

It is, therefore, worth noting that particular resources of a hardware engine may be configured with selective power control options. For example, a hardware engine including a first set of hardware resources and a second set of hardware resources may be monitored. When processing for a burst of data within the stream is complete or inactive at the first set of resources, a controller may generate or receive a signal indicating this inactivity. Various signals may be used to inform the controller whether this inactivity is due to completion of the processing or other inactivity. For example, certain resources may only be used in certain standards, modes, signal conditions, etc., and not in others. Thus, different resources may be powered on or off successively, or simply remain powered off in certain standards, modes, signal conditions, etc. Power may be withheld from certain hardware resources for a given engine, while providing power to the other resources of that engine (e.g., for processing of a burst). Alternatively, power may be applied to certain hardware resources for a given engine, while withholding power to the other resources of that engine.

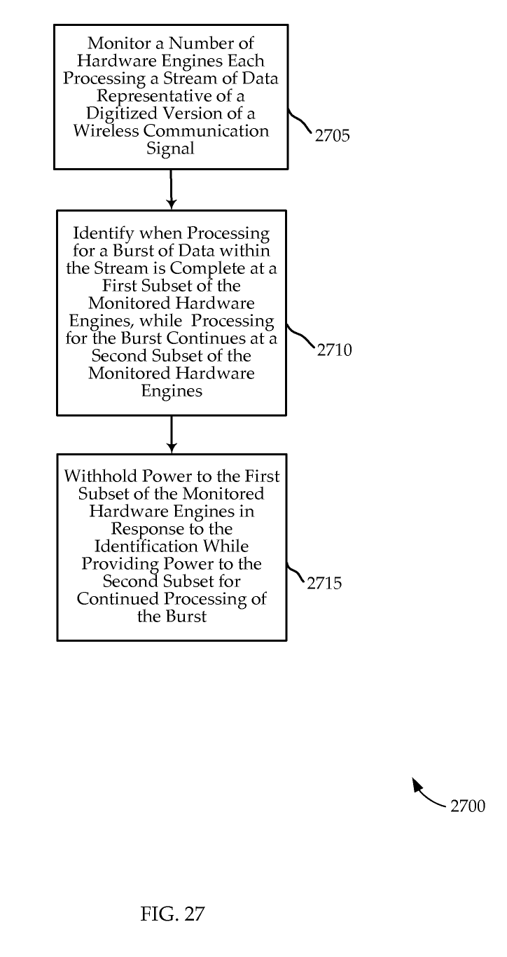

FIG. 27 is a flowchart illustrating a method 2700 of controlling power to hardware engines according to various embodiments of the invention. The method 2700 may, for example, be performed in whole or in part on the device 105 of FIG. 1 or 2 or, more specifically, using the device 105 of FIG. 21, 22A, 22B, or 23.

At block 2705, a number of hardware engines, each processing a stream of data representative of a digitized version of a wireless communication signal, are monitored. At block 2710, an identification is made when processing for a burst of data within the stream is complete at a first subset of the monitored hardware engines, while processing for the burst continues at a second subset of the monitored hardware engines. At block 2715, power to the first subset of the monitored hardware engines is withheld in response to the identification, while power is provided to the second subset for continued processing of the burst.

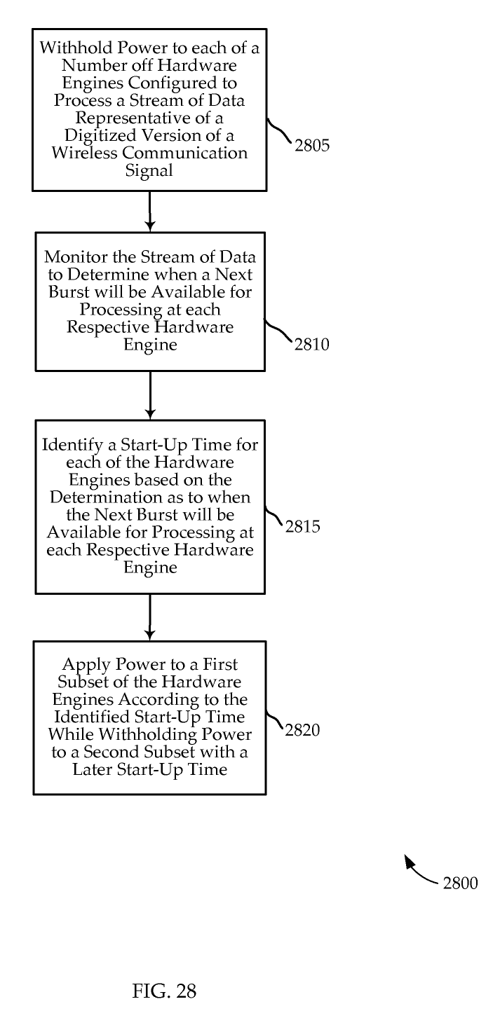

FIG. 28 is a flowchart illustrating a method 2800 of successively applying power to hardware engines according to various embodiments of the invention. The method 2800 may, for example, be performed in whole or in part on the device 105 of FIG. 1 or 2 or, more specifically, using the device 105 of FIG. 21, 22A, 22B, or 23.

At block 2805, power is withheld from each of a number of hardware engines configured to process a stream of data representative of a digitized version of a wireless communication signal. At block 2810, each hardware engine is monitored to determine when a next burst will be available for processing at each respective engine. At block 2815, a start-up time is identified for each of the hardware engines based on the determination as to when the next burst will be available for processing at each respective engine. At block 2820, power is applied to a first subset of the hardware engines according to the identified start-up time, while withholding power to a second subset with a later start-up time.

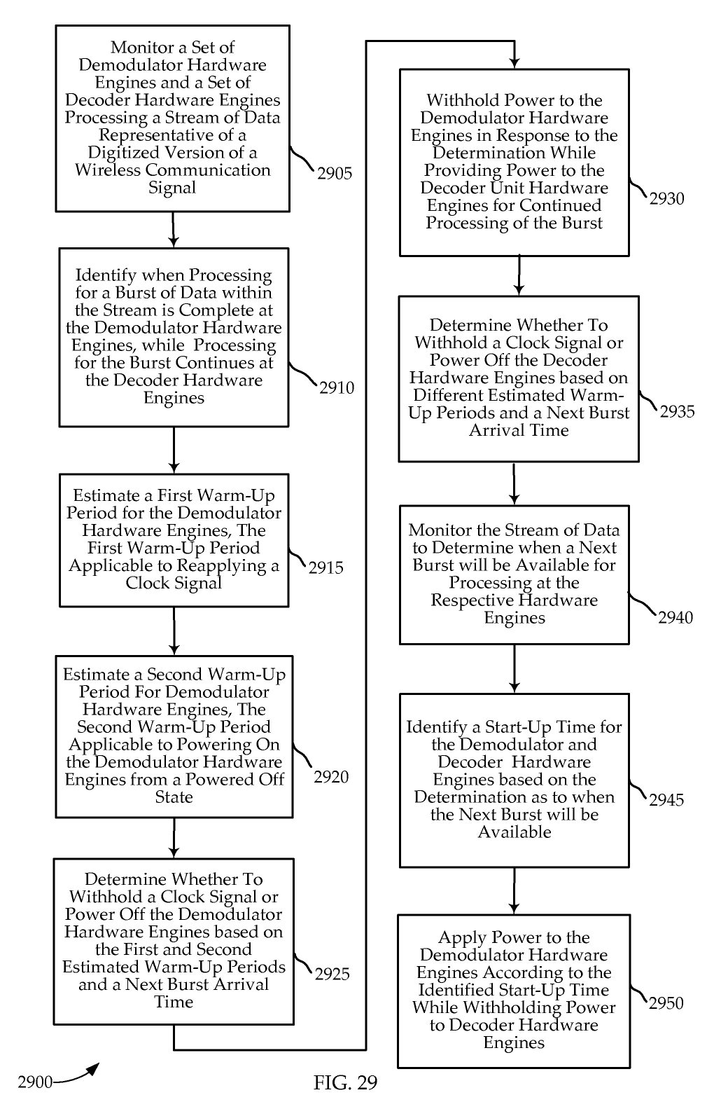

FIG. 29 is a flowchart illustrating a method 2900 of controlling the application and withdrawal of power to hardware engines according to various embodiments of the invention. The method 2900 may, for example, be performed in whole or in part on the device 105 of FIG. 1 or 2 or, more specifically, using the device 105 of FIG. 21, 22A, 22B, or 23.

At block 2905, a set of demodulator hardware engines and a set of decoder hardware engines are monitored, the engines configured to process a stream of data representative of a digitized version of a wireless communication signal. At block 2910, an identification is made (e.g., generation of a notification signal) when processing for a burst of data within the stream is complete at the demodulator hardware engines, while processing for the burst continues at the decoder hardware engines.

At block 2915, a first warm-up period for the demodulator hardware engines is estimated, the first warm-up period applicable to reapplying a clock signal. At block 2920, a second warm-up period for the demodulator hardware engines is estimated, the second warm-up period applicable to powering on the demodulator hardware engines from a powered off state. At block 2925, a determination is made whether power is to be withheld by withholding a clock signal or powering off the demodulator hardware engines, based on the first and second estimated warm-up periods and a next burst arrival time. At block 2930, power is withheld to the demodulator hardware engines in response to the determination, while providing power to the decoder unit hardware engines for continued processing of the burst.

At block 2935, a determination is made whether to withhold a clock signal or power off the decoder hardware engines based on different estimated warm-up periods and a next burst arrival time. At block 2940, the stream of data is monitored to determine when a next burst will be available for processing at the respective hardware engines. At block 2945, start-up times for the demodulator and decoder hardware engines are identified based on the determination as to when the next burst will be available. At block 2950, power is applied to the demodulator hardware engines according to the identified start-up times, while withholding power to the decoder hardware engines.

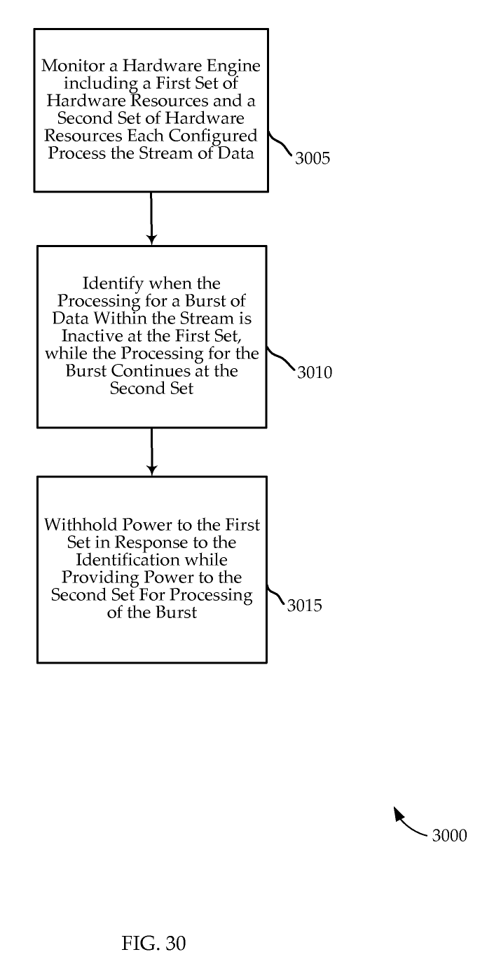

FIG. 30 is a flowchart illustrating a method 3000 for monitoring and controlling particular resources of a hardware engine according to various embodiments of the invention. The method 3000 may, for example, be performed in whole or in part on the device 105 of FIG. 1 or 2 or, more specifically, using the device 105 of FIG. 21, 22A, 22B, or 23.

At block 3005, a hardware engine is monitored, including a first set of hardware resources and a second set of hardware resources each configured to process the stream of data. At block 3010, an identification is made when processing for a burst of data within the stream is inactive at the first set of resources, while the processing for the burst continues at the second set. At block 3015, power is withheld from the first set in response to the identification, while providing power to the second set for processing of the burst.

3. Decoder Unit Configuration: In one embodiment, a hardware engine is configured as a single decoder unit 145 configured to process both packets and frames. The decoder unit 145 may be configured to decode and correct both physical (PHY) layer packets and link layer frames. The decoder unit 145 may be configured to serially process and decode packets and rows of a frame, using arbitration algorithms described in more detail below to decide whether to queue a packet or row. In one embodiment, some the decoding related functions may be performed by another processor (e.g., an on chip CPU or a host).

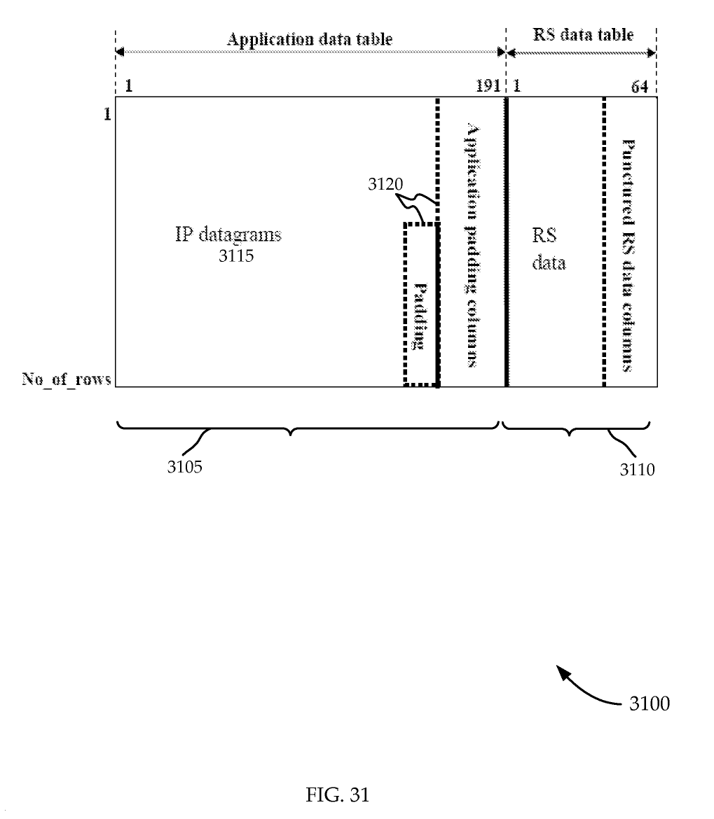

Consider first the DVB-H standard (digital video broadcasting for handheld devices), developed for digital TV reception on battery-based mobile devices. FIG. 31 illustrates a frame 3100 of data (an MPE-FEC frame) which may be formatted at a transmitter in accordance with the DVB-H standard. Note that, while the DVB-H standard is used for purposes of example, a variety of aspects of the invention are applicable to a number of other MDTV and other wireless standards, as well. Also, other types of framing formats may be used, and the following is for purposes of example only.

In one embodiment, a frame 3100 to be transmitted is arranged as a matrix with 255 columns of one byte each, and a flexible number of rows. The frame is filled at the transmitter (e.g., by the headend unit 115 of FIG. 1). In one embodiment, the number of rows may be set and signaled dynamically by the transmitter, and may vary in number to a maximum allowed value of 1,024, which if full makes the total frame 3100 almost 2 Mb in size. Another embodiment has allowed values of 256, 512, 768, or 1024 rows. The left part of the frame is made up of the 191 columns dedicated for IP datagrams 3115 and possible padding 3120, and this part of the frame is called the application data table 3105. The right part of the frame, made up of the 64 columns on the right and dedicated for parity information of the FEC code, is called the RS data table 3110. Each byte position in the application data table 3105 may have an address ranging from (1 to 191)×(row number). In the same way, each byte position in the RS data table 3110 may have an address ranging from (1 to 64)×(row number).

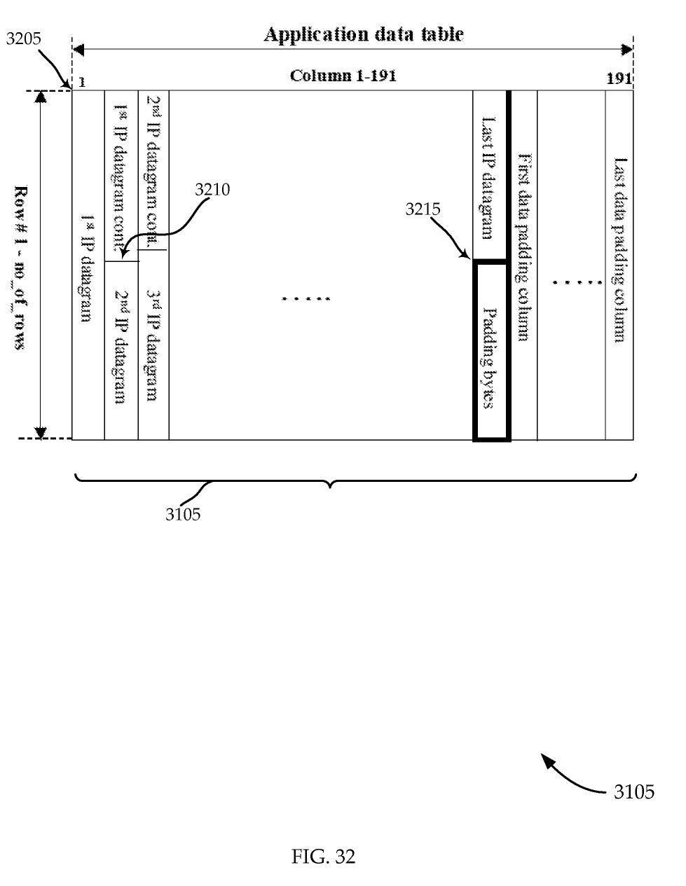

An example of the process of filling the application data table 3105 is illustrated by FIG. 32, while noting that the filling process may vary significantly for other embodiments. Data is filled, starting with the first byte of a first datagram in the upper left corner of the matrix 3205 and going downward in the first column. The length of the IP datagrams may vary arbitrarily from datagram to datagram. After the end of one IP datagram 3210, the following IP datagram starts. If an IP datagram does not end precisely at the end of a column, it continues at the top of the following column. When all IP datagrams have entered the application data table 3215, unfilled byte positions are padded with zero bytes, a process which makes the leftmost 191 columns completely filled. The number of full and partial padding columns may be signalled dynamically from the transmitter.

Referring back to FIG. 31, with the application data table 3105 filled, the 64 parity bytes for each row of the RS data table 3110 are calculated from the 191 bytes of IP data (and possible padding) for the row. In one embodiment, the code used is Reed-Solomon RS (255, 191) with a field generator polynomial and a code generator polynomial. Each row then contains one RS codeword. Some of the rightmost columns of the RS data table may be discarded and thus will not be transmitted, which may enable puncturing. With these steps, the RS data table 3110 is completely filled, and the frame 3100 is completed.

In one embodiment, the IP data is to be carried in MPE sections per the DVB standard. Thus, each MPE section carries a start address in the frame 3100 for the IP datagram. This address indicates the byte position in the application data table 3105 of the first byte of the IP datagram, and is included in the MPE header. A receiver (e.g., the device 105 of FIG. 1) will then be able to put the received IP datagram in the right byte positions in the application data table 3105 and identify particular sets of byte positions as “reliable” for the RS decoder, provided the CRC-32 or other checksum shows that the section is correct. The last section of the application data table 3105 may contain a flag which indicates the end of the IP datagrams within the application data table 3105. If previous sections within the application data table 3105 have been received correctly, the receiver does not need to receive any additional sections, and if time slicing is used, the receiver can then power off certain components. The parity bytes may be carried in a separate, specially defined section type. These are similar to MPE sections and are named MPE-FEC sections.

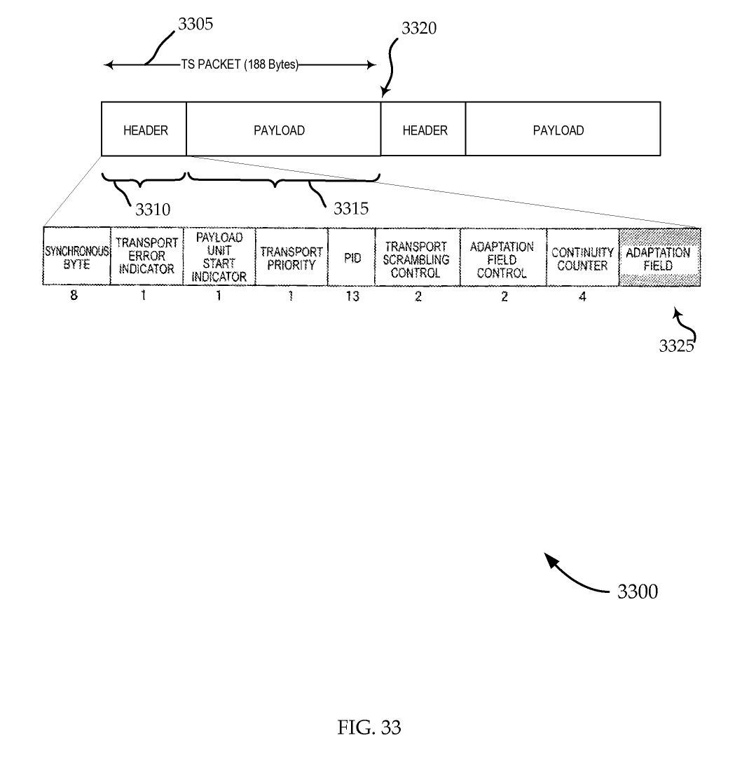

Still at a transmitter (located either at the source 125 of the transmission or an intermediate location, such as the headend unit 115), in one embodiment, the MPE and MPE-FEC sections are transmitted as the payload of MPEG-2 transport stream (TS) packets. FIG. 33 illustrates the format structure 3300 for an example TS packet 3305 to be transmitted according to an embodiment of the invention, containing 188 bytes. As noted, the MPE and MPE-FEC sections of the MPE-FEC frame may be encapsulated as payload 3315 of a TS packet. Each TS packet 3305 may then be encoded by an encoder at the transmitter. This encoding may, for example, be RS encoding performed by appending a number of parity bytes at the location indicated by reference number 3320 (after TS packet 3305). The parity bytes may, for example, be calculated based the applicable TS packet 3305. In another embodiment, the parity bytes (sometimes referred to as a parity code) may be stored within the TS packet 3305, where the parity code may be calculated based on all or part of the rest of the TS packet 3305. The parity code may, for example, be stored in the adaptation field 3325, and/or in another region of the header 3310. This encoding may, in some embodiments, be performed on data (e.g., a TS packet 3305) which is randomized and/or multiplexed. Once the TS packet 3305 is encoded, it may be interleaved and multiplexed. The data may then be modulated and upconverted for transmission via an RF signal. These steps may occur at a source 125 or intermediate location between the source 125 and device 105, such as the headend unit 115.

The RF signal may then be received by a mobile communications device, such as the device 105 of FIG. 1 or 2. The device 105 of FIG. 1 or 2 may be configured to receive the transmitted wireless signal, and downconvert and digitize the signal as generally described above. The demodulator unit 170 may demodulate the digitized signal to produce a digitized version of the received signals. The demodulator unit 170 may generate a stream of data made up of a series of physical layer packets, the stream generated from the digitized wireless communication signals. Thus, in one embodiment, a received version of the TS packet and appended parity code is received from the demodulator 170 by a decoder unit 145.

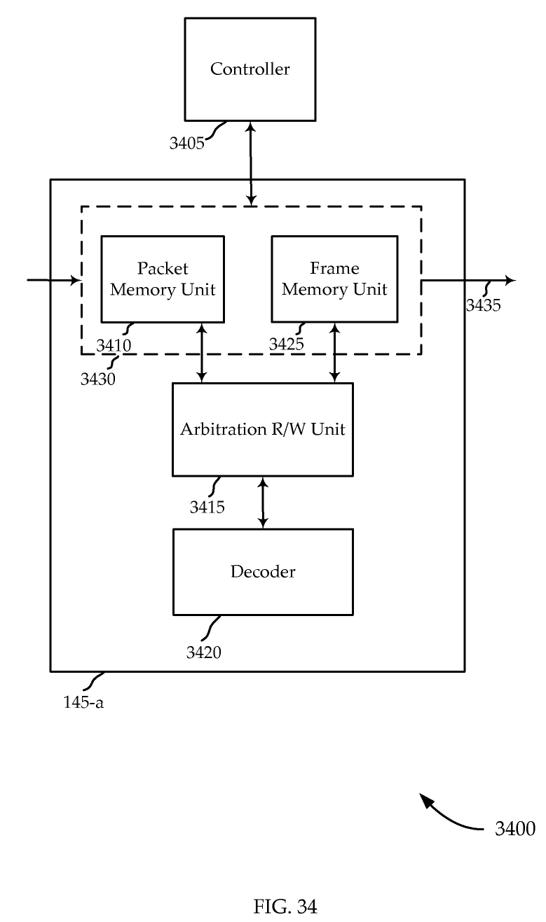

Referring next to FIG. 34, a block diagram 3400 is shown with an example decoder unit 145-a and controller 3405 for decoding and correcting the received data at different stages of processing. In one embodiment, this is the decoder unit 145 of the device of FIG. 1, although the forthcoming description may be applied in a variety of alternative devices, as well. The decoder unit 145-a may include an arbitration read/write (r/w) unit 3415, a decoder 3420, and memory 3430. The memory 3430 may include a packet memory unit 3410 and frame memory unit 3425 for storing the physical layer packets and a frame both before and during the decoding and correction process.

In one embodiment, the decoder unit 145-a is a distinct set of multipliers, adders, rounders, and memory configured to perform decoding and correction of both packets (e.g., physical layer packets) and rows (e.g., from link layer frames). Thus, the resources (multipliers, adders, and rounders) of the decoder 3420 may be allocated to perform decoding of both physical layer packets and link layer frames (e.g., particular rows thereof), while not performing other functions (e.g., not performing symbol synchronization, fast fourier processing, etc.). The decoder 3420 may be configured to process one physical layer packet or one row at a time. Thus, the processing (e.g., decoding and correction) at the decoder 3420 may occur on a progression of rows or packets serially, processing one row or one packet at a time. This arbitration between packets and rows may be managed by the arbitration r/w unit 3415, the controller 3405, or any combination thereof.

As noted above, a stream of encoded physical layer packets (e.g., TS packets encoded with parity codes) may be received by the decoder unit 145-a (e.g., from the demodulator 170 directly or after some intermediate processing), and placed in the packet memory unit 3410 of memory 3430. The controller 3405 (which may, for example, be the supervisory block 250 of FIG. 2, an additional processor of FIG. 2 (e.g., an on chip CPU), or any combination thereof) may be configured to identify errors by, for example, using checksums of the physical layer packets. The arbitration r/w unit 3415 may access the packet memory unit 3410 and provide the encoded packets to decoder 3420. The decoder 3420 may process the encoded data to produce a decoded and corrected TS packet (e.g., using the appended parity code to correct the TS packets, if possible). The corrected data may be written back to the packet memory unit 3410 or to the frame memory unit 3425 depending, for example, on the processing stage and particular embodiment. The decoder 3420 may perform decoding and forego correction, for example, if the data is too corrupted or the coding rate insufficient. This process of decoding and correction by the decoder 3420 may be continued for a stream of encoded TS packets (or, in other embodiments, a stream of otherwise encoded physical layer packets).

The controller 3405 (which, again, may be the supervisory block 250 of FIG. 2, an on chip CPU, a host processor, or any combination thereof) may process the payloads of the decoded TS packets. As the MPE and MPE-FEC sections of an MPE-FEC frame are extracted from the payloads 3315 in the stream of TS packets, the frame 3100 from FIG. 31 may be reconstructed and stored in the frame memory unit 3425 (on a column by column basis). Thus, the corrected data from the packet memory unit 3410 may be forwarded to the frame memory unit 3425. To determine frame 3100 parameters, the number of rows for a frame 3100 may be signaled, but may also be determined from the section length of the MPE-FEC sections, since the payload length of these sections may be equal to the number of rows.

To place the received section belonging to the application data table 3105 or to the RS data table 3110 in the appropriate location in the frame memory unit 3425, the controller 3405 may look to the section header for the start address of the payload within the section. This procedure may result in some missing sections (e.g., because they were lost during during transport). MPE and MPE-FEC sections are typically protected by a CRC-32 code, which reliably detects erroneous sections. In other embodiments, a variety of checksums may be used.

Memory 3430 also includes buffers (allocated on a temporary or more permanent basis) for storing reliability data corresponding to certain “regions” or “chunks” of the received frame 3100. As the received data continues to be placed in the frame memory unit 3425, the arbitration r/w unit 3415 may tag or mark regions containing error bytes or missing data as unreliable in corresponding buffers. Thus, the buffers storing reliability data may have sections corresponding to the parts of the frame 3100.

Once an entire frame 3100 is stored in the frame memory unit 3425, and the reliability data has been written, a row of received data in the frame memory unit 3425 may be processed for error correction and decoding. The decoder 3420 may correct each row tagged with an indicator of unreliability (rows without such tags are typically not sent to the decoder 3430 for error correction, although they may be in some embodiments). Once corrected by the decoder 3420, the arbitration r/w unit 3415 writes the corrected row back (or simply corrects the incorrect bits) to the frame memory unit 3425. Returning to FIG. 1, decoded data may be forwarded for additional processing (e.g., by an on chip CPU, host processor, or combination thereof). Thus, once the data of a frame is corrected, it may be forwarded 3435 for additional processing to free up memory space for the next frame to be filled.

In some embodiments, the memory 3430 space allocated to the packet memory unit 3410 and the frame memory unit 3425 are physically separate. In another embodiment, the memory 3430 space allocated to the buffers indicative of frame reliability are also distinct. However, in still other embodiments, the memory is shared for the decoder unit 145-a, but distinct from other processing engines. In other embodiments, the memory is shared between various processing units of the device 100 of FIG. 1.

By way of a more specific example, the packet memory unit 3410 may be allocated approximately 10 Kb of random access memory (RAM), while the frame memory unit 3425 is allocated approximately 2.5 Mb of RAM which is physically distinct from the RAM for packet memory unit 3410. As physical layer packets are received, there is only enough memory to store approximately six TS packets. Also, assuming a 2 Mb frame, there is only enough frame memory in this embodiment to store approximately 1.25 frames. Assume an embodiment wherein the decoder 3420 processes only one packet or one row at a time. Also assume that a frame stored in the frame memory unit 3425 has been filled, and is being decoded and corrected row by row. As the packet memory unit 3410 fills, the decoder 3420 processing of the frame memory unit 3425 may be suspended or otherwise briefly interrupted to decode and correct the packets stored in the packet memory unit 3410. This interrupt may occur when one or more physical layer packets are stored and ready for decoding, or may occur once the number of physical layer packets ready for decoding meets or exceeds a threshold. Once these packets are decoded and corrected by the decoder 3420, portions thereof may be forwarded for storage to the frame memory unit 3425. Thus, the corrected data may be forwarded and stored for the next frame in the frame memory unit 3425. Once this physical layer packet processing is completed, the row by row decoding and correcting of the frame may be continued. As will be discussed in more detail below, the clocks applied to one or more engines of the decoder unit 145-a (e.g., to the decoder 3420) may be accelerated to ensure sufficient memory is available, the acceleration triggered by memory usage, SNR, mode, etc.

Consider another embodiment of the invention illustrating an example addressing the time slice nature of DVB. Assume that the decoder unit 145-a is powered down. Before an anticipated time slice is received, the packet memory unit 3410, frame memory unit 3425, arbitration r/w unit 3415, and decoder 3420 may be powered up with a sufficient wakeup period. As a stream of encoded TS packets are respectively received and stored in the packet memory unit 3410, they may be selectively corrected by the decoder 3420 (e.g., before the whole frame is received). As the MPE and MPE-FEC sections of an MPE-FEC frame are extracted from the payloads 3315 in the stream of TS packets, the frame 3100 from FIG. 31 may begin to be reconstructed and buffered in the frame memory unit 3425 by the controller 3405.

The decoder 3420 will, in this embodiment, wait to correct any row with a tagged error until the entire frame 3100 is filled. When filled, the respective rows of the frame 3100 with tagged errors begin to be corrected by the decoder 3420. This row-by-row correction may continue until a TS packet (e.g., for the next frame to be filled) is ready to be corrected (e.g., stored in memory waiting to be processed by the RS decoder 3420). At that time, the row-by-row frame 3100 processing may be interrupted at the decoder 3420, to allow the decoder 3420 to correct the packet. There may be a threshold amount of packets to be corrected before there is an interrupt (e.g., no interruption of frame 3100 correction until four (or 32, or X) packets are waiting). The thresholds may differ depending upon where in the frame 3100 the correction process is (e.g., a smaller threshold at the beginning of the frame 3100). A number of alternative configurations may be employed to achieve this functionality, as evident to those skilled in the art. Thus, this arbitration may continue to occur as packets and rows are decoded and corrected to process the received data.

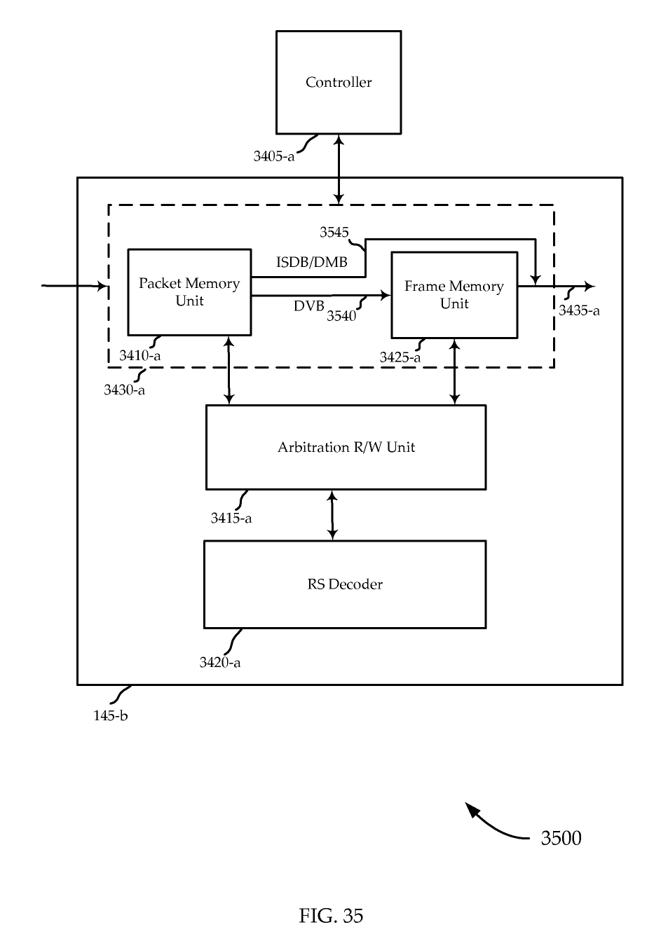

Referring next to FIG. 35, a block diagram 3500 is shown with an example decoder unit 145-b and controller 3405-a for decoding data from received wireless signals. In one embodiment, this is the decoder unit 145 of the device of FIG. 1 or 35, although the forthcoming description may be applied in a variety of alternative devices, as well. The decoder unit 145-b may include an arbitration read/write (r/w) unit 3415-a, an RS decoder 3420-a, and memory 3430-a. The memory may include a packet memory unit 3410-a and frame memory unit 3425-a, which may be made up of distinct regions of memory.

In one embodiment, the RS decoder 3420-a is a distinct set of multipliers, adders, and rounders, and memory configured to perform decoding and correction of both packets (e.g., physical layer packets) and rows (e.g., from link layer frames). Thus, the resources of the RS decoder 3420-a may be configured to not perform other functions (e.g., not performing symbol synchronization, fast fourier processing, arbitration, etc.). In one embodiment, the RS decoder 3420-a is configured to process only one physical layer packet or one row at a time. Thus, the processing (e.g., decoding and correction) at the RS decoder 3420-a may occur on a progression of rows or packets serially, processing one at a time.

Again assume a stream of encoded physical layer packets (e.g., TS packets encoded with parity codes) may be received by the decoder unit 145-a (e.g., from the demodulator 170 directly or after some intermediate processing), and placed in the packet memory unit 3410-a of memory 3430-a. The arbitration r/w unit 3410-a may access the packet memory unit 3410-a and provide the encoded packets to RS decoder 3420-a. The RS decoder 3420-a may decode and correct the encoded data to produce a corrected TS packet (e.g., using the appended parity code to correct the TS packets). The controller 3405-a (which may, for example, be the supervisory block 250 of FIG. 2, an additional processor of FIG. 1 (e.g., an on chip CPU), or any combination thereof) may be configured to identify whether the packet to be processed was transmitted under the DVB-H standard or an alternative standard (ISDB/DMB). The corrected data may be written back to the packet memory unit 3410-a, written back or forwarded to the frame memory unit 3425-a, or otherwise forwarded. These decisions may be based on mode or vary with configuration. This process of decoding by the RS decoder 3420-a may be continued for a stream of encoded TS packets (or, in other embodiments, a stream of otherwise encoded physical layer packets).

The controller 3405-a may process the payloads of the decoded physical layer packets. If the controller 3405-a has identified DVB-H mode, the MPE and MPE-FEC sections of an MPE-FEC frame may be extracted from the payloads 3315 in the stream of TS packets, and the frame 3100 from FIG. 31 may be reconstructed and buffered 3540 in the frame memory unit 3425-a. To determine frame 3100 parameters, the number of rows for a frame 3100 may be signaled, but may also be determined from the section length of the MPE-FEC sections, since the payload length of these sections may be equal to the number of rows. In other modes (e.g., ISDB or DMB), the frame memory unit may be avoided 3545, and clocks (or power) may be withheld from the frame memory unit to save power. Thus, in some modes, use of the frame memory unit 3425-a may be suspended.

Returning to the discussion of DVB-H, the RS decoder unit 3420-a may wait to decode the first frame until the first frame is filled. Once data is received indicating that an entire frame 3100 is stored in the frame memory unit 3425-a, a row of received data in the frame memory unit 3425-a may be processed for error correction. The RS decoder 3420-a may correct each row tagged with an indicator of unreliability (rows without such tags are typically not sent to the RS decoder 3420-a for error correction, although they may be in certain embodiments). Once corrected by the RS decoder 3420-a, the arbitration r/w unit 3415-a writes the corrected row back (or simply corrects the incorrect bits) to the frame memory unit 3425-a. Returning to FIG. 1, this corrected data may be forwarded 3435-a for additional processing (e.g., by an on chip CPU, host processor, or combination thereof). Thus, once the frame is corrected, it may be forwarded for additional processing to free up memory space for the next frame to be filled.

The decoder unit 145-b unit may then receive data (e.g., from controller 3405-a) or otherwise recognize that one or more stored physical layer packets for a next frame are stored in the packet memory unit 3410-a and are ready to be decoded. The decoder unit 145-b (e.g., via the arbitration r/w unit 3415-a) may interrupt or otherwise suspend the decoding of the rows of the frame from the frame memory unit 3425-a being decoded to process the waiting physical layer packets. Once this decoding of the one or more stored physical layer packets is complete, the decoder unit 145-b (e.g., via the arbitration r/w unit 3415-a) may resume the decoding of the interrupted frame. Thus, the decoder unit 145-b may receive data or otherwise recognize that the decoding for the one or more stored physical layer packets is complete, and then resume the decoding of the interrupted first frame. As noted above, the frame decoding interrupt may be triggered when the number of stored physical layer packets exceeds a threshold (e.g., three or four packets).

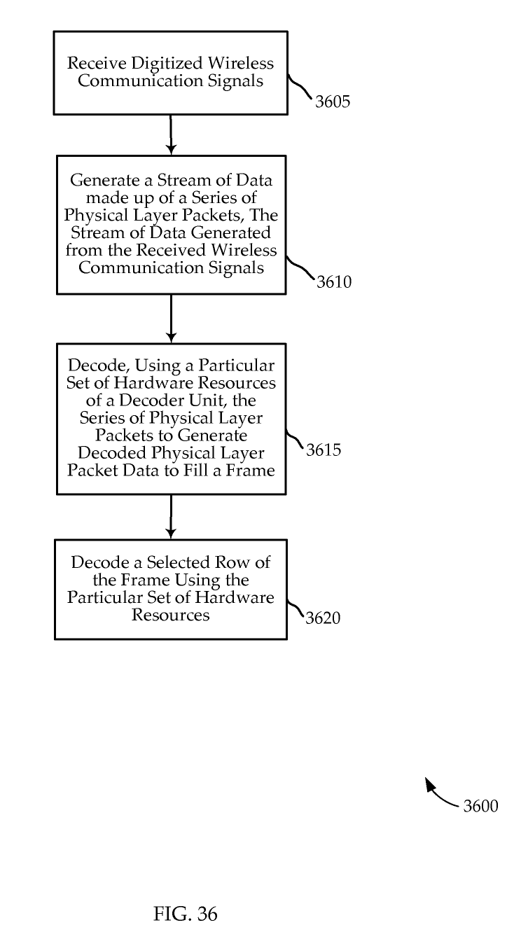

FIG. 36 is a flowchart illustrating a method 3600 for decoding according to various embodiments of the invention. The method 3600 may, for example, be performed in whole or in part on the mobile communications device 105 of FIG. 1 or 2 or, more specifically, using the decoder unit 145 of FIG. 2, 34, or 35.

At block 3605, a number of digitized wireless communication signals are received. This reception may be performed with a hardware engine which receives data from an on chip source. At block 3610, a stream of data made up of a series of physical layer packets is generated, the stream of data generated from the digitized wireless communication signals. At block 3615, using a particular set of hardware resources of a decoder unit, the series of physical layer packets is decoded to generate decoded physical layer packet data to fill a frame. At block 3620, a selected row of the frame is decoded using the particular set of hardware resources.

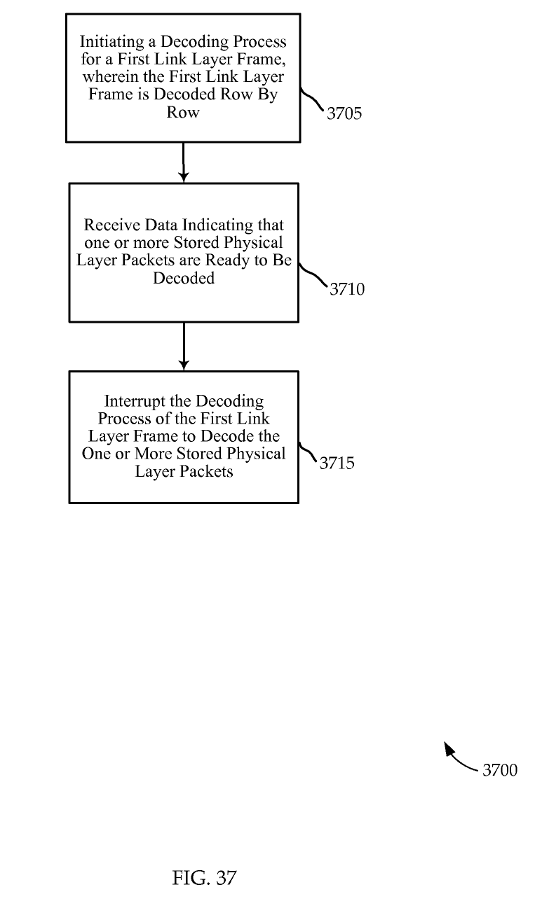

FIG. 37 is a flowchart illustrating a method 3700 for decoding physical layer packets and rows of a link layer frame according to various embodiments of the invention. The method 3700 may, for example, be performed in whole or in part on the mobile communications device 105 of FIG. 1 or 2 or, more specifically, using the decoder unit 145 of FIG. 2, 34, or 35.

At block 3705, a decoding process for a first link layer frame is initiated, wherein the first link layer frame is decoded row by row. At block 3710, data is received indicating that one or more stored physical layer packets are ready to be decoded. At block 3715, the decoding process of the first link layer frame is interrupted to decode the one or more stored physical layer packets.

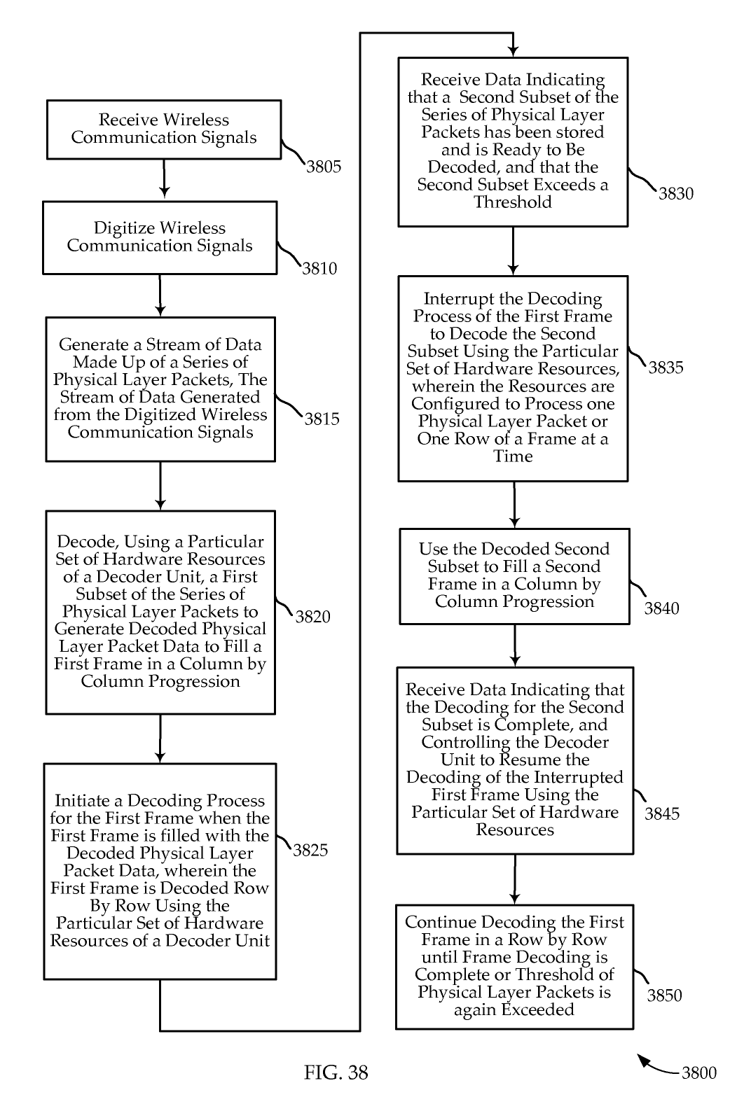

FIG. 38 is a flowchart illustrating an alternative method 3800 for decoding packets and rows according to various embodiments of the invention. The method 3800 may, for example, be performed in whole or in part on the mobile communications device 105 of FIG. 1 or 2 or, more specifically, using the decoder unit 145 of FIG. 2, 34, or 35.

At block 3805, wireless communication signals are received. At block 3810, the received wireless communication signals are digitized. At block 3815, a stream of data made up of a series of physical layer packets is generated from the digitized wireless communication signals.

At block 3820, using a particular set of hardware resources of a decoder unit, a first subset of the series of physical layer packets is decoded to generate decoded physical layer packet data to fill a first frame in a column by column progression. At block 3825, a decoding process is initiated for the first frame when the first frame is filled with the decoded physical layer packet data, wherein the first frame is decoded row by row using the particular set of hardware resources of the decoder unit.

At block 3830, data is received indicating that a second subset of the series of physical layer packets has been stored and is ready to be decoded, and that the amount of stored packets in the second subset exceeds a threshold number. At block 3835, the decoding process of the first frame is interrupted to decode the second subset using the particular set of hardware resources, wherein the resources are configured to process one physical layer packet or one row of a frame at a time.

At block 3840, the decoded second subset is used to fill a second frame in a column by column progression. At block 3845, data is received indicating that the decoding for the second subset is complete, and controlling the decoder unit to resume the decoding of the interrupted first frame using the particular set of hardware resources. At block 3850, decoding of the first frame is continued row by row until frame decoding is complete or threshold of physical layer packets is again exceeded.

4. Accelerated Processing for Subset of Hardware Engines: In one set of embodiments, clocks running at different speeds are applied to different hardware engines. For example, referring to the mobile communications device 105-a of FIG. 2, clocks running at one speed may be applied to a first subset of hardware engines, while clocks applied to the remainder of the hardware engines may be dynamically accelerated in response to attributes of a received wireless signal or certain performance metrics.

A device may include an analog processing unit configured to receive a wireless communication signal, and generate a digitized version of the signal. Such a device may further include a digital processing unit, which is made up of a number of hardware engines configured to process the digitized signal. Some of these hardware engines may operate in a first clock domain controlled by a clock output set at a first frequency, the first frequency applied in a first mode and a second mode. Other hardware engines may operate in a second clock domain. The second clock domain may be controlled, in a first mode, by a clock output set at substantially the first frequency, while in a second mode be controlled by a clock output set at a second, different frequency. The device may be configured to monitor attributes of the signal or other signal processing performance metrics, and dynamically switch between modes in response to the monitoring.

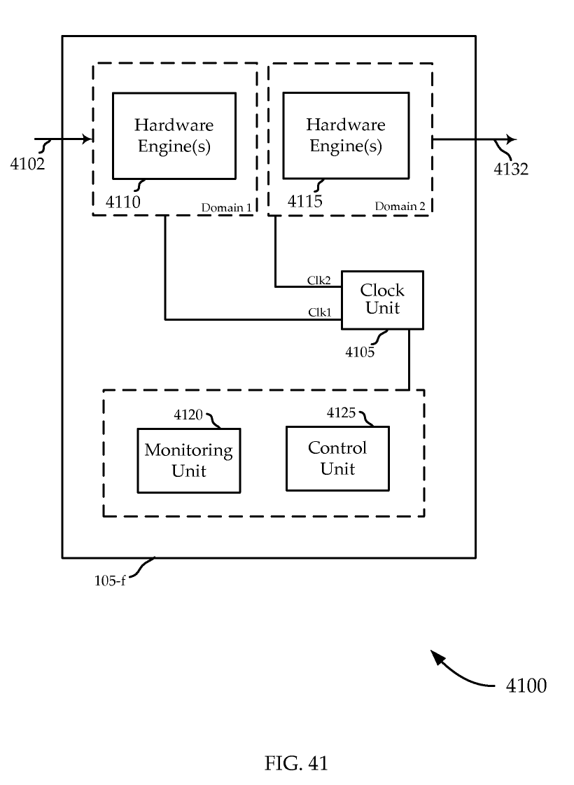

Referring first to FIG. 41, a block diagram 4100 is shown illustrating a device 105-f including an example configuration for the application of clocks to hardware engines 4110, 4115. This device 105-f may represent the device 105 of FIG. 1 or 2, although the illustrated configuration may be utilized in a number of different processors or devices. A digitized version of a wireless communication signal 4102 is received at hardware engine(s) 4110. In the illustrated embodiment, there is a clock unit 4105, configured to output different speeds for the respective sets of one or more engines 4110, 4115. In one embodiment, the clock unit includes two clock outputs.

A first clock output (clk1) frequency (which may be referred to hereinafter as the “base frequency”) may initially be set to work with a given standard or set of standards (e.g., DVB-H, DMB, ISDB-T, or MediaFLO) being used within a multi-mode device 105-a. This base frequency for domain 1 may be fixed to run a first subset of the hardware engines 4110 in each of two or more different modes. Turning to the second clock output (clk 2), in one mode it may also be set to run at or about base frequency to control the second subset of the hardware engines 4115 for domain 2. However, in another mode, the second clock output (clk 2) may be configured to run at an accelerated rate (e.g., at 2 times the base frequency, although in other embodiments, other speed differentials may be applied). Thus, in different modes, the second clock output may be changed dynamically.

The clock unit output speeds may be set by controller 4130, which may be the supervisory block 250 of FIG. 2, the additional processing unit 255 of FIG. 2, a combination thereof, or another processor. The controller 4130 may include a monitoring unit 4120 and a control unit 4125. The controller 4130 may be configured to switch the device between modes dynamically in response to processor performance or a monitored attribute of a received wireless communication signal.

The monitoring unit 4120 may, therefore, be configured to monitor one or more attributes of the received wireless signal or one or more signal processing performance metrics. The control unit 4125 of the controller 4130 may be configured to switch between modes based on the monitoring. For example, the monitoring unit 4120 may identify a change in the mobile digital video standard to be used for processing the received wireless communication signal, and the control unit 4125 may be configured to switch from the first mode to the second mode in response to a changed standard. For example, a switch from ISDB-T to DVB-H may trigger the acceleration, or a switch between DVB-H 2K and DVB-H 8K may trigger the acceleration. The acceleration may occur in domain 2 for hardware engine(s) 4115, while the domain 1 hardware engine(s) 4110 remain at a constant speed.

In addition, the monitoring unit 4120 may monitor a signal to noise ratio for the received wireless communication signal (e.g., averaged over a period of time). The control unit 4125 may receive or generate various signal to noise ratio levels or changes at which frequency acceleration (or reduction) may occur. These threshold levels may be set in advance, or vary according to current signal processing performance. The threshold levels may be different for different standards. The control unit 4125 may switch modes when the monitored signal to noise ratio passes a threshold. A threshold signal to noise ratio for the acceleration of a set of hardware engines 4115 may be different than a threshold signal to noise ratio for the deceleration of the set of hardware engines 4115, so as to avoid ringing between modes and better ensure stability.

The monitoring unit 4120 may also monitor other performance metrics. For example, the monitoring unit 4120 may monitor usage of memory available to the second set of hardware engines 4115. The control unit 4125 may receive or generate various memory usage levels or changes at which frequency acceleration or reduction may occur. These threshold levels may be set in advance or vary according to current performance, and may be different for different standards. The usage levels may, for example, be an amount of memory available, or a percentage of memory used. The control unit 4125 may switch modes when the monitored memory usage passes a threshold. A threshold memory usage for the acceleration of a set of hardware engines 4115 may be larger than a threshold memory usage for the deceleration of the set of hardware engines 4115. In another example, the monitoring unit 4120 may monitor processing delay at certain engines or for certain processing steps at the second set of hardware engines 4115. The control unit 4125 may receive or generate various delay levels or changes at which frequency acceleration or reduction may occur. These delay levels may be set in advance or vary according to current performance, and may be different for different standards. The control unit 4125 may switch modes when the monitored delay passes a threshold. A threshold delay for the acceleration of a set of hardware engines 4115 may be larger than a threshold delay for the deceleration of the set of hardware engines 4115.

The monitoring unit 4120 may also monitor other aspects of signal processing. For example, the monitoring unit 4120 may monitor whether a signal is being processed through a single antenna or if signals from different antennas are being processed (e.g., if diversity is not needed, only a single antenna may be used to save power Thus, one antenna may be configured to receive and provide a first version of the wireless communication signal for processing in both the first mode and the second mode. A second antenna may be configured to provide a second version of the wireless communication signal for processing in only the second mode.

After processing by the hardware engine(s) 4115 of domain 2, the data may be forwarded 4132 to another component or off of the device. In other embodiments, the functionality set forth for the monitoring unit 4120 may be integrated into other components, such as the control unit 4125 or other aspects of the controller 4130. The functions of the controller 4130 may, individually or collectively, be implemented with one or more Application Specific Integrated Circuits (ASICs) adapted to perform some or all of the applicable functions in hardware. Alternatively, the functions may be performed by one or more other processing units (or cores), on one or more integrated circuits. In other embodiments, other types of integrated circuits may be used (e.g., Structured/Platform ASICs, Field Programmable Gate Arrays (FPGAs), and other Semi-Custom ICs), which may be programmed in any manner known in the art. The functions may also be implemented, in whole or in part, with instructions embodied in a memory, formatted to be executed by one or more general or application-specific processors.

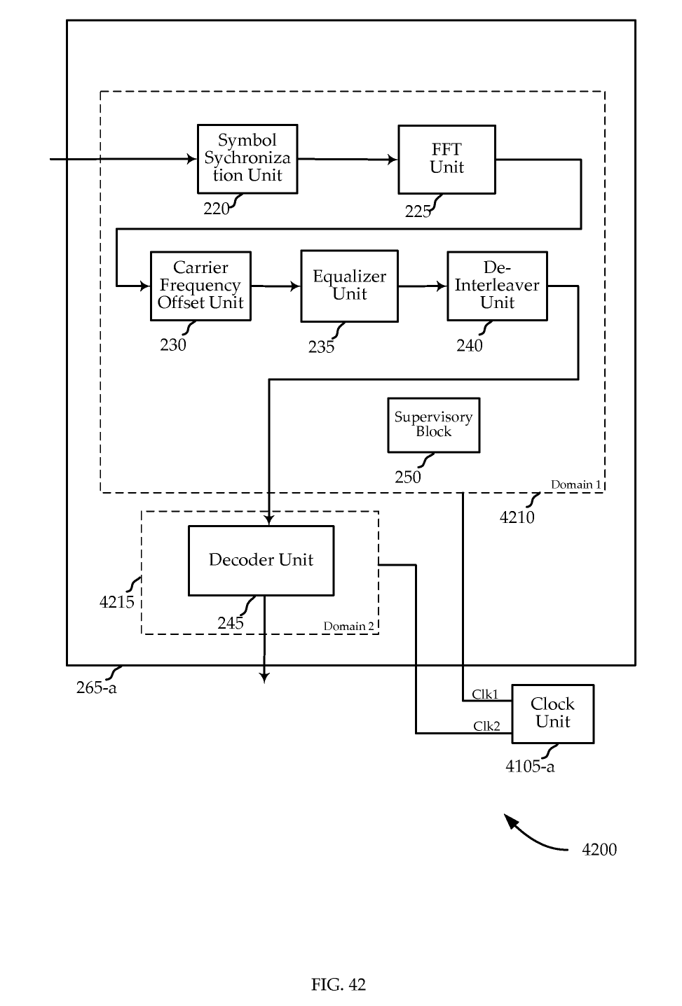

Referring now to FIG. 42, an example configuration 4200 for the application of clocks to hardware engines is illustrated. This configuration 4200 may represent components of the device 105-a of FIG. 2, including the hardware engines 265-a therein, although it may be utilized in a number of different devices. For example, the configuration 4200 also illustrates an example implementation of the configuration on device 105-f of FIG. 41. In the illustrated embodiment, there is a clock unit 4105-a, configured to provide multiple clock outputs that run at the same, or different, speeds for the respective engines depending on mode. In one embodiment, the clock unit includes two clock outputs.

A first clock speed (clk1) for the hardware engines of domain 1 is initially set based on the standard (e.g., DVB-H, DMB, ISDB-T, or MediaFLO) being used within the multi-mode device 100. The second clock speed (clk 2) may be set to run at either the same speed as domain 1, or 2 times that speed (although in other embodiments, other speed differentials may be applied). Therefore, a first clock (clk1) may be applied to domain 1 4210, and the second clock (clk2) may be applied to domain 2 4215. By way of example, in one embodiment domain 1 4210 includes symbol synchronization unit 220, FFT unit 225, carrier frequency offset unit 230, equalizer unit 235, de-interleaver unit 240, and supervisory block 250, while domain 2 includes decoder unit 245.

This dual clock application may, for example, be particularly applicable to the configuration of the decoder unit 145 described with reference to FIGS. 34 and 35. Specifically, by accelerating the processing of decoder unit 145 (or, more specifically, only the decoder 3420), less memory 3430 may be required. This may occur in some embodiments because the decoder 3420 processes both physical layer packets and link layer frames. In addition to this processing, in some embodiments the decoder 3420 waits to correct the rows of a frame until the frame is completely filled. This configuration of the decoder unit 245 may lead to delays requiring additional memory, unless processing is accelerated (e.g., by using a dual or multi-clock domain configuration described herein).

In one embodiment, this accelerated processing may be triggered when supervisory block 250 (or other processor, such as a CPU) identifies a change in the mobile digital video standard (e.g., from ISDB-T to DVB-H) to be used for processing the received wireless communication signal, and accelerates the (clk 2) output to domain 2. The acceleration may occur in domain 2 for the decoder unit 245 (or components thereof), while the domain 1 hardware engines remain at a constant speed. The accelerated processing may be triggered by additional factors, as well. For example, in one embodiment the accelerated processing for domain 2 will occur when DVB-H is the standard and the signal to noise ratio falls below a certain threshold. In another embodiment, the accelerated processing for domain 2 will occur when DVB-H is the standard and the available memory for the decoder unit 245 falls below a threshold. In still another embodiment, the accelerated processing for domain 2 will occur when DVB-H is the standard and processing delays at the decoder unit 245 exceed a threshold. A number of other examples are possible, as the supervisory block 250 (or other processor, such as a CPU) may monitor a number of signal attributes or other signal processing metrics, using the data to make decisions about accelerating processing to ensure sufficient memory is available and decelerating processing to save power.

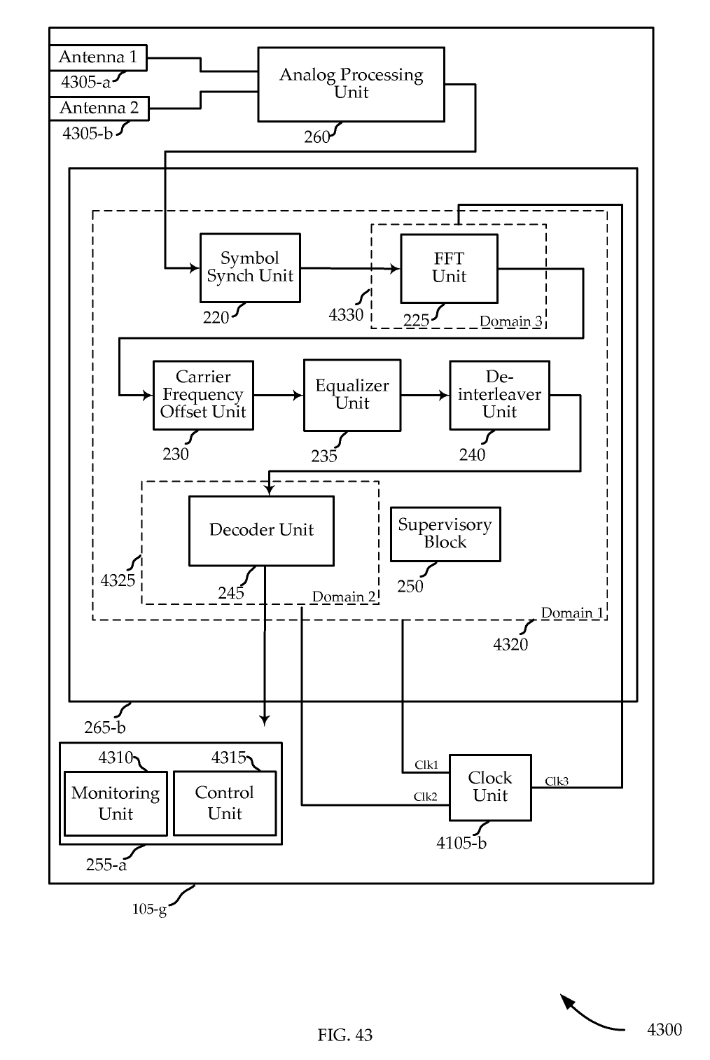

Referring next to FIG. 43, a block diagram 4300 illustrates an example device 105-g for the application of clocks to hardware engines. This device 105-g may represent the device 105-a of FIG. 2, including the hardware engines 265-b therein. In addition, the device 105-g is also an example implementation of the device 105-f of FIG. 41, or the configuration 4200 of FIG. 42. The device 105-g includes a clock unit 4105-b, configured to run certain engines at the same, or different, speeds as the remainder of the engines. In one embodiment, the clock unit includes 3 clock outputs. A first clock speed (clk1) is initially set based on the standard (e.g., DVB-H, DMB, ISDB-T, or MediaFLO) being used within the multi-mode device 100. Other clocks (clk 2, clk 3) are set to run at an accelerated speed (which may be identified in any manner described above). By way of example, the first clock (clk1) may be applied to domain 1 4320, which includes symbol synchronization unit 220, FFT unit 225, carrier frequency offset unit 230, equalizer unit 235, de-interleaver unit 240, decoder unit 245, and supervisory block 250. A second clock (clk2) may be applied to domain 2 4325, which includes decoder unit 245. A third clock speed (clk3) may be applied to domain 3 4330, which includes FFT unit 225. In one embodiment, therefore, certain hardware engines may be configured to run at either a standard speed (clk1) or an accelerated speed (clk2, clk3).

Real-time metrics (e.g., delay at certain engines, signal to noise ratio, memory usage at certain engines, etc.) may be monitored to determine the clock to be applied to certain engines. The device 105-g includes an additional processing unit 255-a, including a monitoring unit 4310 and a control unit 4315. This monitoring unit 4310 and control unit 4315 may have the same functionality as described with reference to the monitoring unit 4120 and control unit 4125 described with reference to FIG. 41. Thus, the monitoring unit 4310 may monitor the standard being processed, memory usage, processing delays, signal to noise ratio, and other factors outlined herein to determine whether to accelerate processing. The control unit 4315 may use this information to control switching between modes.

The device 105-g, in one embodiment, also include two antennas 4305. The control unit 4315 may control the analog processing unit 260 on the device to process signals from either one, or both, of the antennas. The control unit 4315 may control the hardware engines 265-b on the device to process signals from either one, or both, of the antennas. This selective processing may depend on the signal quality received from each antenna, and the desired quality of a video being received. Antenna diversity may be used in only select situations in order to save power. Certain accelerated processing (e.g., for domain 2 4325 and domain 3 4330) may be triggered when signals from multiple antennas are being processed.

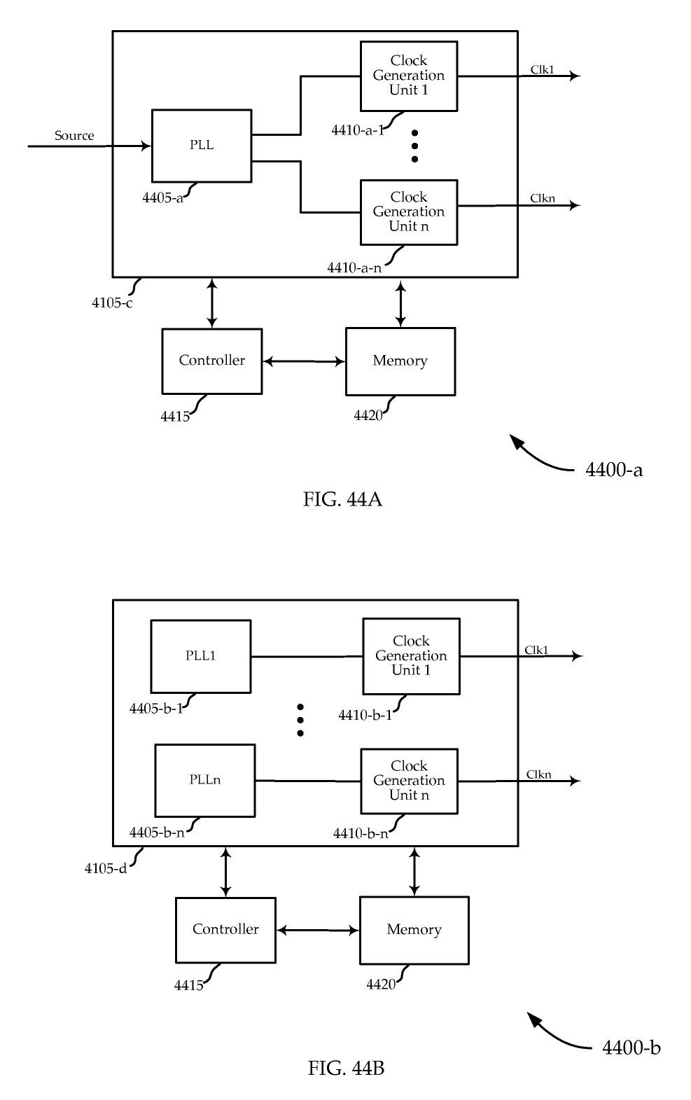

There are a number of different ways in which clocks and associated domains may be implemented. Referring first to FIG. 44A, an example clock configuration 4400-a is shown. This may be the configuration employed for the clock unit 4105 of FIG. 41, 42, or 43. The clock unit 4105-c of FIG. 44-a includes a PLL 4405-a, which receives a clock input from a source (on or off chip), and typically outputs a higher frequency to clock generation unit(s) 4410-a. The clock generation unit(s) 4410-a may be made up of one or more downconverters (e.g., divide-by logic), which receive the output of the PLL 4405-a and modify the signal to generate a particular clock output (e.g., clk1 or clkn). Each clock generation unit(s) 4410-a may be applied to a different domain (e.g., assuming n=2, clock generation unit 1 4410-a-1 may be applied to domain 1 4210 of FIG. 42, while the second clock generation unit 4410-a-n may be applied to domain 2 4215 of FIG. 42). In some embodiments, the clock generation units 4410-a may be dynamically accelerated or decelerated by changing the divide-by-logic, for example. In such instances, the outputs may be switched temporarily to a local oscillator until the clock generation units 4410-a have settled on the changed speeds. In other embodiments, a clock generation unit 4410-a may be applied to multiple domains, and/or domains may be configured to receive a signal from more than one unit 4410-a.

This clock configuration 4400-a also includes a controller 4415 (which may, for example, be the supervisory block 150 of FIG. 1, an on chip CPU, a host processor, or any combination thereof). The controller 4415 may be configured to control the PLL 4405-a and its output frequency. The controller 4415 may also be configured to control the clock generation unit(s) 4410-a and each of their respective output frequencies.

In one embodiment, the controller 4415 may access a table in memory 4420 which identifies the frequencies to be applied to different domains for each particular standard (e.g., DVB-H, DMB, or ISDB-T), and in different processing environments. Similarly, the table may identify different frequencies depending on the mode of the particular standard (e.g., 2 k, 4 k, or 8 k mode of DVB-H). The proportional difference between the frequencies applied to each domain may differ for each standard.

In one embodiment, the proportional difference between the frequencies applied to each domain may differ based on real-time performance issues. For example, referring briefly back to FIG. 41, there may be a measurement of the memory usage at the hardware engines 4115 when the mode being processed switches to DVB-H, and the processing speed for domain 2 may be increased as the measured memory usage increases. In another example, referring briefly back to FIG. 42, there may be a measurement of the delay at the decoder unit 245, and the processing speed for domain 2 4215 may be increased as the measured delay increases. Alternatively, there may be a measurement of signal to noise ratio, and the processing speed for domain 2 4215 may be increased as the performance degrades (as the requirements on the decoder unit 245 may increase thereby). Conversely, the processing speed for domain 2 4215 may be decreased as the performance improves (as the requirements on the decoder unit 245 may decrease thereby). There may be any number of alternative configurations employed to determine the frequencies and domains to be applied to respective hardware engines, as well.

Referring next to FIG. 44B, an alternative example clock configuration 4400-b is shown. This may also be the configuration used for the clock unit 4105 of FIG. 41, 42, or 43. The clock unit 4105-d of FIG. 44B includes a number of PLLs 4405-b, each of which may receive a clock input from a source (on or off chip). In one embodiment, at least a subset of the PLLs 4405-b is local to each domain. Separate voltage inputs and regulators may be used for each of the PLLs 4405-b.

The clock unit 4105-d of FIG. 44B also includes one (or more) clock generation unit(s) 4410-b for respective PLLs 4405-b. Each clock generation unit(s) 4410-b may be made up of one or more downconverters (e.g., divide-by logic), which receive the output of the respective PLLs 4405-b and modify the signal to generate a particular clock output (e.g., clk1 . . . clkn). The clock generation unit(s) 4410-b of FIG. 44B may have the same functionality as described with reference to the clock generation unit(s) 4410-a of FIG. 44A. Similarly, one or more controllers 4415 may be configured to control the PLLs 4405-b, clock generation unit(s) 4410-b, and respective output frequencies.

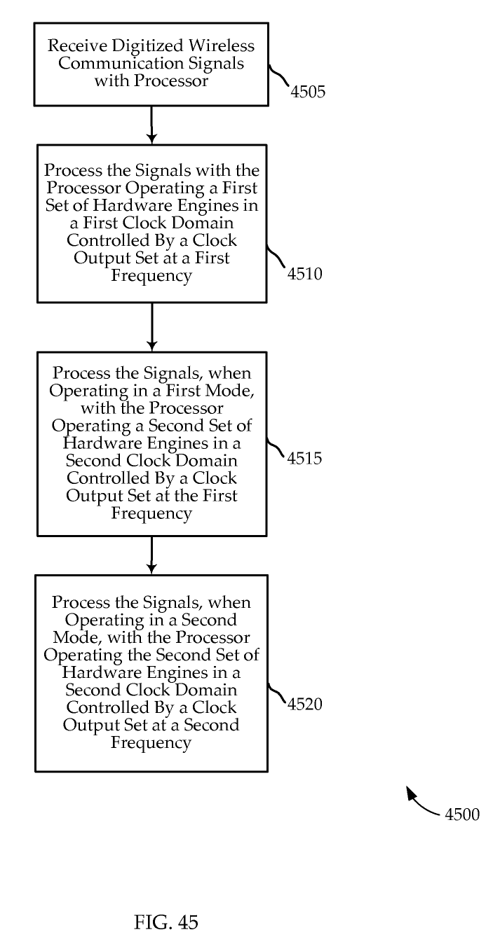

FIG. 45 is a flowchart illustrating a method 4500 for operating a processor with clock domains at different speeds according to various embodiments of the invention. The method 4500 may, for example, be performed in whole or in part on the device 105 of FIG. 1 or 2 or, more specifically, using the device 105-f of FIG. 41, the configuration 4200 of FIG. 42, or the device 105-g of FIG. 43.

At block 4505, digitized wireless communication signals are received at a processor. At block 4510, the processor operates a first set of hardware engines in a first clock domain controlled by a clock output set at a first frequency. At block 4515, the signals are processed, in a first mode, with the processor operating a second set of hardware engines in a second clock domain controlled by a clock output set at the first frequency. At block 4520, the signals are processed, in a second mode, with the processor operating the second set of hardware engines in a second clock domain controlled by a clock output set at a second frequency.

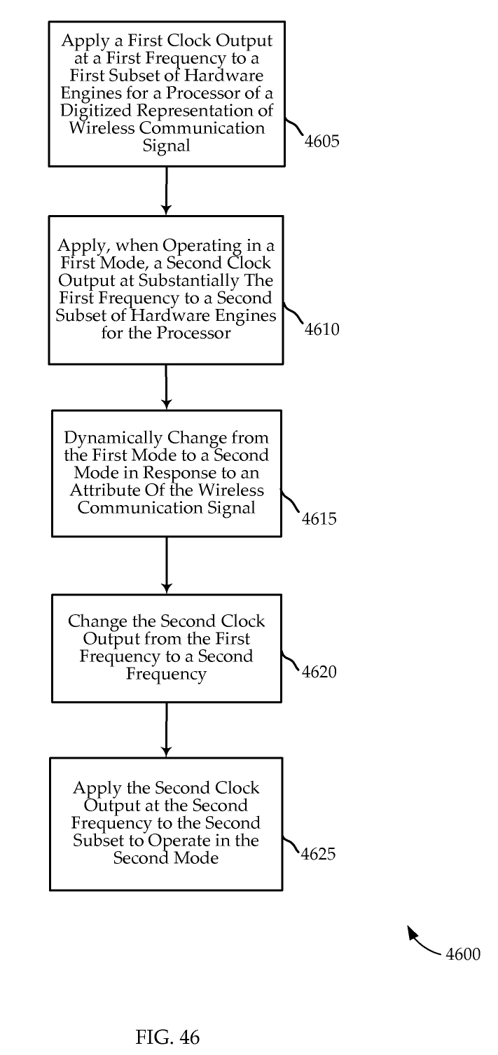

FIG. 46 is a flowchart illustrating a method 4600 for dynamically modifying the operating frequency in a subset of hardware engines for a processor according to various embodiments of the invention. The method 4600 may, for example, be performed in whole or in part on the device 105 of FIG. 1 or 2 or, more specifically, using the device 105-f of FIG. 41, the configuration 4200 of FIG. 42, or the device 105-g of FIG. 43.

At block 4605, a first clock output at a first frequency is applied to a first subset of hardware engines for a processor of a digitized representation of a wireless communication signal. At block 4610, when operating in a first mode, a second clock output at substantially the first frequency is applied to a second subset of hardware engines for the processor. At block 4615, the processor dynamically changes from the first mode to a second mode in response to an attribute of the wireless communication signal. At block 4620, the second clock output is changed from the first frequency to a second frequency. At block 4625, the second clock output at the second frequency is applied to the second subset to operate in the second mode.

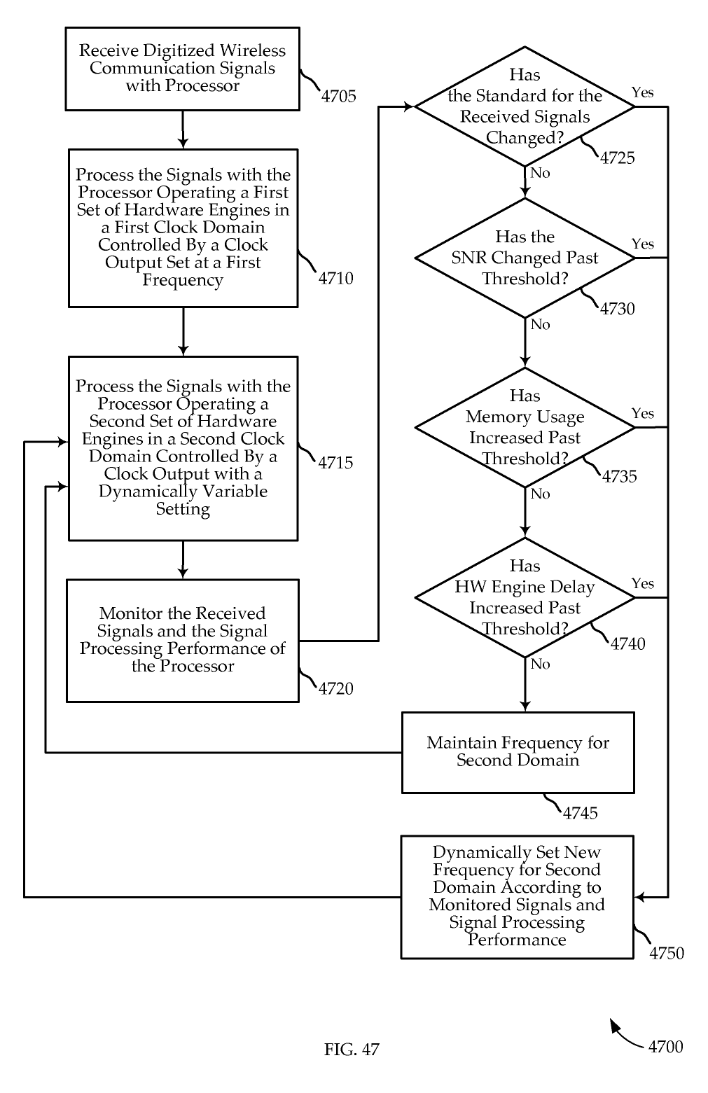

FIG. 47 is a flowchart illustrating a method 4700 for responsively modifying the operating frequency in a subset of hardware engines for a processor according to various embodiments of the invention. The method 4700 may, for example, be performed in whole or in part on the device 105 of FIG. 1 or 2 or, more specifically, using the device 105-f of FIG. 41, the configuration 4200 of FIG. 42, or the device 105-g of FIG. 43.

At block 4705, digitized wireless communication signals are received. At block 4710, the signals are processed with a processor operating a first set of hardware engines in a first clock domain controlled by a clock output set at a first frequency. At block 4715, the signals are processed with the processor operating a second set of hardware engines in a second clock domain controlled by a clock output with a dynamically variable setting.

At block 4720, the received signals and the signal processing performance of the processor are monitored. At block 4725, a determination is made whether the standard for the received signals has changed to DVB-H 8K. If not, at block 4730, a determination is made whether the SNR has changed past threshold. If not, at block 4735, a determination is made whether memory usage has increased past threshold. If not, at block 4740, a determination is made whether a hardware engine delay has increased past threshold. If not, at block 4745, frequency for the second domain is maintained, and the monitoring continues to block 4715.

If 1) the standard for the received signals changed to DVB-H 8K at block 4725, 2) the SNR changed past the threshold at block 4730, 3) the memory usage increased past the threshold at block 4735, or 4) the hardware engine delay increased past threshold at block 4740, the process shifts to block 4750, wherein a new frequency for the second domain is dynamically set according to monitored signals and signal processing performance. The monitoring then continues at block 4715.

5. Harmonics Avoidance: In a number of embodiments, clock units run the digital logic for the hardware engines of a device at one or more speeds, as described in more detail above. The device may, for example, be the device 105 described with reference to FIGS. 1 and 2. However, running the digital logic at a given frequency may create harmonics, which are component frequencies of the signal at integer multiples of the one or more clock speeds. For example, for a given frequency f, the harmonics off are 2f, 3f, 4f, 5f, etc. Assuming a clock unit (e.g., clock 2260 of FIGS. 22-23, or clock unit 4105 of FIGS. 41-44) is running at 64 MHz, harmonics may be produced at multiples of 64 MHz (e.g., 128 MHz, 256 MHz, 1.024 GHz, etc.). If the harmonics of sufficient energy fall on one or more carriers (e.g., at 1.024 GHz) of an analog signal being received (e.g., via the antenna 205 and analog processing units 260 of FIG. 2), the harmonics may cause errors and associated performance issues.

Therefore, in one set of embodiments, a device 105 may be configured to address harmonics avoidance. By way of example, a device 105 may monitor noise at various processing stages (e.g., measured through error rates and signal strength). If performance degrades beyond certain threshold levels, the device may dynamically change the clock speeds to avoid harmonics.

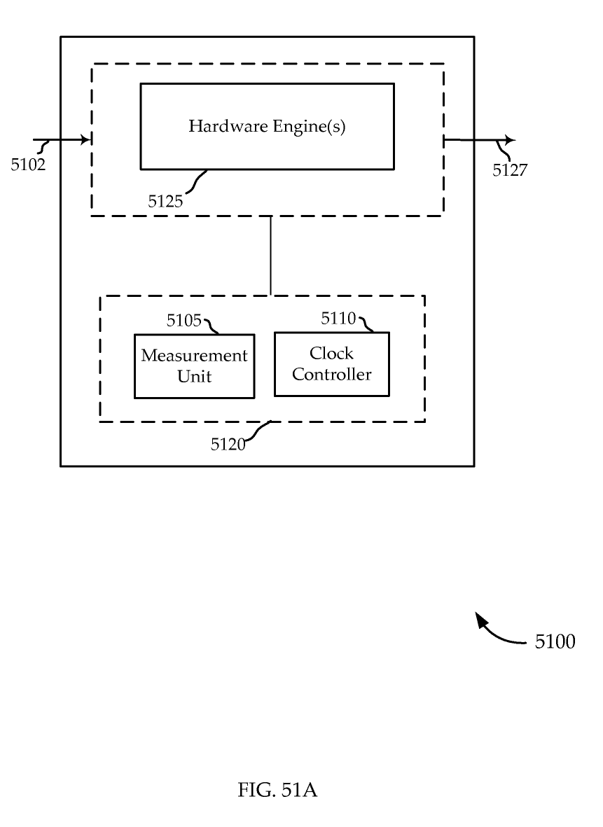

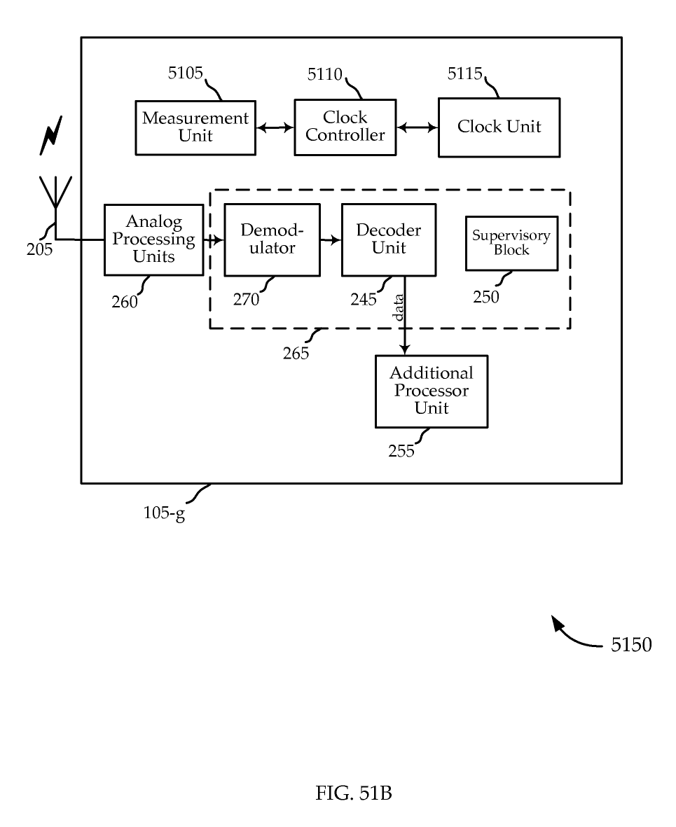

Referring first to FIG. 51A, a block diagram is shown illustrating a device 5100 including an example configuration for selectively changing clock speeds to avoid harmonics at hardware engines 5125. This device 5100 may represent the device 105 of FIG. 1 or 2, although the illustrated configuration may be utilized in a number of different processors or devices. A digitized version of a wireless communication signal 5102 is received at the set of hardware engine 5125 (perhaps after being received and digitized by analog processing units (not shown)).

For purposes of explanation, first assume the hardware engines are each operating to process a stream of data representative of the wireless communication signal transmitted according to one of a number of different standards (e.g., DVB-H, DMB, ISDB-T). The device 5100 may switch between modes to process data in each of a number of different standards. The hardware engines 5125 may each be a hardware engine of FIG. 2, such as a symbol synchronization unit 220, FFT unit 225, carrier frequency offset unit 230, equalizer unit 235, de-interleaver unit 240, or decoder unit 245, or may be any combination or subset thereof.

The device also includes a controller 5120, which may be the supervisory block 250 of FIG. 2, the additional processing unit 255 of FIG. 2, a combination thereof, or another processor or set of processors. The controller 5120, or particular components thereof, may be configured to monitor performance at various processing stages for the set of hardware engines 5125, and modify clock speeds running the hardware engines when the performance degrades. Although the example device 5100 shows that the controller 5120 controls the hardware engines 5125, in other embodiments, there may be any number of hardware engines and other components (e.g., other memory, analog processing units, etc.) individually or collectively controlled by controller 5120. The controller 5120 may include a measurement unit 5105 and a clock controller 5110. The controller 5120 may be configured to dynamically change the frequencies at which the engine or set of engines are running in response to noise measurements on a stream of data through the device 5100.

The measurement unit 5105 may, therefore, be configured to monitor processing of the stream of data through the hardware engines and perform one or more noise measurements. For example, the measurement unit 5105 may be configured to perform the noise measurement by measuring a bit error rate or other error related metric attributed to a stream of data (e.g., measuring error identification and, perhaps, correction for the stream of data). In addition, or alternatively, the measurement unit 5105 may be configured to perform aspects of the noise measurement by measuring a signal to noise ratio or another measure of signal strength attributed to the wireless digital video signal. The measurement unit 5105 may receive, or otherwise generate, a threshold level which will trigger modification of the clock speeds being applied to the hardware engines.

When it is determined that the threshold noise measurement has been met or exceeded, the clock controller 5110 may transmit an interrupt signal to suspend processing of the wireless digital video signal at the hardware engines 5125 before the clock output frequency is changed. The clock controller 5110 may change the clock output by transitioning directly from the first frequency to the second frequency by modifying the divide by logic in the phase-locked loop. Alternatively, the clock controller 5110 may be configured to transition the digital logic from the current frequency to a frequency of the local oscillator, then transition the digital logic from the frequency of the local oscillator to a new frequency.

Once changed, the clock controller 5110 may monitor the stability of the clock output at the new frequency, and control the hardware engines 5125 to resume processing of the digitized wireless signal when the monitored stability exceeds a stability threshold. After the change, the measurement unit 5105 may receive or identify a change in the threshold level for the noise measurement (e.g., changing the bit error rate or signal to noise ratio factors that will trigger changing the frequencies). This changed threshold may be permanent, temporary, or may gradually shift back to a standard level as time passes after a transition. The threshold levels for the noise measurements may vary across different standards. These different thresholds may be implemented, for example, because there may be certain standards that are more or less prone to harmonics issues based on their standard operating frequencies and/or the frequency bands in which their signals are typically transmitted.

There are a number of different ways in which a device 5100 may identify a new frequency to be used for a transition. For example, a device may look up a new frequency in a table listing a set of alternative frequencies available for transition. The different sets of frequencies may be listed in the table for each standard of a number of mobile digital video standards. After processing by the hardware engines 5125, the mobile digital video data may be forwarded 5127 to another component or off of the device (e.g., to a display for viewing). It is worth noting that some or all of the functions of the controller 5120 and any components therein may, individually or collectively, be implemented with one or more Application Specific Integrated Circuits (ASICs) adapted to perform some or all of the applicable functions in hardware. Alternatively, the functions may be performed by one or more other processing units (or cores), on one or more integrated circuits. In other embodiments, other types of integrated circuits may be used (e.g., Structured/Platform ASICs, Field Programmable Gate Arrays (FPGAs), and other Semi-Custom ICs), which may be programmed in any manner known in the art. The functions may also be implemented, in whole or in part, with instructions embodied in a memory, formatted to be executed by one or more general or application-specific processors.

Referring to FIG. 51B, a block diagram 5150 illustrates an example mobile communications device 105-g which may be configured to process signals in a manner to avoid the noise related to harmonics. This device 105-g may, for example, be the device 105 of FIG. 1 or 2, or the device 5100 of FIG. 51A. The simplified block diagram shows the device 105-g including an antenna 205, analog processing units 260, demodulator 270, decoder unit 245, supervisory block 250, and an additional processor unit 255 (e.g., an on or off chip CPU, host processor, or combination thereof). The device 105-g also includes a clock unit 5115 (e.g., clock 2260 of FIGS. 22-23, or clock unit 4105 of FIGS. 41-44). The clock unit 5115 may generate one or more frequencies to be applied to some or all of the hardware engines in the hardware block 265. The device 105-g includes one or more memory units (not explicitly shown in this embodiment, but illustrated elsewhere) used for a variety of purposes.

In one embodiment, an RF signal is received via an antenna 205, and down-converted and digitized by the analog processing units 260. The harmonics of the clock unit 5115 may be at frequencies which interfere with one or more carriers of the RF signal. The harmonics may thereby cause noise and other performance problems resulting in errors as the digitized signal is processed by the demodulator 270, decoded by the decoder unit 245, and processed further by the additional processor unit 255.

The device 105-g may also include a measurement unit 5105, which may be configured to perform or receive any of the following error, signal, and noise measurements and detections, which may collectively be referred to hereinafter as “noise measurements.” Thus, the measurement unit 5105 may be configured to perform a noise measurement by detecting the rate of errors of the signal. For example, the measurement unit 5105 may measure the rate, level, or other metric of error detection and/or correction at the decoder unit 245. A bit-error rate (BER) may be measured at the additional processor unit 255 or the measurement unit 5105. A variety of other error measurement metrics may be used. The measurement unit 5105 may also be configured to detect the signal quality using other metrics as well. For example, the measurement unit 5105 may measure the rate, level, or other metric of signal quality or signal strength before, during, or after processing at the analog processing units 260, demodulator 270, decoder unit 245, supervisory block 250, and/or the additional processor unit 255. A signal to noise ratio (SNR) may be measured at any combination of the units. The signal quality and noise measurements may be directed to certain subsets of the frequencies, or be less directed. A variety of other signal quality metrics may be used.

In one embodiment, the measurement unit 5105 monitors for errors at one or more processing stages. When measured errors exceed a threshold level, the measurement unit 5105 may monitor the signal strength. If the measured signal strength is over a threshold, the measurement unit 5105 may send an interrupt signal, which may result is suspending processing of the mobile digital video signal at the hardware block 265 while the frequency is transitioned. Once the processing of the mobile digital video signal is resumed, the measurement unit 5105 may continue the monitoring.

A number of different techniques may be used, as well. For example, the device 105-g may send location data (e.g., GPS data) to a headend unit or other central server (e.g., the headend unit 115 or data source 125 of FIG. 1). A central server could transmit region- or location-specific signal strength information back to the device 105-g to provide additional information to the device 105-g to discern whether errors are due to a weak signal or due to harmonics. In another embodiments, a signal to noise ratio may be monitored for sudden degradation when a signal is being acquired (e.g., because of a change in ISDB-T channel). If the signal to noise ratio degrades quickly, this may trigger the clock output frequency modification, as well.

Thus, in a number of embodiments, a device 105-g may be configured to automatically modify the frequency or frequencies being generated by the clock unit 5115 when metrics produced by the measurement unit 5105 (or otherwise received) exceed certain thresholds. The thresholds triggering the modification may be preset, or may be set or adjusted dynamically. For example, in a low signal strength environment, the thresholds may be raised to have the modification occur only with very degraded performance metrics. In a high signal strength environment, the thresholds may be changed to have the modification occur with less degraded performance metrics. The threshold levels may include error rate, noise levels, signal strength, or any combination thereof, and may also include other signal quality metrics. The threshold levels may include a time component as well, requiring sustained levels for a period of time.

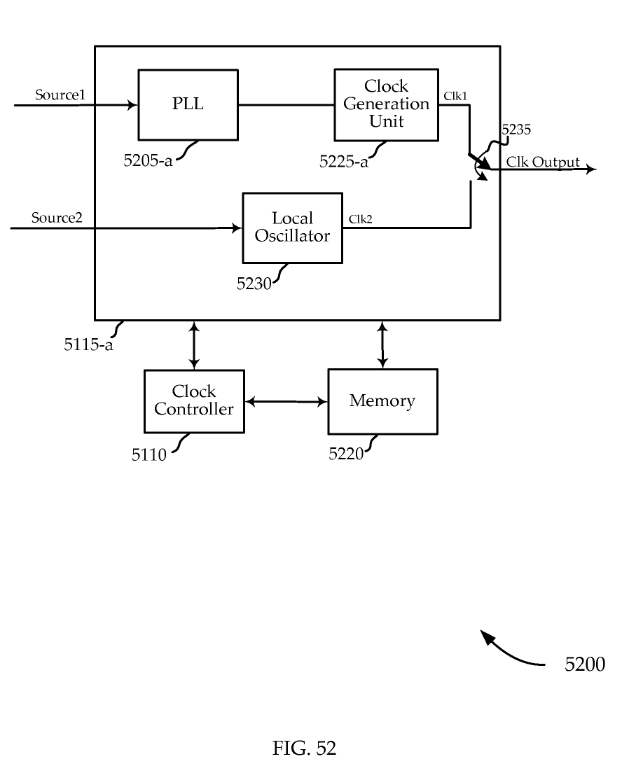

The device 105-g may also include a clock controller 5110, configured to control the output frequency or frequencies. By way of example, the clock controller 5110 may be configured to control the PLL (and its output frequency) and/or a clock generation unit (and its output frequency) for a clock unit 5115. FIG. 52 illustrates an example clock configuration 5200, which may be used for the device 105-g. The clock unit 5115-a of FIG. 52 includes a PLL 5205-a, which receives a clock input from a source (on or off chip), and typically outputs a higher frequency to clock generation unit(s) 5225-a. The clock generation unit(s) 5225-a may be made up of one or more downconverters (e.g., divide-by logic), which receive the output of the PLL and modify the signal to generate a particular clock output. The clock controller 5110 may also be configured to control particular clock generation units 5225-a (e.g., downconverters or dividers) and each of their respective output frequencies. The clock controller 5110 may be controlled by or integrated with, in whole or in part, supervisory block 250 or the additional processor unit 255 (e.g., on or off chip CPU or host processor).

The clock unit 5115-a of FIG. 52 also includes the ability to output a temporary frequency before shifting to the modified frequency. The clock output may first transition from a current frequency (clk1) generated by clock generation unit 5225-a to a frequency of a local oscillator 5230 (clk2), and then transition back to the clock generation unit 5225-a once the newly selected frequency has stabilized. For example, assume that the default speed (71.7 MHz) is being output at clock generation unit 5225-a. To transition to an available output frequency (e.g., 83.3 MHz), instead of switching directly to 83.3 MHz, a switch 5235 may first transition from 71.7 MHz to 48 MHz of a local oscillator clock 5230, and then transition back to the stabilized 83.3 MHz, to avoid glitches. In one embodiment, the local oscillator 5230 is used as an interim source only if frequency errors or other indicia of a glitch are detected during a direct transition.

The clock configuration 5200 of FIG. 52 also includes memory 5220 (in communication with the clock controller 5110 and clock unit 5115-a), which may store the thresholds that trigger the modification of the output frequency or frequencies of the clock unit 5115-a. The thresholds may vary for any of the reasons cited above, or may vary based in part on the applicable standard, mode, application (e.g., phone, data, or video), etc.

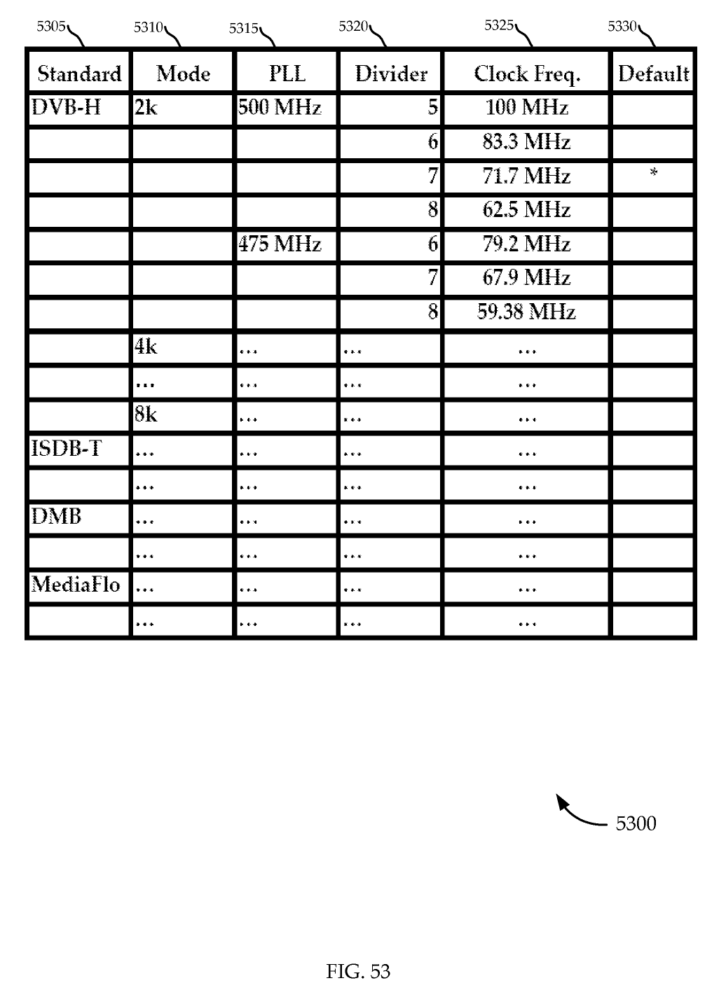

The memory 5220 may also include one or more tables formatted to indicate particular output frequencies which may work with different standards. Turning to FIG. 53, a simplified example of such a table 5300 is shown for purposes of illustration. Table 5300 includes a listing of output frequencies for use with each of a number of standards 5305 (e.g., DVB-H, DMB, ISDB-T, Media-Flo) and modes 5310. In one embodiment, a PLL column 5315 indicates a PLL frequency to be used for the particular standard and mode. A divider column 5320 indicates the various divide-by options available for a particular standard and mode. An output frequency column 5325 indicates the applicable output frequency. A default column 5330 may indicate a particular setting to be used as the default setting. Note that in other embodiments, instead of changing the divide-by logic, the PLL frequency may be changed. Similarly, a given PLL 5315 column may include multiple PLL frequencies with different divider options for each. A range of alternative options are available.

Turning to the use of the table 5300, assume that the default speed (71.7 MHz) is being used, and a threshold noise level is exceeded (e.g., as measured by the measurement unit 5105 of FIG. 51A or 51B). The clock controller 5110 of FIG. 51A, 51B, or 52 may be configured to access the table to determine the available output frequencies (e.g., 83.3 MHz) that may be used for the given standard. The memory 5220 may store recent modifications, and steer the clock controller 5110 away from recently identified noisy frequencies.

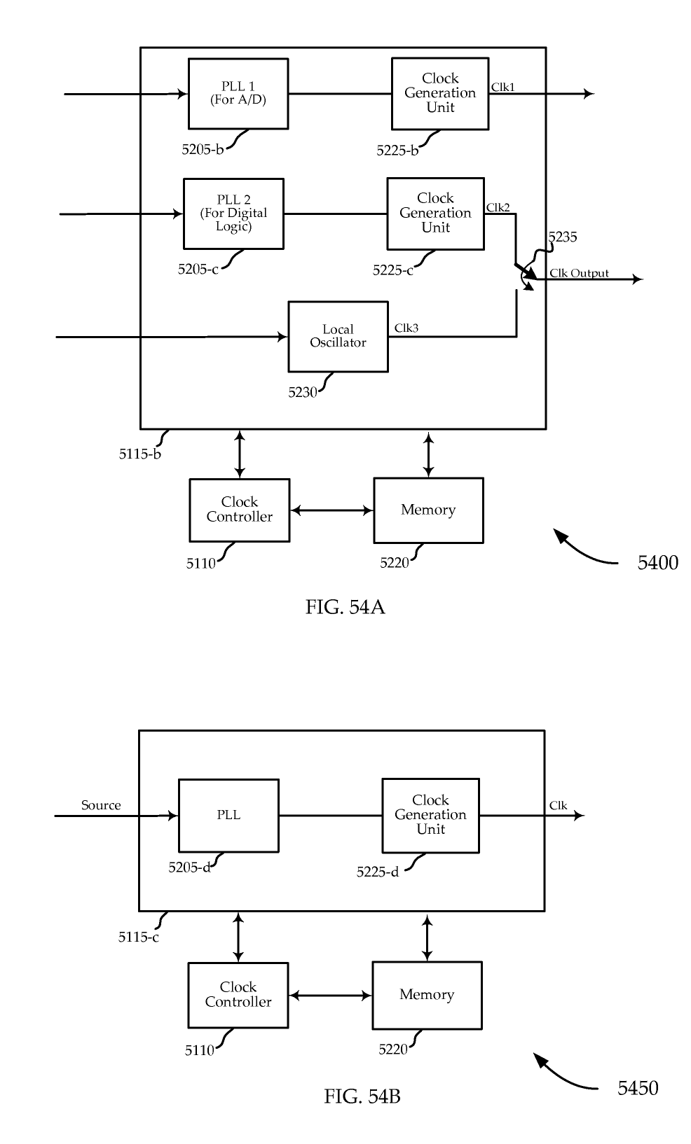

FIG. 54A illustrates an alternative example clock configuration 5400, which may also be used for the device 5100 of FIG. 51A or the mobile communications device 105-g of FIG. 51B. The clock unit 5115-b of FIG. 54A includes a first PLL 5205-b for an A/D converter (e.g., analog processing units 260 of FIG. 51B), and a second PLL 5205-c for the digital logic (e.g., digital logic for hardware block 265). Each PLL 5205 receives a clock input from a source (on or off chip), and typically outputs a higher frequency to respective clock generation unit(s) 5225-b, 5225-c. This configuration may allow more transitional options because the second PLL 5205-c for the digital logic is free to transition more freely without being constrained by the PLL 5205-b setting needed for the A/D. In one embodiment, the clock unit 5115-b of FIG. 54A also includes a switch 5235 to allow use of the local oscillator clock 5230 before shifting to the modified frequency.

FIG. 54B illustrates yet another alternative example clock configuration 5450, which may also be used for the device 5100 of FIG. 51A or the mobile communications device 105-g of FIG. 51B. The clock unit 5115-c of FIG. 54B again includes a PLL 5205-d, which receives a clock input from a source (on or off chip), and typically outputs a higher frequency to clock generation unit(s) 5225-d. In one embodiment, the clock controller 5110 suspends processing of the wireless digital video signal at the hardware engines (e.g., hardware block 265 of FIG. 51B) before the clock is changed. The clock controller 5110 then changes the clock output by transitioning directly from a first frequency to a second frequency using a same phase-locked loop, and simply changing the PLL 5205-d frequency or perhaps the divide-by logic of the clock generation unit 5225-d. The clock controller 5110 may then determine when the second frequency has stabilized, and control the resumption of the wireless digital video signal at the hardware engines.

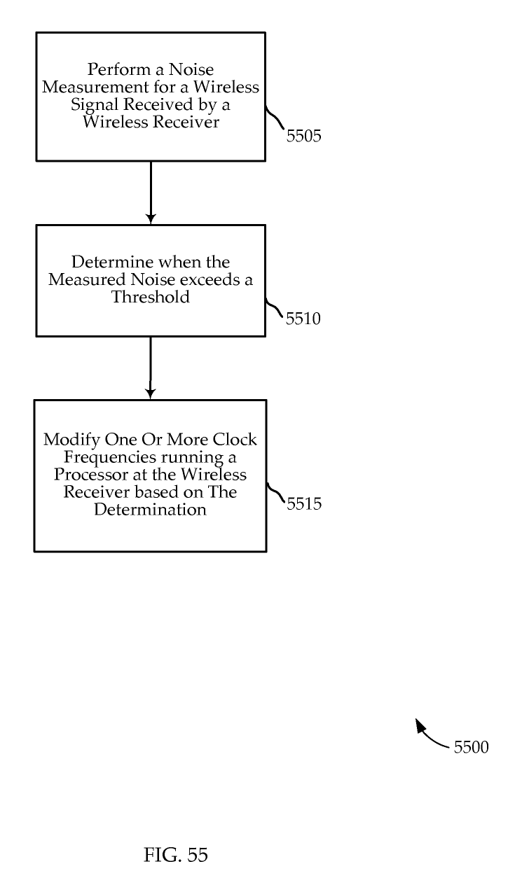

FIG. 55 is a flowchart illustrating a method 5500 for avoiding harmonics in a wireless receiver according to various embodiments of the invention. The method 5500 may, for example, be performed in whole or in part using the device 105 of FIG. 1, 2, or 51B or using the device 5100 of FIG. 51A.

At block 5505, a noise measurement (e.g., the error rate before correction at a decoder combined with received signal strength) is performed for a wireless signal received by a wireless receiver. At block 5510, a determination is made that the measured noise exceeds a threshold. At block 5515, one or more clock frequencies running a processor at the wireless receiver are modified based on the determination.

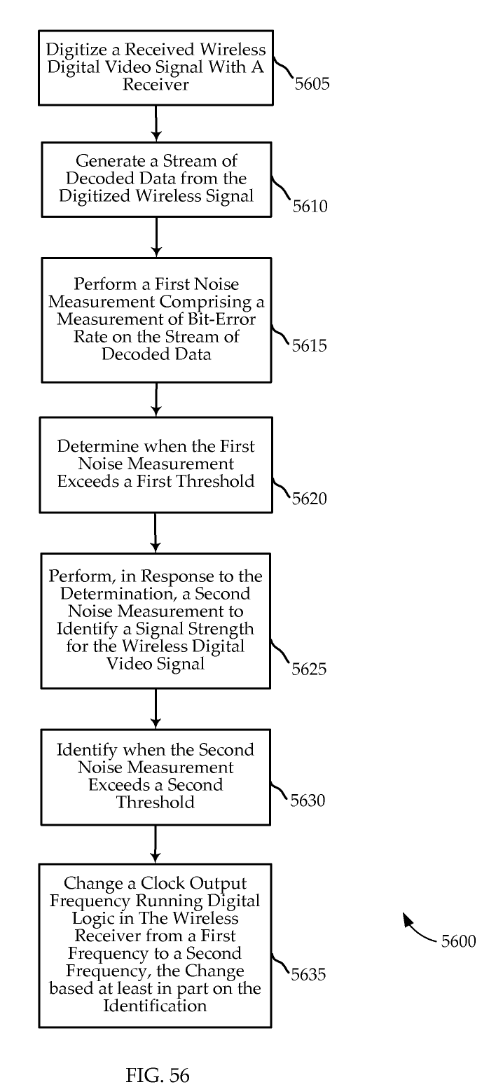

FIG. 56 is a flowchart illustrating a method 5600 for avoiding harmonics in a wireless receiver receiving a wireless digital video signal according to various embodiments of the invention. The method 5600 may, for example, be performed in whole or in part using the device 105 of FIG. 1, 2, or 51B or using the device 5100 of FIG. 51A.

At block 5605, a received wireless digital video signal is digitized. At block 5610, a stream of decoded data is generated from the digitized wireless signal. At block 5615, a first noise measurement comprising a measurement of bit error rate is performed on the stream of decoded data (e.g., a bit error rate before, during, or after correction at a decoder). At block 5620, a determination is made when the first noise measurement exceeds a first threshold.

At block 5625, in response to the determination, a second noise measurement is performed to identify a signal strength for the wireless digital video signal. At block 5630, an identification is made when the second noise measurement exceeds a second threshold. At block 5635, a clock output frequency running digital logic in the wireless receiver is changed from a first frequency to a second frequency, the change based at least in part on the identification.

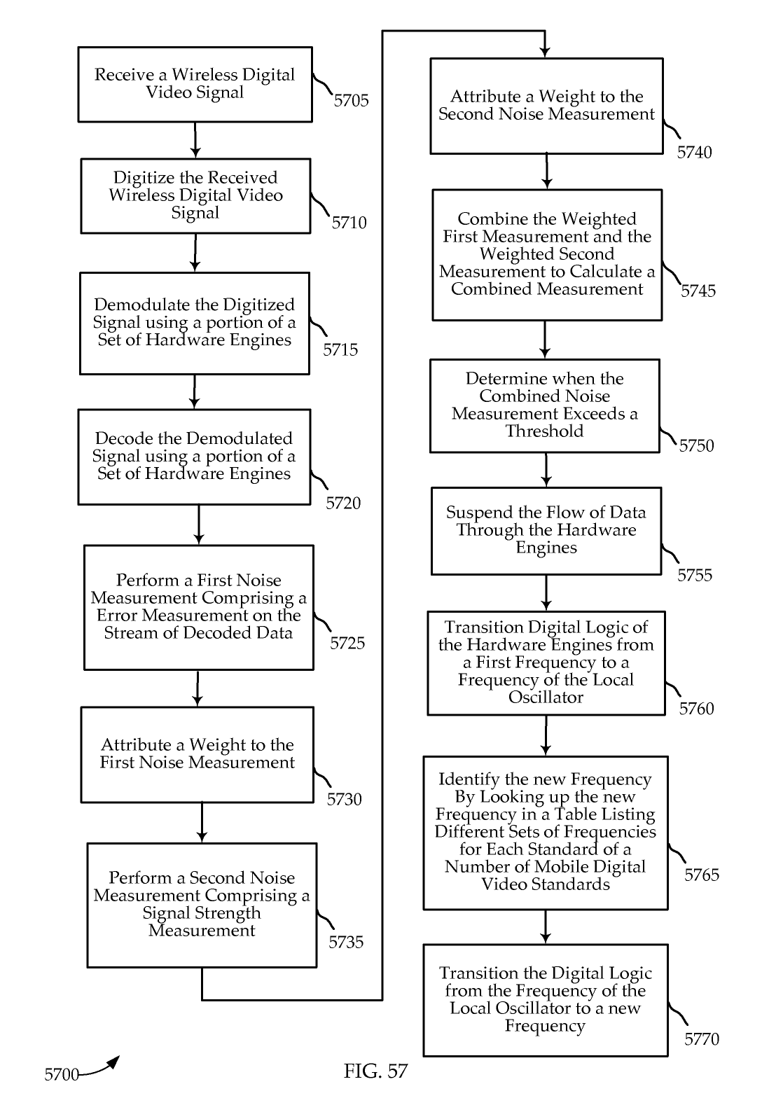

FIG. 57 is a flowchart illustrating a method 5700 for transitioning clock frequencies to avoiding harmonics from the reception of a wireless digital video signal according to various embodiments of the invention. The method 5700 may, for example, be performed in whole or in part using the device 105 of FIG. 1, 2, or 51B or using the device 5100 of FIG. 51A.

At block 5705, a wireless digital video signal is received. At block 5710, the received wireless digital video signal is digitized. At block 5715, the digitized signal is demodulated using a portion of a set of hardware engines. At block 5720, the demodulated signal is decoded using a portion of a set of hardware engines.

At block 5725, a first noise measurement comprising an error measurement is performed for the stream of decoded data. At block 5730, a weight is attributed to the first noise measurement. At block 5735, a second noise measurement comprising a signal strength measurement is performed. At block 5740, a weight is attributed to the second noise measurement. At block 5745, the weighted first measurement and the weighted second measurement are combined to calculate a combined measurement. At block 5750, a determination is made when the combined noise measurement exceeds a threshold.

At block 5755, the flow of data through the hardware engines is suspended in response to the determination. At block 5760, digital logic of the hardware engines is transitioned from the first frequency to a frequency of the local oscillator. At block 5765, the new frequency is identified by looking up the new frequency in a table listing different sets of frequencies for each standard of a number of mobile digital video standards. At block 5770, the digital logic is transitioned from the frequency of the local oscillator to a new frequency.

6. Hardware Taps: In another set of embodiments, a device is configured with a series of taps to capture input to or output from certain hardware engines or components therein. The taps may be implemented to capture data from one of the respective hardware engines of the device 105 of FIG. 1 or 2. Individual taps may be selectively enabled or disabled dynamically (controlled by a tap controller, perhaps in response to real time conditions). The taps may also be used to test or debug the respective units of the device 105. This may be done by pumping a known pattern through an interface, or possibly comparing the actual output of the respective units generated from a known input with an expected output calculated from a known input.

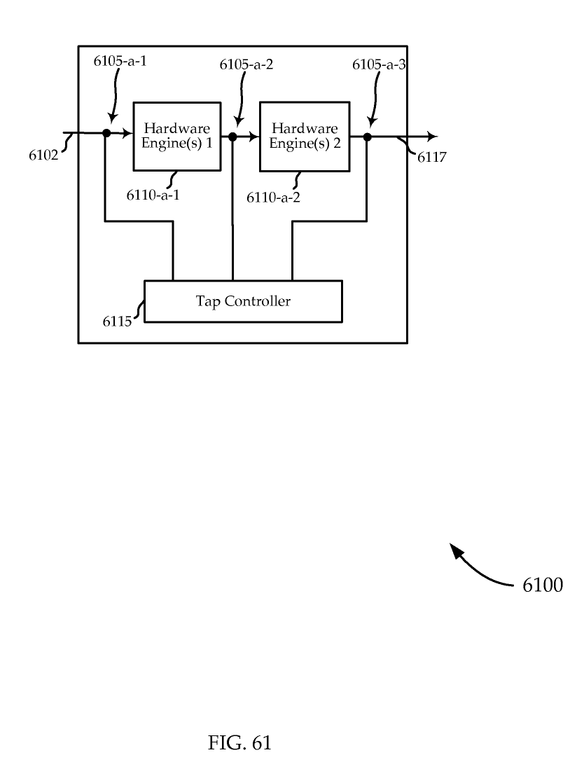

Referring first to FIG. 61, a block diagram is shown illustrating a device 6100 including an example configuration for selectively enabling and disabling taps to collect data input to or output from hardware engines 6110-a. This device 6100 may represent the device 105 of FIG. 1 or 2, although the illustrated configuration may be utilized in a number of different processors or devices. A digitized version of a wireless communication signal 6102 may be received at the set of hardware engine 6110-a (perhaps after being received and digitized by analog processing units (not shown)). In other embodiments, known test signals may be input as the signal 6102. It is further worth noting that, in some embodiments, known test signals may be input at any number of points before or within the chain of hardware engines.

For purposes of explanation, first assume the hardware engines are each operating to process a stream of data representative of the wireless communication signal transmitted according to one of a number of different standards (e.g., DVB-H, DMB, ISDB-T). The device 6100 may switch between modes to process data in each of a number of different standards. The hardware engines 6110-a may each be a hardware engine of FIG. 2, such as a symbol synchronization unit 220, FFT unit 225, carrier frequency offset unit 230, equalizer unit 235, de-interleaver unit 240, or decoder unit 245, or may be any combination or subset thereof.

The device also includes a number of taps 6105-a, each connected with a different input to or output from one of the hardware engines 6110-a, and configured to collect data from the respective input to or output from a hardware engine 6110-a or component therein. The taps 6105 may be selectively turned on or off. The device 6110-a may also include a tap controller 6115, which may be the supervisory block 250 of FIG. 2, the additional processing unit 255 of FIG. 2, a combination thereof, or another processor or set of processors. The tap controller 6115, or particular components thereof, may be configured to control the capture of data on a per tap 6105-a basis. The tap controller 6115 may monitor performance at various processing stages for the set of hardware engines 6110-a (perhaps using the collected data), and determine which taps to enable or disable based on the monitoring. Alternatively, the taps may be enabled and disabled based on other inputs or for other purposes. After processing by the hardware engines 6110-a, the processed date may be output 6117.

The data tapped from each enabled tap may be buffered and transferred in a number of different ways. For example, in one embodiment there are a number of different buffer units (e.g., FIFOs), each buffer unit coupled with a different tap 6105-a, configured to temporarily store the collected data unit before it is transferred to other, typically longer term, memory. In one embodiment, an arbiter is configured to proceed in round robin fashion through the buffer unit of each enabled tap 6105-a to transfer the collected data. This may be weighted to collect more or less data from certain taps, or collect data more or less often (e.g., with a weighted round robin progression). In another embodiment, the tap controller 6115 is configured to monitor each of the buffer units and generate a request to transfer collected data from a selected buffer unit when storage at the selected buffer unit exceeds a programmable threshold (e.g., programmable on a per unit basis based on size of the buffer unit, importance of the particular output, etc.). The arbiter may be configured to transfer the collected data from the selected buffer unit in response to the request from the tap controller 6115.

In addition, there is a wide range of functionality that may be implemented in an arbiter. For example, an arbiter clock may be configured to run the arbiter at one frequency, which is different than the frequency of the clock running the hardware engines 6110-a. The amount of data to be collected from the enabled taps may be monitored, and the arbiter clock unit may be sped up or slowed down in response to monitoring (e.g., to conserve power).

There are a number of other issues worth noting. For example, a tap 6105-a may be configured to collect data output from a selected hardware engine 6110-a (including its memory), input to a selected hardware engine 6110-a (including its memory), output within a selected hardware engine 6110-a (including its memory), state information from a selected hardware engine 6110-a, or any combination thereof.

As noted, the device 6100 may be a mobile communications device. As such, the device 6100 may be configured to analyze the collected data (e.g., using the additional processing unit 255 of FIG. 2), and change processing at one or more of the hardware engines 6110-a in response to the analyzed data. For example, different hardware resources or different demodulation or decoding algorithms may be used based on an analysis of the collected data. The mobile communications device (e.g., using a control unit such as the additional processing unit 255 of FIG. 2) may also be configured to identify certain collected data to be wirelessly transmitted to a central server computer system from the device (e.g., to the headend unit 115 or data source 125 of FIG. 1). The central server computer system may then process the information, and transmit changes or updates to the mobile communications device based on the remote processing of the collected data. Therefore, there are a number of different ways in which the collected data may be processed, and then serve as the basis for changing the processing or resources used at a device.

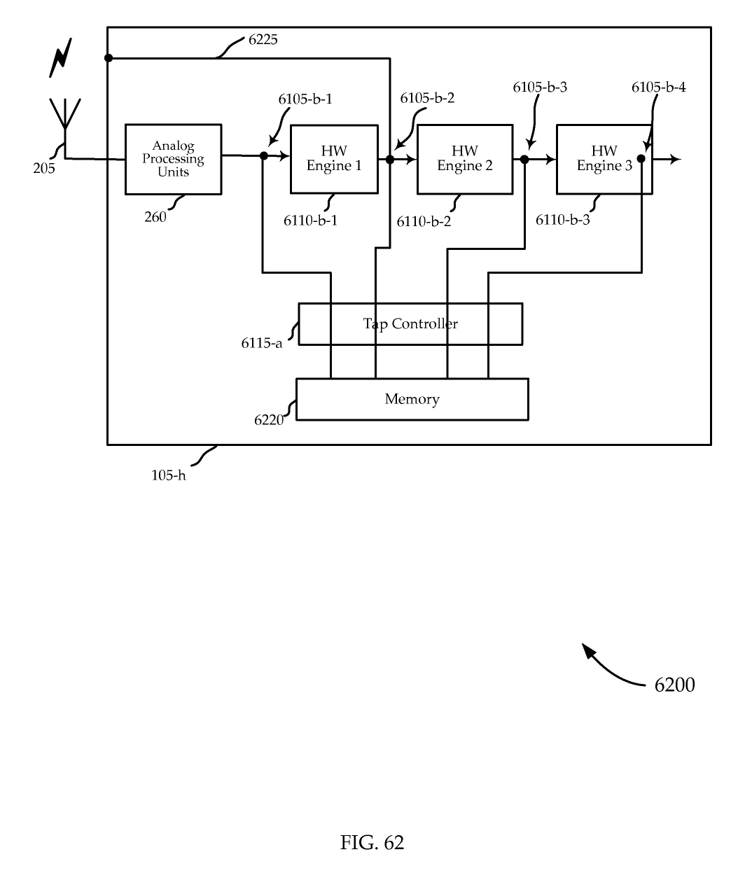

Referring to FIG. 62, a block diagram 6200 of a tap configuration that may be used for a wireless communications device 105-h is shown. This device 105-h may be the device 105 of FIG. 1 or 2, or the device 6100 of FIG. 61, or other types of devices. The simplified block diagram shows a set of components for a wireless device, including an antenna 205, analog processing units 260, and an additional set of hardware engines 6110-b (e.g., the processing units 220, 225, 230, 235, 240 of FIG. 1, or components thereof). Thus, the illustrated hardware engines 6110-b of FIG. 62 may be hardware engines or components of hardware engines. The diagram also illustrates a series of taps 6105-b, to tap data representing the output or input of certain engines 6110-b. Moreover, output of specified components within an engine 6110-b-3 may have a tap 6105-b-4 as well. The components of the device 105-h may be implemented on a single processor or set of processors.

In one embodiment, an RF signal is received via an antenna 205, and down-converted and digitized by the analog processing units 260. The digitized signals are processed and passed through units 6110, and data is captured via the taps 6105. However, as discussed in more detail below, known patterns of data may be pumped into the chip (received from memory or an external source) at certain parts of the data path in lieu of receiving data processed by the analog processing units.

The tap configuration for the device 105-g also includes a controller 6115-a, which may be configured to selectively enable or disable (turn on and off) each of the respective taps 6105-b or output thereof (e.g., so that only a subset of taps may be operating). The tap controller 6115-a may, as noted above, be the supervisory block 250 of FIG. 2, an on or off chip CPU, a host processor, or any combination thereof. The tap configuration of device 105-h may also include memory 6220 to store the output of the taps allowed by the tap controller 6115-a, and the control and management of the memory 6220 may be handled in a variety of ways. For example, memory 6220 may be a number of FIFO buffers, distinct for each tap 6105. Alternatively, memory 6220 may be memory shared by all of the taps 6105. Memory 6220 may be any combination of temporary, more permanent, shared, or distinct memory. The tap controller 6115-a and memory 6220 may be, in whole or in part, either integrated into a mobile communications device 105-h or in a separate device in wired or wireless communication with the device.

There are a number of tap locations possible, and the data capture function may capture samples of A/D output, capture samples of FFT input and output, capture output of de-interleaver, capture Viterbi output, capture an MPE header or frame, capture an MPE-FEC frame, or capture various memories. The tap configuration may capture certain bursts, capture a frame, perform a continuous sampling, or perform a one time capture. A number of other tap locations may be used as well.

As noted, known test data may also be pumped into the device 105-h. An example of such an insertion is shown by the data path 6225, showing how a known pattern of data may be pumped into hardware engine 2 6110-b-2 avoiding hardware engine 1 6110-b-1. A number of similar or alternative techniques may be used to test performance at different points in the chain of hardware engines 6110-b. When a known test pattern of data is used (e.g., via data path 6225 or in lieu of a digitized stream from the A/D), it may be pumped into a processor at a given rate. Thus, the antenna 205 and analog processing units 260 may be bypassed, or even excluded in certain processors used for testing. This data may then be passed through a series of hardware engines (e.g., engines 6110-b) and the data is tapped at certain taps (e.g., taps 6105-b) in the data path. The data taps 6105-b can be selectively enabled or disabled (e.g., by the tap controller 6115-a), and collected data stored in memory 6220.

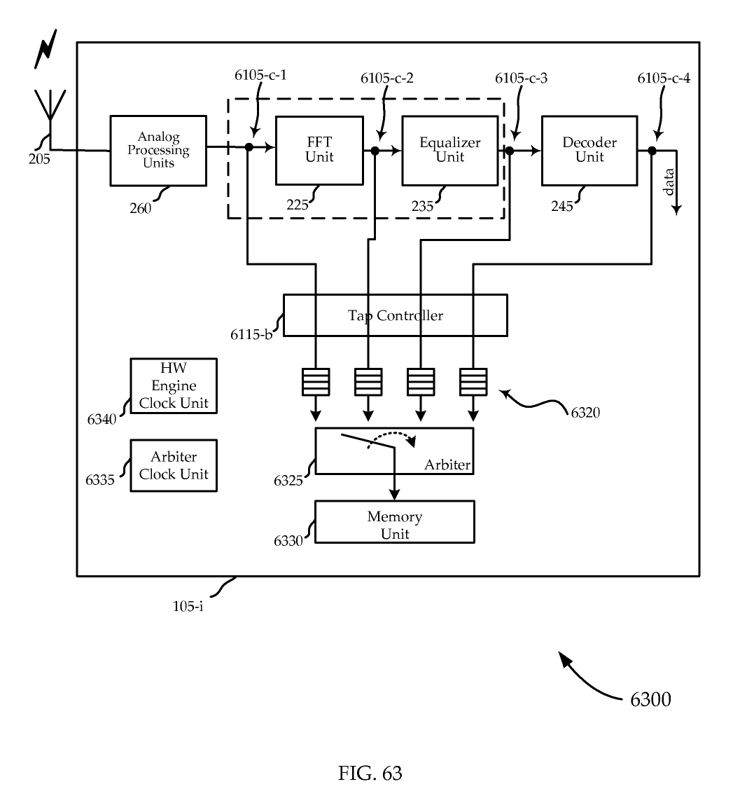

Referring next to FIG. 63, a block diagram 6300 of a tap configuration used for a wireless communications device 105-i is shown. This device 105-i may the device 105 of FIG. 1, 2, or 62, the device 6100 of FIG. 61, or in other devices as well. The simplified block diagram shows a set of components for a wireless device, including an antenna 205, analog processing units 260, an FFT unit 225, an equalizer unit 235, and a decoder unit 245. There may also be any number of intervening processing units or engines (not shown).

The diagram also illustrates a series of taps 6105-c, to tap data representing the output or input of certain units. In the disclosed embodiment, the taps are at the input 6105-c-1 and output 6105-c-2 of the FFT unit 225, the output 6105-c-3 of the equalizer unit 235, and the output 6105-c-4 of the decoder unit 245. There may be more, or fewer, taps in other embodiments, placed in different locations. Moreover, output of specified components within a unit (e.g., the input or output of a time domain or frequency domain interpolation unit in the equalizer unit 235) may have a tap 6105-c as well.

In one embodiment, an RF signal is received via an antenna 205, and down-converted and digitized by the analog processing units 260. The digitized signals are processed and passed through the FFT unit 225, the equalizer unit 235, and the decoder unit 245, and data captured via the taps 6105-c. However, as discussed previously, known patterns of data may be pumped into the chip (received from memory or an external source) at certain parts of the data path in lieu of receiving data processed by the analog processing units 260. Thus, in certain embodiments, the tap configuration of FIG. 63 may be implemented on a processor, with the antenna 205 and analog processing units 260 excluded.

The tap configuration of FIG. 63 also includes a tap controller 6115-b, which may be configured to enable and disable (turn on and off each of the respective taps 6105-c or outputs thereof so that only a subset of taps may be operating). The tap controller 6115-b may be the supervisory block 250 of FIG. 2, an on or off chip CPU, a host processor, or any combination thereof. For example, the supervisory block 250 registers may be programmed by the CPU of a host processor.

The data tapped from different taps 6105-c may be collected into different buffer units 6320 (e.g., FIFOs). In one embodiment, the each buffer unit 6320 may be distinct, and may be set up to service only one tap 6105-c at a time. The particular tap 6105-c served by a buffer unit 6320 may be programmable, or fixed. An arbiter unit 6325 may be configured to pick data from one of these buffer units 6320 and transfer the data on to pins and through to another memory unit 6330 (memory which may be shared among taps and for other purposes). If the data from more than one buffer unit 6320 is to be sent on to pins or other memory unit 6330, then the arbiter unit 6325 may proceed in a round robin manner, jumping from one buffer unit 6320 to another sending chunks of data from different units to the pins. The round robin progression may be weighted. For example, the weighting may be based on the rate of data capture, the importance of certain data, or weighted toward a certain comparison being sought. Along with the data, an address or other identifier that corresponds to the buffer unit 6320 may be sent. The received data from the taps 6105-c may be captured via a logic analyzer from the pins. The data may be displayed for one or more side-by-side comparisons.

If a tap 6105-c is enabled, the data may be put into its corresponding buffer unit 6320 on every clock cycle. The logic of arbitration and transferring data from buffer unit 6320 to memory unit 6330 may be run on a different frequency than a hardware engine clock unit 6340 running the hardware engines 6110-c. The arbiter clock unit 6335 for the arbiter unit 6325 may be set to a frequency so that the bandwidth on the pins is equal to the sum of the bandwidth required by individual taps 6105-c that are turned on. Thus, the amount of data to be collected from the enabled taps may be monitored, and the arbiter clock unit 6335 may be sped up or slowed down in response to monitoring (e.g., to conserve power).

If the buffer unit 6320 has reached a certain programmed storage threshold in a given queue, a request may be generated to the arbiter unit 6325 to transfer the data. The tap controller 6115-b may be configured to monitor each of the buffer units 6320 and generate a request to transfer collected data from a selected buffer unit 6320 when storage at the selected buffer unit 6320 exceeds a programmable threshold (e.g., programmable on a per unit basis based on size of the buffer unit 6320, importance of the particular output, etc.). The arbiter unit 6325 may be configured to transfer the collected data from the selected buffer unit 6320 in response to the request from the tap controller 6115-b. The data transfer decision for an arbiter unit 6325 can happen during a previous data transfer, so that it is not necessary to take an extra cycle to decide. It is worth noting that the memory configuration described above may be modified or changed in other embodiments (e.g., the memory 6220 of FIG. 62 may be the buffer unit 6320 and memory unit 6330 of FIG. 63). The control and management of the memory may also be handled in a variety of ways. These components may be, in whole or in part, either integrated into a device or in a separate device in wired or wireless communication with the device. There are a number of tap locations possible, as well.

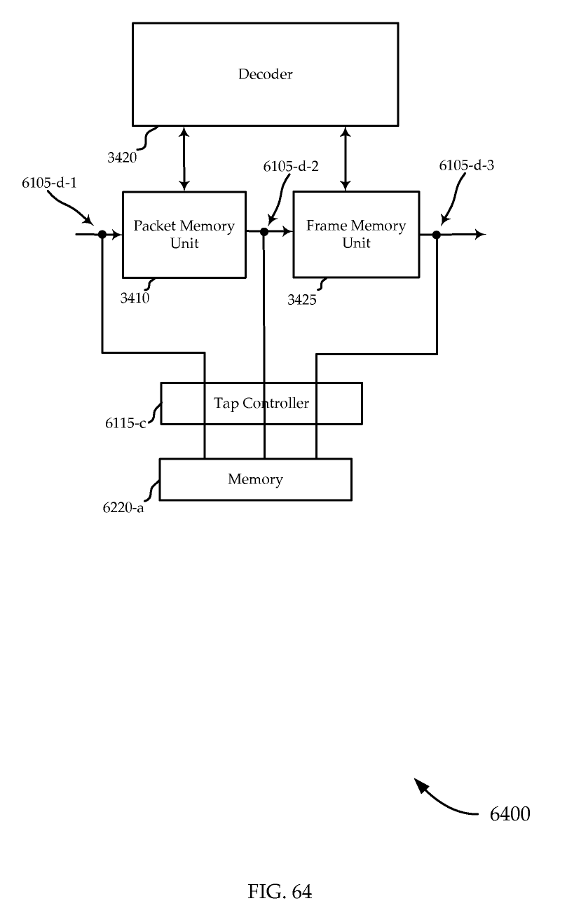

Referring next to FIG. 64, a block diagram of a tap configuration 6400 that may be used for a wireless communications device is shown. This tap configuration 6400 is related to the decoder unit 245-a described with reference to FIG. 34. However, variants of this configuration may be used for a range of components for the device 105 of FIG. 1, 2, 62, or 63, the device 6100 of FIG. 61, or in other devices as well. The simplified block diagram shows a set of components, including a packet memory unit 3410 and frame memory unit 3425, along with an decoder 3420. These may be components of the decoder unit 145-a described with reference to FIG. 34.

Thus, packets may be received from a demodulator 270 or other data path, and stored in the packet memory unit 3410. These may be TS packets with appended or otherwise integrated parity code. The decoder 3420 may detect errors and correct these packets using the parity information, and the payload data may be forwarded to the frame memory unit 3425 where a frame is reconstructed. Once the frame is filled, rows of the frame may be corrected. Taps 6105 may be placed at the input 6105-d-1 to the packet memory unit 3410, at the output 6105-d-2 to the packet memory unit 3410, and at the output 6105-d-3 to the frame memory unit 3425.

The tap configuration 6400 also includes a tap controller 6115-c, which may be configured to turn on and off each of the respective taps 6105-d or output thereof (e.g., so that only a subset of taps may be operating). The tap controller 6115-c may be the supervisory block 250 of FIG. 2, an on or off chip CPU, a host processor, or any combination thereof. For example, the supervisory block 250 registers may be programmed by the CPU of a host processor. The output of the taps 6105-d may be stored in memory 6220-a (e.g., the buffer unit 6320 and/or memory unit 6330 of FIG. 63), or otherwise stored as described above. In this embodiment, a variable rate arbiter unit (e.g., such as the implementation using the arbiter clock unit 6335 and arbiter unit 6325 of FIG. 63) may be appropriate, as a high error environment could otherwise put excessive strain on an arbiter unit. Those skilled in the art recognize how the buffer and clock management techniques may be specifically tailored to performance flexibility and power preservation.

It is worth noting that the tap controller 6115 of FIGS. 61-64 may be implemented with one or more Application Specific Integrated Circuits (ASICs) adapted to perform some or all of the applicable functions in hardware. Thus, the tap controller 6115 may be implemented with the supervisory block 250 of FIG. 2. Alternatively, the functions may be performed by one or more other processing units (or cores), on one or more integrated circuits. In other embodiments, other types of integrated circuits may be used (e.g., Structured/Platform ASICS, Field Programmable Gate Arrays (FPGAs), and other Semi-Custom ICs), which may be programmed in any manner known in the art. The functions of each unit may also be implemented, in whole or in part, with instructions embodied in a memory, formatted to be executed by one or more general or application-specific processors. Thus, the tap controller 6115 may be implemented with the additional processor unit 255 of FIG. 2. The tap controller 6115 functionality may also be divided among processing units, or be a stand alone processor or hardware engine using a distinct set of resources.

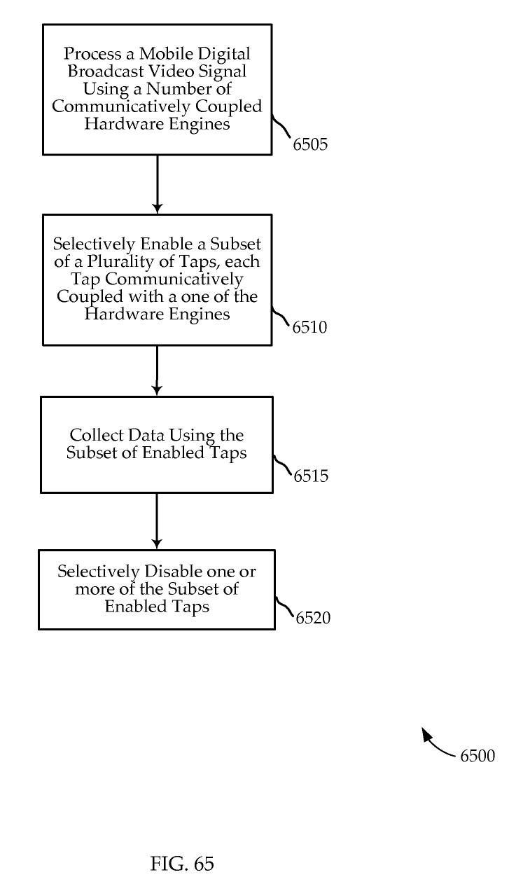

FIG. 65 is a flowchart illustrating a method 6500 for utilizing taps to collect data according to various embodiments of the invention. The method 6500 may, for example, be performed in whole or in part using the device 105 of FIG. 1, 2, 62, or 63, using the device 6100 of FIG. 61, or using the configuration 6400 of FIG. 64.

At block 6505, a mobile digital broadcast video signal is processed using a number of communicatively coupled hardware engines. At block 6510, a subset of a plurality of taps is selectively enabled, each tap communicatively coupled with a one of the hardware engines. At block 6515, data is collected using the subset of enabled taps. At block 6520, one or more of the subset of enabled taps is selectively disabled.

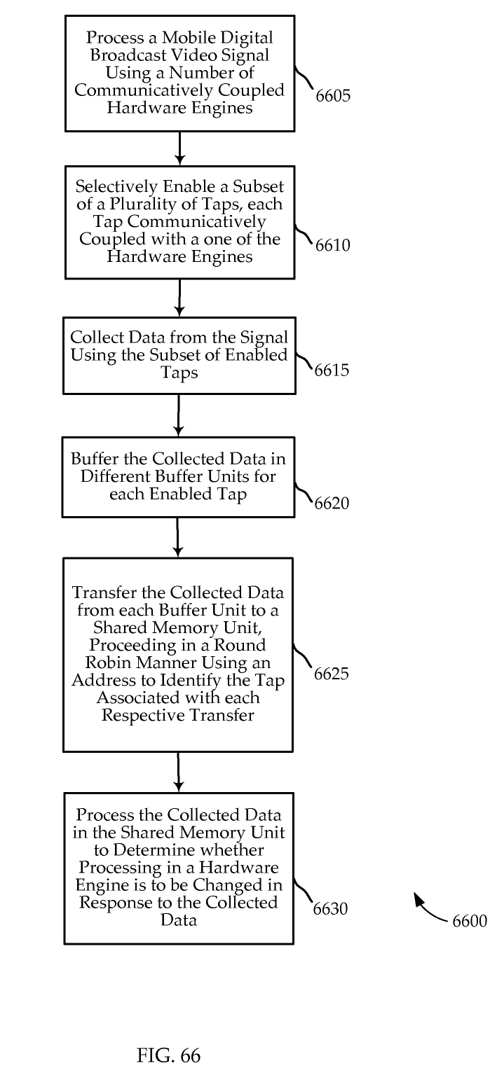

FIG. 66 is a flowchart illustrating a method 6600 for utilizing taps to collect data when receiving a digital video broadcast signal according to various embodiments of the invention. The method 6600 may, for example, be performed in whole or in part using the device 105 of FIG. 1, 2, 62, or 63, using the device 6100 of FIG. 61, or using the configuration 6400 of FIG. 64.

At block 6605, a mobile digital video broadcast signal is processed using a number of communicatively coupled hardware engines. At block 6610, a subset of a plurality of taps is selectively enabled, each tap communicatively coupled with a one of the hardware engines. At block 6615, data is collected from the signal using the subset of enabled taps. At block 6620, the collected data is buffered in different buffer units for each enabled tap. At block 6625, the collected data is transferred from each buffer unit to a shared memory unit, the transfer proceeding round robin through the buffer units using an address to identify the tap associated with each respective transfer. At block 6630, the collected data is processed in the shared memory unit to determine whether processing in a hardware engine is to be changed in response to the collected data.

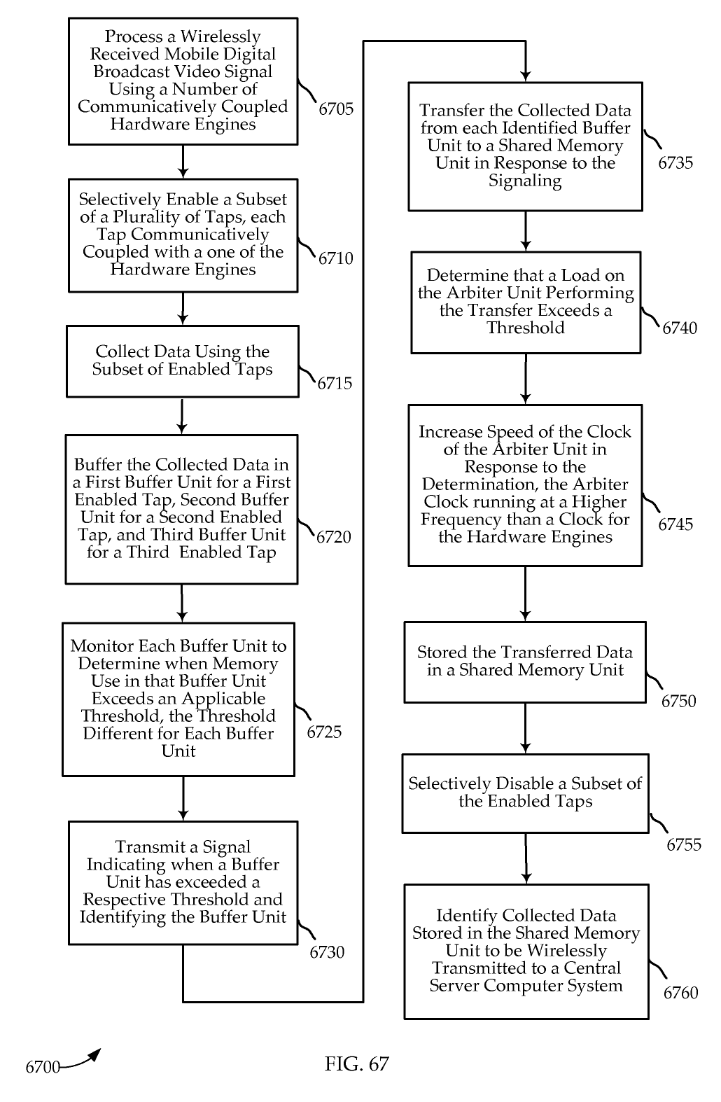

FIG. 67 is a flowchart illustrating a method 6700 for utilizing taps to collect and transfer data when receiving a wireless digital video broadcast signal according to various embodiments of the invention. The method 6700 may, for example, be performed in whole or in part using the device 105 of FIG. 1, 2, 62, or 63, using the device 6100 of FIG. 61, or using the configuration 6400 of FIG. 64.

At block 6705, a wirelessly received mobile digital broadcast video signal is processed using a number of communicatively coupled hardware engines. At block 6710, a subset of a plurality of taps is selectively enabled, each tap communicatively coupled with one of the hardware engines. At block 6715, data is collected using the subset of enabled taps.

At block 6720, the collected data is buffered in a first buffer unit for a first enabled tap, in a second buffer unit for a second enabled tap, and in a third buffer unit for a third enabled tap. At block 6725, each buffer unit is monitored to determine when memory use in that buffer unit exceeds an applicable threshold, the threshold different for each buffer unit. At block 6730, a signal is transmitted indicating when a buffer unit has exceeded a respective threshold and identifying the particular buffer unit. At block 6735, the collected data is transferred from each identified buffer unit to a shared memory unit in response to the signaling.

At block 6740, a determination is made that a load on the arbiter unit performing the transfer exceeds a threshold. At block 6745, the speed of the clock of the arbiter unit is increased in response to the determination, the arbiter clock running at a higher frequency than a clock for the hardware engines.

At block 6750, the transferred data is stored in a shared memory unit. At block 6755, a subset of the enabled taps is selectively disabled. At block 6760, collected data stored in the shared memory unit is identified to be wirelessly transmitted to a central server computer system.

Although aspects of the functionality included within this Detailed Description are described above with reference to various embodiments of device 105, the functionality may be performed by a variety of other components in this or other types of devices. The functions performed by the functional units (e.g., symbol synchronization unit 220, FFT unit 225, carrier frequency offset unit 230, equalizer unit 235, de-interleaver unit 240, decoder unit 245, supervisory unit 250, or additional processor unit 255 (CPU or host), or any components thereof) may, individually or collectively, be implemented with one or more Application Specific Integrated Circuits (ASICs) adapted to perform some or all of the applicable functions in hardware. Alternatively, certain functions may be performed by one or more other processing units (or cores), on one or more integrated circuits. In other embodiments, other types of integrated circuits may be used (e.g., Structured/Platform ASICs, Field Programmable Gate Arrays (FPGAs) and other Semi-Custom ICs), which may be programmed in any manner known in the art. The functions of each unit may also be implemented, in whole or in part, with instructions embodied in a memory, formatted to be executed by one or more general or application-specific processors. It should also be noted that although certain concepts related to sampling rate are set forth, a range of sampling techniques may be employed. Also, while examples of analog and digital filtering are used, certain functionality may be performed in the analog or digital domain.

It should be noted that the methods, systems, and devices discussed above are intended merely to be examples. It must be stressed that various embodiments may omit, substitute, or add various procedures or components as appropriate. For instance, it should be appreciated that, in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner. Also, it should be emphasized that technology evolves and, thus, many of the elements are examples and should not be interpreted to limit the scope of the invention.

Specific details are given in the description to provide a thorough understanding of the embodiments. However, it will be understood by one of ordinary skill in the art that the embodiments may be practiced without these specific details. For example, well-known circuits, processes, algorithms, structures, and techniques have been shown without unnecessary detail in order to avoid obscuring the embodiments.

Also, it is noted that the embodiments may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Moreover, as disclosed herein, the term “memory” or “memory unit” may represent one or more devices for storing data, including read-only memory (ROM), random access memory (RAM), magnetic RAM, core memory, magnetic disk storage mediums, optical storage mediums, flash memory devices, or other computer-readable mediums for storing information. The term “computer-readable medium” includes, but is not limited to, portable or fixed storage devices, optical storage devices, wireless channels, a sim card, other smart cards, and various other mediums capable of storing, containing, or carrying instructions or data.

Furthermore, embodiments may be implemented by hardware, software, firmware, middleware, microcode, hardware description languages, or any combination thereof. When implemented in software, firmware, middleware, or microcode, the program code or code segments to perform the necessary tasks may be stored in a computer-readable medium such as a storage medium. Processors may perform the necessary tasks.

Having described several embodiments, it will be recognized by those of skill in the art that various modifications, alternative constructions, and equivalents may be used without departing from the spirit of the invention. For example, the above elements may merely be a component of a larger system, wherein other rules may take precedence over or otherwise modify the application of the invention. Also, a number of steps may be undertaken before, during, or after the above elements are considered. Accordingly, the above description should not be taken as limiting the scope of the invention.

What is claimed is:

1. A device for receiving wireless communication signals, the device comprising:
an analog processing unit configured to digitize the received wireless communication signals;
a demodulator unit, coupled with the analog processing unit, and configured to generate a stream of data comprising a series of physical layer packets, the stream of data generated from the digitized wireless communication signals; and
a decoder unit comprising a decoder hardware engine and coupled with the modulator unit, and configured to:
decode, using a set of hardware resources of the decoder hardware engine, the series of physical layer packets to generate decoded physical layer packet data to fill at least a part of a first frame; and
decode a selected row of the first frame using the set of hardware resources.

2. The device of claim 1, wherein the decoder unit further comprises:
a first memory configured to store each of the physical layer packets while they are decoded; and
a second memory configured to store the decoded physical layer packet data in a column by column progression for the first frame, wherein the row comprises data from each of a plurality of the series of physical layer packets.

3. The device of claim 1, wherein the decoder unit is further configured to:
wait to decode the first frame until the first frame is filled;
receive data indicating that the first frame is filled; and
decode, upon receiving the data indicating that the first frame is filled, each of the plurality of rows of the first frame using the set of hardware resources.

4. The device of claim 3, wherein the decoder unit is further configured to:
receive data indicating that one or more stored physical layer packets for a second frame are ready to be decoded; and
interrupt the decoding of the first frame to decode the one or more stored physical layer packets.

5. The device of claim 4, wherein the set of hardware resources are configured to process one physical layer packet or one row at a time.

6. The device of claim 4, wherein the decoder unit is further configured to:
complete decoding of the one or more stored physical layer packets to be filled in the second frame; and
resume the decoding of the interrupted first frame after the decoding of the one or more stored physical layer packets is completed.

7. The device of claim 4, wherein the decoder unit is further configured to:
receive data indicating that the decoding for the one or more stored physical layer packets is complete, thereby triggering the decoder unit to resume the decoding of the interrupted first frame.

8. The device of claim 1, wherein the decoder unit is further configured to:
interrupt the decoding of the first frame to decode stored physical layer packets when a number of stored physical layer packets exceed a threshold, the threshold comprising a plurality of physical layer packets.

9. The device of claim 1, wherein the decoder unit is further configured to:
receive data identifying that a standard being used for the wireless communication signal has changed from a first standard to a second standard; and
suspend frame decoding functionality according to the second standard.

10. The device of claim 1, wherein,
the device comprises a mobile communications device;
the decoder unit comprises a Reed-Salomon decoder; and
the first frame comprises a link layer frame.

11. The device of claim 1, wherein,
the device comprises a processor including plurality of hardware engines;
the modulator unit comprises a subset of the plurality of hardware engines; and
the decoder unit comprises one of the plurality of hardware engines.

12. A processor comprising a plurality of hardware engines for processing digitized wireless communication signals, the processor comprising:
a demodulator unit comprising a first subset of the plurality of hardware engines configured to:
receive a digitized version of the received wireless communication signal; and
generate, using the digitized version, a stream of data comprising a series of physical layer packets; and
a decoder unit comprising a second subset of the plurality of hardware engines coupled with the modulator unit, and configured to:
decode the series of physical layer packets to generate decoded data to fill at least a part of a frame using a set of hardware resources of the second subset; and
decode a row of the frame using the set of hardware resources.

13. The processor of claim 12, wherein the processor further comprises:
a first memory region configured to store each of the physical layer packets before they are decoded; and
a second memory region, distinct from the first memory region, and configured to store the decoded physical layer packet data in a column by column progression for the first frame,
wherein the decoder unit corrects identified errors in physical layer packets by manipulating data stored in the first memory region and correct identified errors in the row of the frame by manipulating data stored in the second memory region.

14. The processor of claim 12, wherein the decoder unit is further configured to:
wait to decode the first frame until the first frame is filled; and
decode, upon receiving the data indicating that the first frame is filled, each of the plurality of rows of the first frame using the set of hardware resources.

15. The processor of claim 14, wherein the decoder unit is further configured to:
receive data indicating that one or more stored physical layer packets for a second frame are to be decoded; and
interrupt the decoding of the first frame to decode the one or more stored physical layer packets, wherein the set of hardware resources are configured to process one physical layer packet or one row at a time.

16. The processor of claim 15, wherein the decoder unit is further configured to resume the decoding of the interrupted first frame after the decoding of the one or more stored physical layer packets to be filled in the second frame is completed.

17. The processor of claim 12, wherein the decoder unit is further configured to:
continue decoding of the first frame after a stored physical layer packet is received and ready to be decoded; and
interrupt the decoding of the first frame to decode stored physical layer packets when a number of stored physical layer packets exceed a threshold, the threshold comprising a plurality of physical layer packets.

18. The processor of claim 12, wherein the decoder unit is further configured to:
receive data identifying that a standard being used for the wireless communication signal has changed from a first standard to a second standard; and
suspend frame decoding functionality according to the second standard.

19. The processor of claim 12, wherein,
the processor further comprises an analog processing unit configured to digitize the received wireless communication signals;
the decoder unit comprises a Reed-Salomon decoder; and
a first frame comprises a link layer frame, wherein the row comprises data from a plurality of the series of physical layer packets included in the first frame.

20. A method of decoding a received wireless signal, the method comprising:
initiating a decoding process for a first link layer frame, wherein the first link layer frame is decoded row by row;
receiving data indicating that one or more stored physical layer packets are ready to be decoded; and
interrupting the decoding process of the first link layer frame to decode the one or more stored physical layer packets.

21. The method of claim 20, further comprising:
completing the decoding of the one or more stored physical layer packets;
storing the decoded one or more stored physical layer packets in a second link layer frame with a column by column progression; and
resuming the row by row decoding process of the interrupted link layer frame.

22. The method of claim 20, further comprising:
receiving data indicating that the decoding of the one or more stored physical layer packets is complete; and
resuming the decoding of the interrupted link layer frame upon receiving the indication the decoding of the one or more stored physical layer packets is complete.

23. The method of claim 20, wherein the decoding of a selected row of a link layer frame and the decoding of a physical layer packet occurs serially.

24. The method of claim 20, wherein the interrupting step comprises:
interrupting the decoding process of the link layer frame to process stored physical layer packets when a number of stored physical layer packets to be decoded exceeds a threshold.

25. The method of claim 20, further comprising:
receiving data identifying that a standard being used for the wireless signal has changed from a first standard to a second standard; and
suspending frame decoding functionality according to the second standard.
